(19) United States
(12) Patent Application Publication
(10) Pub. No.: US 2005/0051856 A1
(43) Pub. Date: Mar. 10, 2005

(54) Semiconductor device

(76) Inventors: Mizuki Ono, Yokohama-shi (JP); Takamitsu Ishihara, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/882,275

(22) Filed: Jul. 2, 2004

(30) Foreign Application Priority Data
Sep. 4, 2003 (JP) P2003-313093

(51) Int. Cl. H01L 29/94

(52) U.S. Cl. 257/411

(57) ABSTRACT

The semiconductor device includes a gate insulator with a three-layer stacked structure including a first insulator on a semiconductor substrate, a second insulator on the first insulator, and a third insulator on the second insulator. The first insulator is made of silicon oxide, silicon nitride, or oxinitrided silicon. The second and the third insulator contain a metal. The dielectric constant of the second insulator is higher than the square root of the product of the dielectric constants of the first and the third insulator. The present invention provides a high-speed semiconductor device, decreasing scattering of the carriers.

### CROSS REFERENCE TO RELATED APPLICATIONS

This application is based upon and claims the benefit of priority from prior Japanese Patent Applications P2003-313093 filed on Sep. 4, 2003; the entire contents of which are incorporated by reference herein.

### BACKGROUND OF THE INVENTION

1. Field of the Invention

The present invention relates to a semiconductor device.

2. Description of the Related Art

With the aim to increase the operation speed of conventional field-effect transistors, a gate electrode is made of a refractory metal for reducing resistance, and a gate insulator film is made of a high dielectric material for increasing current driving force. It is known that if the gate insulator film is made of a material such as a metal oxide, the mobility of carriers for carrying current through a channel decreases compared to when the gate insulator film is made of silicon oxide. This lowers the current driving force and the device operation speed, preventing high-speed operations of the device. This problem also requires attention when using a metal-containing material for the gate insulator film (for example, JP, A (Japanese Patent Application Laid-Open) No. 2003-8011).

When the gate insulator film is made of a material such as a metal oxide, the decrease in mobility is understood to emanate from the amount of charge existing at the interface between the gate insulator film and a semiconductor substrate or in the gate insulator film. In such a case, the charge is greater than when the gate insulator film is made of silicon oxide, and scattering of carriers moving through a channel is increased as a result thereof. A structure providing a silicon oxide film or the like between the gate insulator film made of a material such as a metal oxide and the semiconductor substrate has also been considered. With such structure, there is little charge at the interface between the gate insulator film and the semiconductor substrate since the insulator film in direct contact with the semiconductor is a silicon oxide film or the like. However, since an interface exists between the silicon oxide film and the metal oxide insulator film in the device structure, charges also exist at that interface. The charges existing in a metal oxide insulator film or the like is also a problem. Therefore, scattering of the carriers due to the charges existing within the insulator film cannot be reduced. On such basis, with a device using a high dielectric material such as a metal oxide for the gate insulator film, the mobility of the carriers, which carry current through the channel, is less than that with a device using silicon oxide for the gate insulator film. This prevents high-speed operations, especially when using a metal-containing material for the gate insulator film. Furthermore, since the dielectric constant for silicon oxide is not very high, provision of a silicon oxide layer between a metal oxide insulator film or the like and the semiconductor substrate is equivalent to a considerable increase in the gate insulator film thickness. This weakens the capacitive coupling between a channel region and a gate electrode, thus weakening the controllability of the gate electrode with respect to the potential of the channel region. As a result, the resistance to the short channel effect is reduced so as to prevent device miniaturization. Such phenomenon prevents implementation of high-speed operations.

The present invention is developed in order to solve the above problems, and provides a minute semiconductor device capable of high-speed operations by reducing the scattering of carriers as well as enhancing the controllability of the gate electrode with respect to the potential of the channel region.

### SUMMARY OF THE INVENTION

An aspect of the present invention inheres in a semiconductor device, including a semiconductor substrate; a source and a drain region, which are arranged at the surface of the semiconductor substrate; a gate insulator film, which is arranged on a channel defined between the source and drain regions at the surface of the semiconductor substrate and is implemented by a stacked structure including a first insulator film, a second insulator film containing a metal is provided on the first insulator film, and a third insulator film containing a metal is provided on the second insulator film. A gate electrode is arranged on the third insulator film, wherein the dielectric constant of the second insulator film is higher than the square root of the product of the dielectric constants of the first and third insulator films.

Another aspect of the present invention inheres in a semiconductor device, including a semiconductor substrate; a source and a drain region arranged at the surface of the semiconductor substrate. A gate insulator film is arranged on a channel defined between the source and drain regions at the surface of the semiconductor substrate and is implemented by a stacked structure including a first insulator film containing a metal and a second insulator film containing a metal on the first insulator film. A gate electrode is arranged on the second insulator film, wherein the dielectric constant of the first insulator film is higher than the square root of the product of the dielectric constants of the semiconductor substrate and the second insulator film.

### BRIEF DESCRIPTION OF DRAWINGS

FIG. 1 is a block diagram for describing a semiconductor device of an embodiment;

FIG. 2 is a block diagram for describing the semiconductor device of the embodiment;

FIG. 3 is a block diagram for describing the semiconductor device of the embodiment;

FIG. 4 is a cross section for describing the structure of a field-effect transistor according to a first embodiment of the present invention;

FIG. 5 is a cross section for explaining a fabrication step for the field-effect transistor according to the first embodiment of the present invention;

FIG. 6 is a cross section for explaining a fabrication step for the field-effect transistor according to the first embodiment of the present invention;

FIG. 7 is a cross section for explaining a fabrication step for the field-effect transistor according to the first embodiment of the present invention;

FIG. 8 is a cross section for explaining a fabrication step for the field-effect transistor according to the first embodiment of the present invention;

FIG. 9 is a cross section for explaining a fabrication step for the field-effect transistor according to the first embodiment of the present invention;

FIG. 10 is a cross section for explaining a fabrication step for the field-effect transistor according to the first embodiment of the present invention;

FIG. 11 is a cross section for explaining a fabrication step for the field-effect transistor according to the first embodiment of the present invention;

FIG. 12 is a cross section for explaining a fabrication step for the field-effect transistor according to the first embodiment of the present invention;

FIG. 13 is a cross section for describing a modified example of the field-effect transistor according to the first embodiment of the present invention;

FIG. 14 is a cross section for describing a modified example of the field-effect transistor according to the first embodiment of the present invention;

FIG. 15 is a cross section for describing a modified example of the field-effect transistor according to the first embodiment of the present invention;

FIG. 16 is a cross section for describing a modified example of the field-effect transistor according to the first embodiment of the present invention;

FIG. 17 is a cross section for describing a modified example of the field-effect transistor according to the first embodiment of the present invention;

FIG. 18 is a cross section for describing a modified example of the field-effect transistor according to the first embodiment of the present invention;

FIG. 19 is a cross section for describing a modified example of the field-effect transistor according to the first embodiment of the present invention;

FIG. 20 is a cross section for describing a modified example of the field-effect transistor according to the first embodiment of the present invention;

FIG. 21 is a cross section for describing a modified example of the field-effect transistor according to the first embodiment of the present invention;

FIG. 22 is a cross section for describing a modified example of the field-effect transistor according to the first embodiment of the present invention;

FIG. 23 is a cross section for describing a modified example of the field-effect transistor according to the first embodiment of the present invention;

FIG. 24 is a cross section for describing a modified example of the field-effect transistor according to the first embodiment of the present invention;

FIG. 25 is a cross section for describing a modified example of the field-effect transistor according to the first embodiment of the present invention;

FIG. 26 is a cross section for describing a modified example of the field-effect transistor according to the first embodiment of the present invention;

FIG. 27 is a cross section for describing a modified example of the field-effect transistor according to the first embodiment of the present invention;

FIG. 28 is a cross section for describing a modified example of the field-effect transistor according to the first embodiment of the present invention;

FIG. 29 is a cross section for describing a modified example of the field-effect transistor according to the first embodiment of the present invention;

FIG. 30 is a cross section for describing a modified example of the field-effect transistor according to the first embodiment of the present invention;

FIG. 31 is a cross section for describing a modified example of the field-effect transistor according to the first embodiment of the present invention;

FIG. 32 is a cross section for describing a modified example of the field-effect transistor according to the first embodiment of the present invention;

FIG. 33 is a cross section for describing the modified example of the field-effect transistor according to the first embodiment of the present invention;

FIG. 34 is a cross section for describing a modified example of the field-effect transistor according to the first embodiment of the present invention;

FIG. 35 is a cross section for describing a modified example of the field-effect transistor according to the first embodiment of the present invention;

FIG. 36 is a cross section for describing a modified example of the field-effect transistor according to the first embodiment of the present invention;

FIG. 37 is a cross section for describing a modified example of the field-effect transistor according to the first embodiment of the present invention;

FIG. 38 is a cross section for describing a modified example of the field-effect transistor according to the first embodiment of the present invention;

FIG. 39 is a cross section for describing a modified example of the field-effect transistor according to the first embodiment of the present invention;

FIG. 40 is a cross section for describing a modified example of the field-effect transistor according to the first embodiment of the present invention;

FIG. 41 is a cross section for describing a modified example of the field-effect transistor according to the first embodiment of the present invention;

FIG. 42 is a cross section for describing a modified example of the field-effect transistor according to the first embodiment of the present invention;

FIG. 43 is a cross section for describing a modified example of the field-effect transistor according to the first embodiment of the present invention;

FIG. 44 is a cross section for describing a modified example of the field-effect transistor according to the first embodiment of the present invention;

FIG. 45 is a cross section for describing a modified example of the field-effect transistor according to the first embodiment of the present invention;

FIG. 46 is a cross section for describing a modified example of the field-effect transistor according to the first embodiment of the present invention;

FIG. 47 is a cross section for describing a modified example of the field-effect transistor according to the first embodiment of the present invention;

FIG. 48 is a cross section for describing a modified example of the field-effect transistor according to the first embodiment of the present invention;

FIG. 49 is a cross section for describing a modified example of the field-effect transistor according to the first embodiment of the present invention;

FIG. 50 is a cross section for describing a modified example of the field-effect transistor according to the first embodiment of the present invention;

FIG. 51 is a cross section for describing a modified example of the field-effect transistor according to the first embodiment of the present invention;

FIG. 52 is a cross section for describing a modified example of the field-effect transistor according to the first embodiment of the present invention;

FIG. 53 is a cross section for describing a modified example of the field-effect transistor according to the first embodiment of the present invention;

FIG. 54 is a cross section for describing a modified example of the field-effect transistor according to the first embodiment of the present invention;

FIG. 55 is a cross section for describing a modified example of the field-effect transistor according to the first embodiment of the present invention;

FIG. 56 is a cross section for describing a modified example of the field-effect transistor according to the first embodiment of the present invention;

FIG. 57 is a cross section for describing a modified example of the field-effect transistor according to the first embodiment of the present invention;

FIG. 58 is a cross section for describing a modified example of the field-effect transistor according to the first embodiment of the present invention;

FIG. 59 is a cross section for describing a modified example of the field-effect transistor according to the first embodiment of the present invention;

FIG. 60 is a cross section for describing a modified example of the field-effect transistor according to the first embodiment of the present invention;

FIG. 61 is a cross section for describing a modified example of the field-effect transistor according to the first embodiment of the present invention;

FIG. 62 is a cross section for describing a modified example of the field-effect transistor according to the first embodiment of the present invention;

FIG. 63 is a cross section for describing a modified example of the field-effect transistor according to the first embodiment of the present invention;

FIG. 64 is a cross section for describing a modified example of the field-effect transistor according to the first embodiment of the present invention;

FIG. 65 is a cross section for describing a modified example of the field-effect transistor according to the first embodiment of the present invention;

FIG. 66 is a cross section for describing a modified example of the field-effect transistor according to the first embodiment of the present invention;

FIG. 67 is a cross section for describing a modified example of the field-effect transistor according to the first embodiment of the present invention;

FIG. 68 is a cross section for describing a modified example of the field-effect transistor according to the first embodiment of the present invention;

FIG. 69 is a cross section for describing a modified example of the field-effect transistor according to the first embodiment of the present invention;

FIG. 70 is a cross section for describing a modified example of the field-effect transistor according to the first embodiment of the present invention;

FIG. 71 is a cross section for describing a modified example of the field-effect transistor according to the first embodiment of the present invention;

FIG. 72 is a cross section for describing a modified example of the field-effect transistor according to the first embodiment of the present invention;

FIG. 73 is a cross section for describing a modified example of the field-effect transistor according to the first embodiment of the present invention;

FIG. 74 is a cross section for describing a modified example of the field-effect transistor according to the first embodiment of the present invention;

FIG. 75 is a cross section for describing a modified example of the field-effect transistor according to the first embodiment of the present invention;

FIG. 76 is a cross section for describing a modified example of the field-effect transistor according to the first embodiment of the present invention;

FIG. 77 is a cross section for describing the structure of a field-effect transistor according to a second embodiment of the present invention;

FIG. 78 is a cross section for explaining a fabrication step for the field-effect transistor according to the second embodiment of the present invention;

FIG. 79 is a cross section for explaining a fabrication step for the field-effect transistor according to the second embodiment of the present invention;

FIG. 80 is a cross section for describing a modified example of the field-effect transistor according to the second embodiment of the present invention;

FIG. 81 is a cross section for describing a modified example of the field-effect transistor according to the second embodiment of the present invention;

FIG. 82 is a cross section for describing a modified example of the field-effect transistor according to the second embodiment of the present invention;

FIG. 83 is a cross section for describing a modified example of the field-effect transistor according to the second embodiment of the present invention;

FIG. 84 is a cross section for describing a modified example of the field-effect transistor according to the second embodiment of the present invention;

FIG. 85 is a cross section for describing a modified example of the field-effect transistor according to the second embodiment of the present invention;

FIG. 86 is a cross section for describing a modified example of the field-effect transistor according to the second embodiment of the present invention;

FIG. 87 is a cross section for describing a modified example of the field-effect transistor according to the second embodiment of the present invention;

FIG. 88 is a cross section for describing a modified example of the field-effect transistor according to the second embodiment of the present invention;

FIG. 89 is a cross section for describing a modified example of the field-effect transistor according to the second embodiment of the present invention;

FIG. 90 is a cross section for describing a modified example of the field-effect transistor according to the second embodiment of the present invention;

FIG. 91 is a cross section for describing a modified example of the field-effect transistor according to the second embodiment of the present invention;

FIG. 92 is a cross section for describing a modified example of the field-effect transistor according to the second embodiment of the present invention;

FIG. 93 is a cross section for describing a modified example of the field-effect transistor according to the second embodiment of the present invention;

FIG. 94 is a cross section for describing a modified example of the field-effect transistor according to the second embodiment of the present invention;

FIG. 95 is a cross section for describing a modified example of the field-effect transistor according to the second embodiment of the present invention;

FIG. 96 is a cross section for describing a modified example of the field-effect transistor according to the second embodiment of the present invention;

FIG. 97 is a cross section for describing a modified example of the field-effect transistor according to the second embodiment of the present invention;

FIG. 98 is a cross section for describing a modified example of the field-effect transistor according to the second embodiment of the present invention;

FIG. 99 is a cross section for describing a modified example of the field-effect transistor according to the second embodiment of the present invention;

FIG. 100 is a cross section for describing a modified example of the field-effect transistor according to the second embodiment of the present invention;

FIG. 101 is a cross section for describing a modified example of the field-effect transistor according to the second embodiment of the present invention;

FIG. 102 is a cross section for describing a modified example of the field-effect transistor according to the second embodiment of the present invention;

FIG. 103 is a cross section for describing a modified example of the field-effect transistor according to the second embodiment of the present invention;

FIG. 104 is a cross section for describing a modified example of the field-effect transistor according to the second embodiment of the present invention;

FIG. 105 is a cross section for describing a modified example of the field-effect transistor according to the second embodiment of the present invention;

FIG. 106 is a cross section for describing a modified example of the field-effect transistor according to the second embodiment of the present invention;

FIG. 107 is a cross section for describing a modified example of the field-effect transistor according to the second embodiment of the present invention;

FIG. 108 is a cross section for describing a modified example of the field-effect transistor according to the second embodiment of the present invention;

FIG. 109 is a cross section for describing a modified example of the field-effect transistor according to the second embodiment of the present invention;

FIG. 110 is a cross section for describing a modified example of the field-effect transistor according to the second embodiment of the present invention;

FIG. 111 is a cross section for describing a modified example of the field-effect transistor according to the second embodiment of the present invention;

FIG. 112 is a cross section for describing a modified example of the field-effect transistor according to the second embodiment of the present invention;

FIG. 113 is a cross section for describing a modified example of the field-effect transistor according to the second embodiment of the present invention;

FIG. 114 is a cross section for describing a modified example of the field-effect transistor according to the second embodiment of the present invention;

FIG. 115 is a cross section for describing a modified example of the field-effect transistor according to the second embodiment of the present invention;

FIG. 116 is a cross section for describing a modified example of the field-effect transistor according to the second embodiment of the present invention;

FIG. 117 is a cross section for describing a modified example of the field-effect transistor according to the second embodiment of the present invention;

FIG. 118 is a cross section for describing a modified example of the field-effect transistor according to the second embodiment of the present invention;

FIG. 119 is a cross section for describing a modified example of the field-effect transistor according to the second embodiment of the present invention;

FIG. 120 is a cross section for describing a modified example of the field-effect transistor according to the second embodiment of the present invention;

FIG. 121 is a cross section for describing a modified example of the field-effect transistor according to the second embodiment of the present invention;

FIG. 122 is a cross section for describing a modified example of the field-effect transistor according to the second embodiment of the present invention;

FIG. 123 is a cross section for describing a modified example of the field-effect transistor according to the second embodiment of the present invention;

FIG. 124 is a cross section of a field-effect transistor of a comparative example; and

FIG. 125 is a cross section of the field-effect transistor of another comparative example.

### DETAILED DESCRIPTION OF THE EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally, and as is conventional in the representation of the device structure, it will be appreciated that the various drawings are not drawn to scale from one figure to another nor inside a given figure, and in particular that the device cross-sectional diagrams are arbitrarily drawn for facilitating the reading of the drawings.

In the following descriptions, numerous specific details are set forth to provide a thorough understanding of the present invention. However, it will be obvious to those skilled in the art that the present invention may be practiced without such specific details. In other instances, well-known device structures have been shown in cross-sectional form in order to not obscure the present invention with unnecessary detail.

Referring to the drawings, embodiments of the present invention are described below. The same or similar reference numerals are attached to identical or similar parts among the following drawings. The embodiments shown below exemplify a device structure and a fabrication method that are used to implement the technical ideas according to the present invention, and do not limit the technical ideas according to the present invention to those that appear below. These technical ideas, according to the present invention, may receive a variety of modifications that fall within the claims.

### COMPARATIVE EXAMPLE

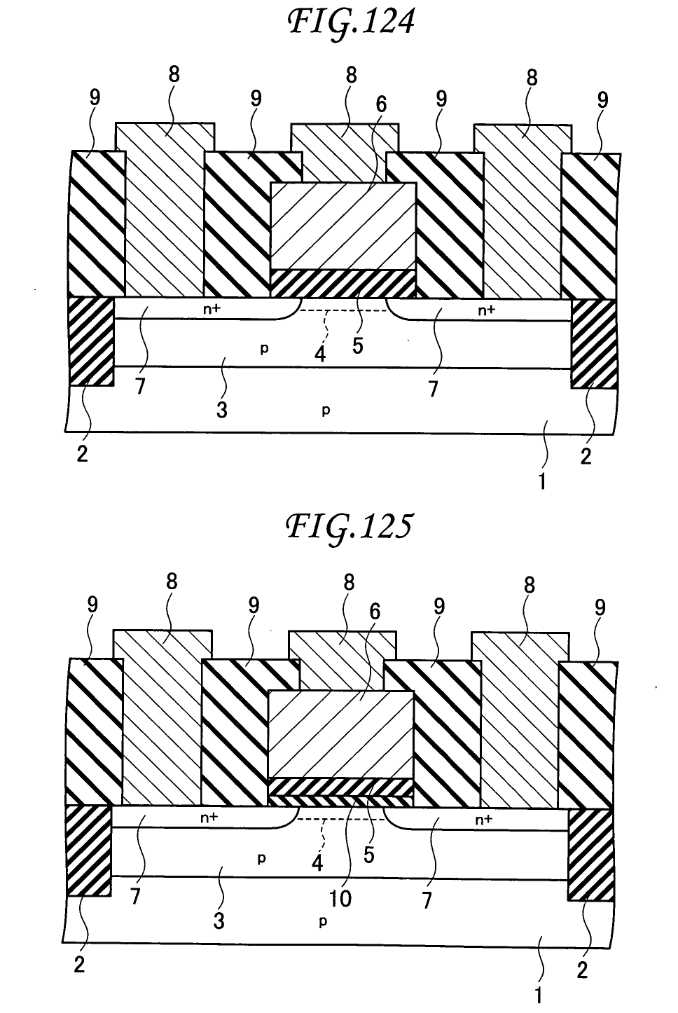

FIGS. 124 and 125 are cross sections of a field-effect transistor of a comparative example. An n-channel field-effect transistor is taken as an example in this case.

As shown in FIGS. 124 and 125, the field-effect transistor of the comparative example includes device isolation regions 2 formed on a p-type Si substrate 1 by trench device isolation. A p-well region 3 is formed in the p-type Si substrate through boron (B) ion implantation and thermal treatment, and an n-channel region 4 is formed in the p-well region 3 through B ion implantation.

In FIG. 124, a gate insulator film 5 such as a metal oxide with a higher dielectric constant than silicon oxide, is formed on the n-channel region 4, and a gate electrode 6 is formed on the gate insulator film 5 by depositing a 100 nm-thick refractory metal by sputtering. Furthermore, source/drain regions 7 are formed through arsenic (As) ion implantation. Reference numeral 8 denotes interconnects, and 9 denotes inter-layer insulator films.

Furthermore, a device is shown in FIG. 125 with a gate insulator film configured of stacked layers of a silicon oxide film 10 made of silicon oxide or oxidized and nitrided silicon provided between the gate insulator film 5 made of a material such as a metal oxide and the semiconductor substrate 1.

(First Embodiment)

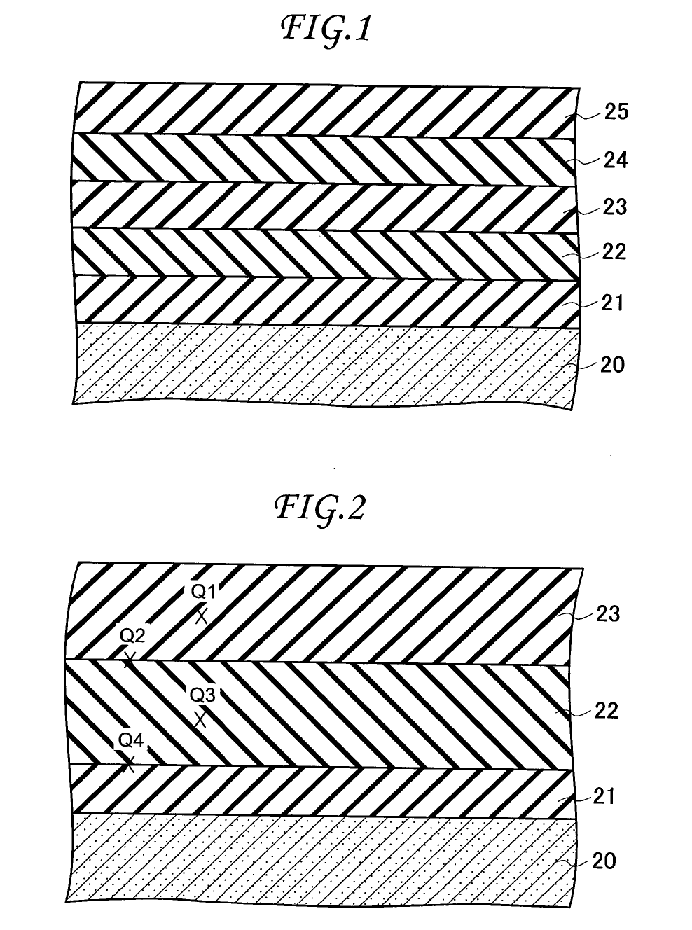

In a field-effect transistor of this embodiment, a gate insulator film is made of multiple stacked layers with differing dielectric constants. The dielectric constants are set as described above to suppress scattering of carriers due to charges in each layer or at the interfaces thereof. This is described forthwith. Stacked insulator films as shown in FIG. 1 are considered. FIG. 1 shows a structure of a first insulator film 21, a second insulator film 22, a third insulator film 23, a fourth insulator film 24, and a fifth insulator film 25 sequentially stacked and formed upon a semiconductor substrate 20. A semiconductor is on the bottom layer with a dielectric constant of ε_{Si}. Furthermore, thickness of the bottom layer is not limited with regard to the effect of the reverse side of the side shown in the drawings. The insulator films are stacked upon the semiconductor, where the j-th insulator film, counting from the bottom, has a dielectric constant εⱼ and thickness Tⱼ(j=1, 2, . . . ). The potential within the semiconductor in the case where a single point charge of size Q exists at the interface between the n−1-th layer and the nth layer of these stacked insulator films is considered. It is assumed that there is no charge in the insulator films or the semiconductor other than Q. In addition, it is assumed that all interfaces are parallel to each other, and the distribution along those parallel interfaces other than point charge Q is uniform.

The potential in the semiconductor along those interfaces may be calculated through the Fourier transform given below:

$$\frac{Q exp ( - k \vert z - {\sum }_{l = 1}^{n - 1} {T}_{l} \vert )}{2 {ɛ}_{0} k} ( {\prod }_{l = 0}^{n - 1} \frac{2 {ɛ}_{1}}{{ɛ}_{l + 1} + {ɛ}_{l}} ) \frac{B}{A} \qquad ( 1 )$$

where k denotes the wavenumber for the Fourier transform, and for the sake of convenience, the dielectric constant of the semiconductor corresponding to ε_{Si} is given as ε₀ in Expression (1). Furthermore, A and B are given as follows:

$$\begin{matrix}A = 1 + {\sum }_{N \geq j > i \geq 0} \{ {E}_{j} {E}_{i} {\prod }_{l = i + 1}^{j} exp ( - 2 {kT}_{l} ) \} + {\sum }_{N \geq m > l > j > i \geq 0} \{ {E}_{m} {E}_{l} {\prod }_{p = l + 1}^{m} exp ( - 2 {kT}_{p} ) \} \{ {E}_{j} {E}_{i} {\prod }_{r = i + 1}^{j} exp ( - 2 {kT}_{r} ) \} + ⋯ & ( 2 ) \\ B = 1 + {\sum }_{N \geq j > i \geq n - 1} \{ {F}_{j} {F}_{i} {\prod }_{l = i + 1}^{j} exp ( - 2 {kT}_{l} ) \} + {\sum }_{N \geq m > l > j > i \geq n - 1} \{ {F}_{m} {F}_{l} {\prod }_{p = l + 1}^{m} exp ( - 2 {kT}_{p} ) \} \{ {F}_{j} {F}_{i} {\prod }_{r = i + 1}^{j} exp ( - 2 {kT}_{r} ) \} + ⋯ & ( 3 )\end{matrix}$$

where N denotes the total number of insulator film layers minus one, and Eᵢ and Fᵢ (i=0, 1, . . . , N) are given as follows:

$$\begin{matrix}{E}_{i} = \frac{{ɛ}_{i + 1} - {ɛ}_{i}}{{ɛ}_{i + 1} + {ɛ}_{i}} & ( 4 ) \\ {F}_{i} = \{ \begin{matrix}{E}_{i} & ( i \neq n - 1 ) \\ - 1 & ( i = n - 1 )\end{matrix} & ( 5 )\end{matrix}$$

By substituting these expressions for Expression (1) and expanding 1/Λ, the Fourier transform of the potential in the semiconductor is represented by the power series exp (−kTⱼ) (j=1, 2, . . . ). The wavenumber for the Fourier transform is denoted by k, as described above. Considering actual scattering of carriers, contribution of the Fermi wavenumber, when the carriers in an inversion layer are regarded as a two-dimensional gas, is large. Here, considering the definitions of Eᵢ and Fᵢ (i=0, 1, . . . , N), the respective absolute values thereof are understood to be no greater than 1. The principal term is then extracted from that power series noting that exp(−kTⱼ) (j=1, 2, . . . ) is generally small. Only the principal term relevant to A and B at the right side of Expression (1) should be considered. Considering the expressions of A and B, the principal term is equivalent to A=B=1. By extracting the principal term in this manner and subjecting it to the Fourier inverse transform, the potential in the semiconductor is the same as that when supposing that the entire space of medium is filled with a material with dielectric constant ε_{Si}, and is the same as the potential where a point charge of a size given by the following expression exists at the position of Q.
(2ε_{Si}(ε_{Si}+ε₁))×(2ε₁/(ε₁+ε₂))× . . . ×(2εₙ₋₁/(εₙ₋₁+εₙ))×Q (6)

It should be noted that the point charge Q exists at the interface between the n−1-th layer and the nth layer of the stacked insulator films in this case; however, in the same way as when Q exists in the nth layer, the potential in the semiconductor is the same as in the case where the entire space of medium is filled with a material with dielectric constant ε_{Si}, and a point charge of a size given by Expression (6) exists at the same position as Q. This can be understood from the fact that if εₙ₋₁ and εₙ are assumed to be equal in FIG. 1, the point charge Q can be regarded to exist in the n−1-th layer, and that the last term (2εₙ₋₁/(εₙ₋₁+εₙ)) appearing in the product of Expression (6) in that case is equal to 1, and the product value is equal to the value of Expression (6) when substituting n−1 for n in Expression (6). Here, since the mobility of the carriers moving in the semiconductor is inversely proportional to the scattering probability, and the scattering probability, which is determined by the charges existing within the gate insulator film and the interface between the gate insulator film and the semiconductor substrate, is proportional to the square of the potential created by the existing charges, the smaller the value of Expression (6), the greater the mobility of the carriers.

Here, a gate insulator film with at least three layers as shown in FIG. 2 is considered. The insulator film closest to the semiconductor substrate is assumed to be a silicon oxide, silicon nitride, or oxidized and nitrided silicon, and the third insulator film counting from the semiconductor substrate is assumed to be an insulator film made of a high dielectric material, such as a metal oxide. The potential determined by a charge Q1 existing in the third insulator film counting from the semiconductor substrate and a charge Q2 existing at the interface between the second insulator film and the third insulator film counting from the semiconductor substrate is considered. This potential is proportionate to
(2 ε_{Si}/(ε_{Si}+ε₁))×(2ε₁/(ε₁+ε₂))×(2 ε₂/(ε₂+ε₃)) (7)
when referencing Expression (6) and the description thereafter. Reduction in the value of Expression (7) by adjusting the dielectric constant of the second insulator film counting from the semiconductor substrate in the structure shown in FIG. 2 is considered. The smaller the potential in the substrate created by the charges as described above, the greater the mobility of the carriers moving in the semiconductor substrate, thereby improving mobility. Considering the dependency on ε₂ in Expression (7), it can be understood that Expression (7) becomes a maximum value in the case of ε₂=(ε₁×ε₃)^{1/2}, and decreases when ε₂ is either higher or lower than that value. Accordingly, it can be understood that the case where the dielectric constant of the second insulator film, counting from the semiconductor substrate, is equivalent to the square root of the product of the dielectric constant of the closest insulator film to the semiconductor substrate and the dielectric constant of the third insulator film counting from the semiconductor substrate is most undesirable. Further the case where ε₂ is either higher or lower than the value of (ε₁×ε3)^{1/2} is preferred. However, if the dielectric constant of the second insulator film counting from the semiconductor substrate is set too low, undesirable results develop: such that the capacitive coupling between the channel region and the gate electrode weakens. Thus, the controllability of the gate electrode with respect to the potential of the channel region deteriorates, an adverse influence of the short channel effect increases, and device current driving capability is reduced. Accordingly, the dielectric constant of the second insulator film, counting from the semiconductor substrate, is preferably set to a higher value than the square root of the product of the dielectric constants of the closest insulator film to the semiconductor substrate and the third insulator film, counting from the semiconductor substrate. Next, the potential in the semiconductor brought about by a charge Q3 existing in the second insulator film, counting from the semiconductor substrate, and a charge Q4 existing at the interface between the closest insulator film to the semiconductor substrate and the second insulator film, counting from the semiconductor substrate, are considered. The potential is proportionate to
(2ε_{Si}/(ε_{Si}+ε₁))×(2 ε₁/(ε₁+ε₂)) (8)
when referencing Expression (6) and the description thereafter. Reduction in the value of Expression (8) by adjusting the dielectric constant of the second insulator film, counting from the semiconductor substrate, is considered. As described above, the smaller the potential due to the charges in the gate insulator film, the greater the mobility of the carriers moving in the semiconductor substrate, so as to improve mobility. The value of Expression (8) decreases as E 2 increases. Accordingly, it can be understood that a higher dielectric constant of the second insulator film counting from the semiconductor substrate, is more desirable. It can be understood from the discussion relating to Expression (8) and Expression (7), given thereabove, that the dielectric constant of the second insulator film counting from the semiconductor substrate is preferably set to a higher value than the square root of the product of the dielectric constants of the closest insulator film to the semiconductor substrate and the third insulator film, counting from the semiconductor substrate. Here, the gate insulator film of the comparative example as shown in FIG. 125 is considered. Since the gate insulator film in this case is made up of two stacked layers of a metal oxide and silicon oxide, the case of ε₂=ε₃ may be considered with Expressions (7) and (8). Since the insulator film closest to the semiconductor substrate is assumed to be silicon oxide, silicon nitride, or oxidized and nitrided silicon as described before Expression (7), and the third insulator film side is assumed to be an insulator film of a high dielectric material such as a metal oxide, the relationship ε₁<ε₃ can be expected to be established. Accordingly, when ε₂=ε₃, ε₂>(ε₁×ε₃)^{1/2} holds true, the value of Expression (2) is a maximum value, and decreases if ε₂ is greater than the value ε₂=(ε₁×ε₃)^{1/2}. Therefore, assuming that ε₂>ε₃ in a gate insulator film with at least three layers as shown in FIG. 2, it can be understood that the potential in the semiconductor substrate due to the charge Q1 or Q2 is smaller than in the case of the gate insulator film of the comparative example as shown in FIG. 125. Furthermore, since the value of Expression (8) decreases as E 2 increases, assuming that ε₂>ε₃ in a gate insulator film with at least three layers as shown in FIG. 2, it can be understood that the potential in the semiconductor substrate due to Q3 or Q4 is smaller than in the case of the gate insulator film of the comparative example as shown in FIG. 125. Therefore, assuming that ε₂>ε₃ in a gate insulator film with at least three layers as shown in FIG. 2, it can be understood that the potential in the semiconductor substrate due to charges other than those at the interface between the semiconductor substrate and the closest insulator film to the semiconductor substrate, which is a silicon oxide, a silicon nitride, or an oxidized and nitrided silicon insulator film, is smaller than in the case of the gate insulator film of the comparative example as shown in FIG. 125. Furthermore, there is very little charge at the interface between the semiconductor substrate and the closest insulator film to the semiconductor substrate. Therefore, assuming that ε₂>ε₃ in a three-layered gate insulator film as shown in FIG. 2, it can be understood that the mobility of the carriers moving in the semiconductor substrate increases more than in the case of the gate insulator film of the comparative example as shown in FIG. 125. Furthermore, ε₂ is set extremely high in the three-layered gate insulator film structure. Thus, controllability of the gate electrode with respect to the potential in the channel region may be not substantially affected due to provision of such insulator film layers. As a result, the short channel effect may be controlled and high current driving capability may be implemented. It should be noted that the second and the third insulator film, counting from the semiconductor substrate, are depicted with nearly equal thicknesses; however, thickness is not of essence to the present description.

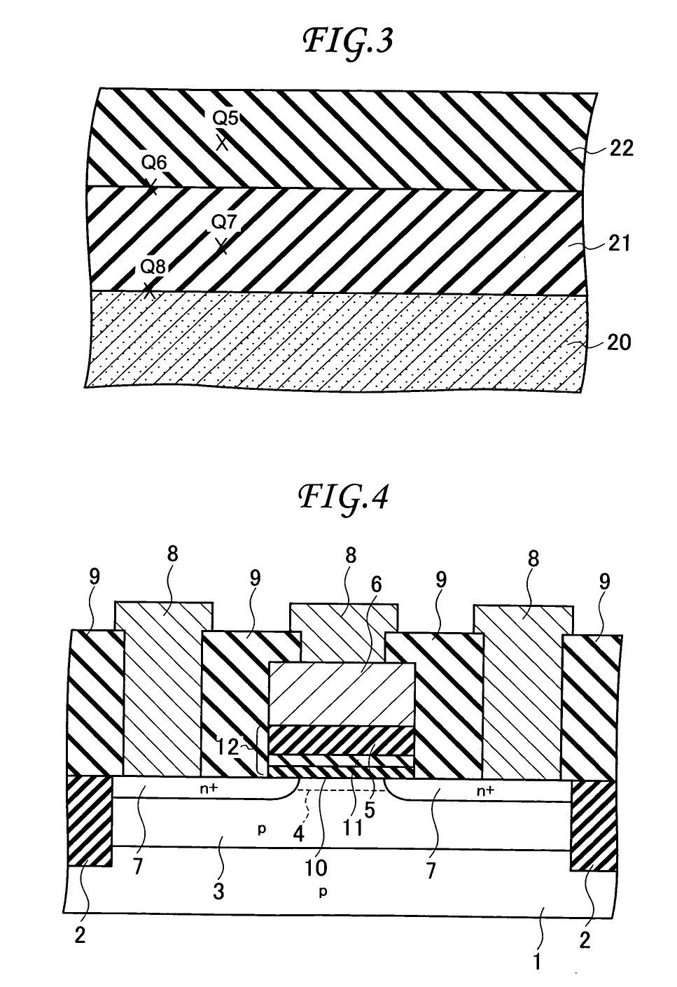

Next, a gate insulator film with at least two layers as shown in FIG. 3 is considered. An insulator film made of a high dielectric material such as a metal oxide is assumed as the second insulator film counting from the semiconductor substrate. The gate insulator film in the semiconductor device of the comparative example as shown in FIG. 125 is provided by making the closest insulator film to the semiconductor substrate of silicon oxide, silicon nitride or oxidized and nitrided silicon. To begin with, the potential in the semiconductor due to a charge Q5 existing in the second insulator film counting from the semiconductor substrate and a charge Q6 existing at the interface between the second insulator film counting from the semiconductor substrate and the closest insulator film to the semiconductor substrate is considered. This potential is proportional to
(2ε_{Si}/(ε_{Si}+ε₁))×(2ε₁/(ε₁+ε₂)) (9)
when referencing Expression (6) and as described thereafter. Reduction in the value of Expression (9) by adjusting the dielectric constant of the closest insulator film to the semiconductor substrate in the structure shown in FIG. 3 is considered. As described above, the smaller the potential in the gate insulator film due to the charges, the greater the mobility of the carriers moving in the semiconductor substrate, thereby improving mobility. Considering the dependency on ε₁ in Expression (9), it can be understood that the value of Expression (9) is a maximum value in the case of ε₁=(ε_{Si}×ε₂)^{1/2}, and decreases when ε₁ is either higher or lower than that value. Therefore, it can be understood that the case where the dielectric constant of the closest insulator film to the semiconductor substrate is equivalent to the square root of the product of the dielectric constant of the semiconductor substrate and the dielectric constant of the second insulator film, counting from the semiconductor substrate, is most undesirable. Further the case where such dielectric constant is either higher or lower is preferred. However, if the dielectric constant of the closest insulator film to the semiconductor substrate is set too low, the capacitive coupling between the channel region and the gate electrode weakens. This weakened capacitive coupling causes undesirable results to develop: such as weakening of the controllability of the gate electrode with respect to the potential of the channel region, an adverse influence of the short channel effect increases, and device current driving capability is reduced. Therefore, the dielectric constant of the closest insulator film to the semiconductor substrate is preferably set to a higher value than the square root of the product of the dielectric constants of the semiconductor substrate and the second insulator film, counting from the semiconductor substrate. Next, the potential in the semiconductor due to a charge Q7 existing in the closest insulator film to the semiconductor substrate and a charge Q8 existing at the interface between the closest insulator film to the semiconductor substrate and the semiconductor substrate is considered. This potential is proportionate to
(2ε_{Si}/(ε_{Si}+ε₁)) (10)
when referencing Expression (6) and the description thereafter. Reduction in the value of Expression (10) by adjusting the dielectric constant of the closest insulator film to the semiconductor substrate is considered. As described above, the smaller the potential in the gate insulator film due to the charges, the greater the mobility of the carriers moving in the semiconductor substrate, thereby improving mobility. The value of Expression (10) decreases as ε₁ increases. Therefore, it can be understood that the higher the dielectric constant of the closest insulator film to the semiconductor substrate, the more preferable. It can be understood from the discussion relating to Expression (10) and Expression (9), given thereabove, that the dielectric constant of the closest insulator film to the semiconductor substrate is preferably set to a higher value than the square root of the product of the dielectric constants of the semiconductor substrate and the second insulator film, counting from the semiconductor substrate. Here, the gate insulator film of the comparative example as shown in FIG. 124 is considered. Since the gate insulator film of the present case is made up of a single layer of a metal oxide, the case of ε₁=ε₂ may be considered with Expression (9) or (10). Since the second insulator film, counting from the semiconductor substrate, is assumed to be a metal oxide as described before Expression (9), ε₂ may be assumed to be approximately the same as or higher than the dielectric constant of the silicon forming the semiconductor substrate. Accordingly, it can be understood that an inequality relationship ε₁>(ε_{Si}×ε₂)^{1/2} holds true, when ε₁=ε₂. As described above, since the value of Expression (9) is a maximum value when ε₁=(εₛᵢ×ε₂)^{1/2}, and decreases if ε₁ is greater than the value (εₛᵢ×ε₂)^{1/2}, assuming that ε₁>ε₂ in a gate insulator film with at least two layers as shown in FIG. 3, it can be understood that the potential in the semiconductor substrate due to Q5 or Q6 is smaller than in the case of the gate insulator film of the comparative example as shown in FIG. 124. Furthermore, since the value of Expression (10) decreases as ε₁ increases, assuming that ε₁>ε₂ in a gate insulator film with at least two layers as shown in FIG. 3, it can be understood that the potential in the semiconductor substrate due to Q7 or Q8 is smaller than in the case of the gate insulator film of the comparative example as shown in FIG. 124. Therefore, assuming that ε₁>ε₂ in a gate insulator film with two layers as shown in FIG. 1, it can be understood that the potential in the semiconductor substrate due to the charges in the gate insulator film or at the interface between the gate insulator film and the semiconductor substrate is smaller than in the case of the gate insulator film of the comparative example as shown in FIG. 124. Therefore, assuming that ε₁>ε₂ in a two-layered gate insulator film as shown in FIG. 3, it can be understood that the mobility of the carriers moving in the semiconductor substrate increases more than in the case of the gate insulator film of the comparative example as shown in FIG. 124. Furthermore, since ε₁ is set extremely high in this structure compared to the dielectric constant of silicon oxide, silicon nitride or oxidized and nitrided silicon, controllability of the gate electrode with respect to the potential in the channel region may be fairly small due to provision of such insulator film layers. Particularly, compared to when an insulator film made of silicon oxide, silicon nitride, or oxidized and nitrided silicon is provided between the insulator film, which is made of a metal oxide or the like, and the semiconductor substrate as shown in FIG. 125, controllability of the gate electrode with respect to the potential in the channel region may be fairly large. As a result, the short channel effect may be controlled and high current driving capability may be implemented. It should be noted that in FIG. 3, the closest insulator film to the semiconductor substrate and the second insulator film, counting from the semiconductor substrate, are depicted with nearly equal thicknesses; however, such equal thickness is not of essence to the present description.

It should be noted that each of Expressions (6) to (10) in this discussion depends on only the ratio of mutual dielectric constants of each insulator film. Therefore, the larger the ratio of εₛᵢ to ε₁, ε₁ to ε₂, and ε₂ to ε₃ or the ratio of dielectric constants of neighboring insulator film layers in the stacked gate insulator film as shown in FIG. 2 or 3, the more significant the effect of this embodiment. Accordingly, it is preferable that the insulator film to be set with a high dielectric constant as described above is made of a high dielectric material such as a metal oxide, a silicate thereof, or a nitride thereof.

As such, the field-effect transistor according to this embodiment is capable of operating at a high speed by enhancing the controllability of the gate electrode with respect to the potential in the channel region using a high dielectric material such as a metal oxide for the gate insulator film, and thereby controlling the short channel effect and also controlling scattering of carriers due to the charges in the gate insulator film and at the interface between that gate insulator film and the semiconductor substrate. Such structure and resultant operation increases the mobility of the carriers moving in the semiconductor substrate. Accordingly, a highly efficient, minute device capable of high-speed operation may be provided.

FIG. 4 is a cross section of the field-effect transistor of this embodiment. An n-channel field-effect transistor is taken as an example in this embodiment. The identical effects may be obtained as in the case of the p-channel field-effect transistor if the impurity conductivity type is reversed, and also as in the case of a complementary field-effect semiconductor using a method of implanting an impurity only in a specified region in the substrate through a method such as photo-lithography-process.

This field-effect transistor is characteristic of a gate insulator film with a three-layer stacked structure. The closest layer to a semiconductor substrate 1 is formed of a silicon oxide film 10, silicon nitride, or oxidized and nitrided silicon, the second and the third layer counting from the semiconductor substrate 1 are gate insulator films 11 and 5 made of a metal oxide, and the dielectric constant of the gate insulator film, which is the second layer counting from the semiconductor substrate, is higher than that of the gate insulator film 5, which is the third layer. This field-effect transistor is structured such that a gate insulator film is formed of stacked films including an additional high dielectric layer between two stacked layers of the gate insulator film in the field-effect transistor of the comparative example shown in FIG. 125, more specifically, between the insulator film made of a metal oxide or the like and the insulator film made of the silicon oxide film 10, silicon nitride, or oxidized and nitrided silicon. Such configured gate insulator film has the same structure as the stacked films in FIG. 2. Thereby, in accordance with the reasons described referencing FIG. 2, carrier mobility increases by controlling scattering of the carriers moving in the semiconductor substrate due to the charges in the gate insulator film. Therefore, a higher current driving capability than with the semiconductor device in the structure of the comparative example shown in FIGS. 124 and 125 may be provided. As a result, using a high dielectric material such as a metal oxide for the gate insulator film, controllability of the gate electrode with respect to the potential in the channel region may be improved and high mobility may be implemented. Further a highly efficient, minute semiconductor device capable of high-speed operation may be implemented.

This field-effect transistor further includes device isolation regions 2 formed on the p-type silicon substrate 1 through trench device isolation. The p-well region 3 is formed in the p-type silicon substrate 1, and the n-channel region 4 is formed in the p-well region 3. A gate insulator film 12, which has a stacked structure of an insulator film 10 made of the silicon oxide film, silicon nitride or oxidized and nitrided silicon, the gate insulator film 5 made of a metal oxide or the like, and the gate insulator film 11 made of a metal oxide with a higher dielectric constant than the gate insulator film 5, are formed on the n-channel region 4; and a gate electrode 6 is formed upon the stacked gate insulator film 12. Reference numeral 7 denotes source/drain region, 8 denotes interconnects, and 9 denotes inter-layer insulator films.

Next, a fabrication method for this field-effect transistor is described forthwith.

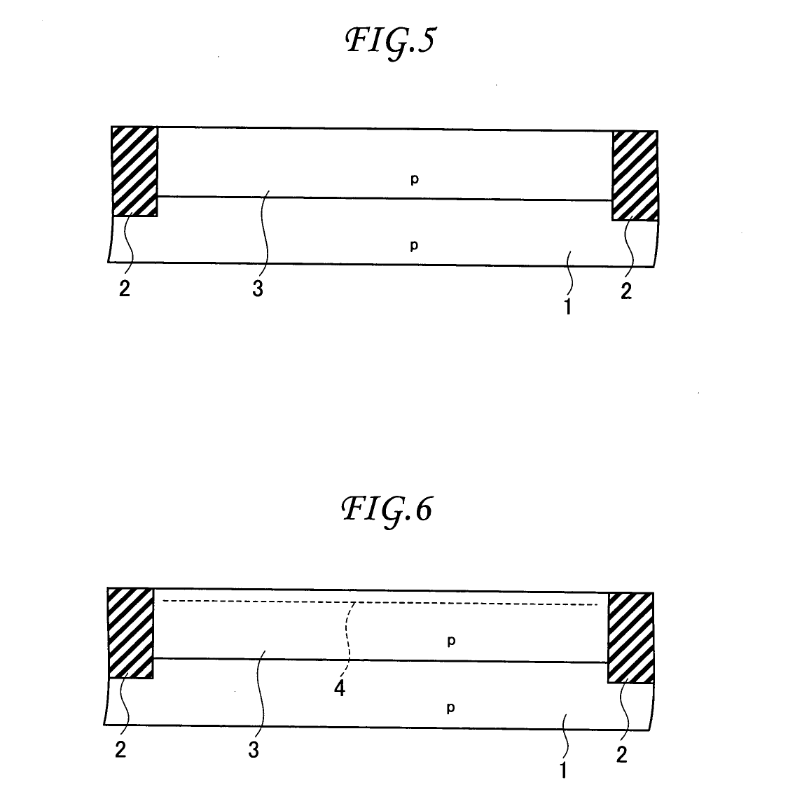

To begin with, as shown in FIG. 5, for example, the device isolation regions 2 are formed on the p-type Si substrate 1 through shallow trench isolation. B ions, for example, are implanted in a p-well formation region using an acceleration energy V_{acc}=100 keV with a dosage Φ=2.0×10¹³ ions/cm², and then forming a p-well region 3 by thermal treatment at 1050° C. for 30 seconds, for example.

As shown in FIG. 6, for example, B ions are implanted into the p-well region 3 using an acceleration energy V_{acc}=30 keV with a dosage Φ=1.0×10¹³ ions/cm² and the value of the surface impurity concentration of the n-channel region 4 is adjusted in order to obtain a desired threshold voltage.

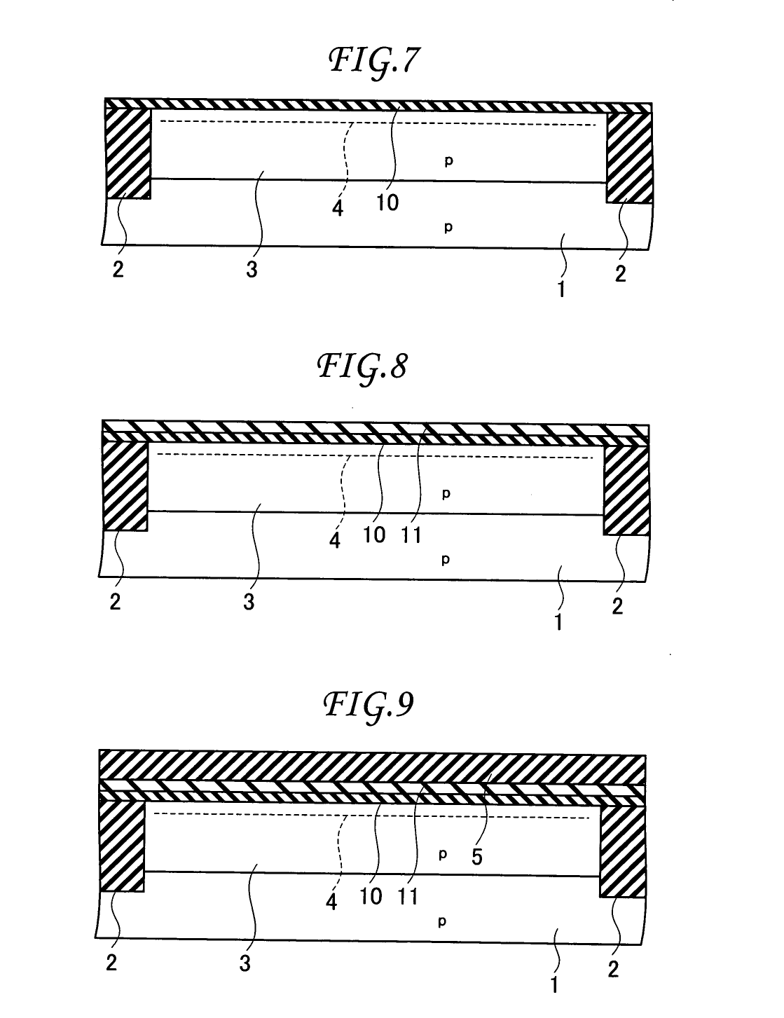

As shown in FIG. 7, the 1 nm-thick silicon oxide film 10, for example, is formed using a method such as exposing the film to a heated oxygen gas, for example.

As shown in FIG. 8, the gate insulator film 11 made of a 3 nm-thick TiO₂ film, for example, is formed by sputtering or related methods.

As shown in FIG. 9, the gate insulator film 5 made of a 5 nm-thick HfO₂ film, for example, is formed by sputtering, or related methods.

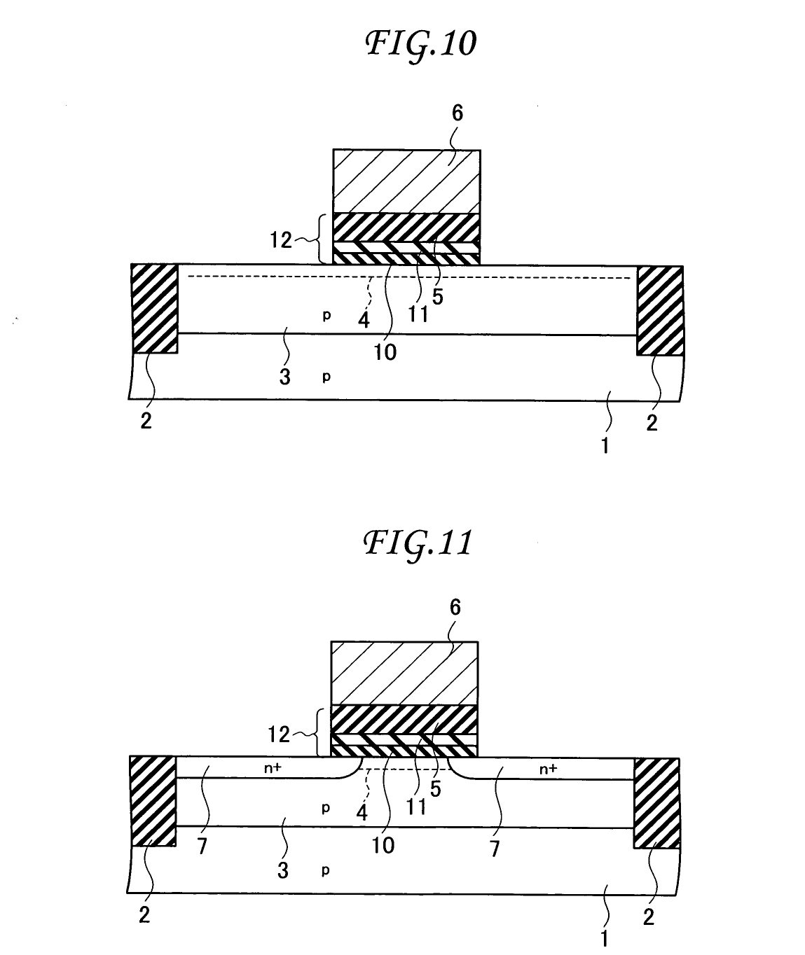

As shown in FIG. 10, for example, a refractory metal film such as tungsten with a thickness of 100 nm is deposited on the HfO₂ film 5 through CVD, and the gate electrode 6 is then formed by processing the refractory metal film through anisotropic etching such as RIE (Reactive Ion Etching) or the like. Subsequently, the gate insulator film 5 made of an HfO₂ film, the gate insulator film 11 made of a TiO₂ film, and the stacked gate insulator film 12 made of the silicon oxide film 10 are processed through anisotropic etching.

As shown in FIG. 11, arsenic (As) ions are implanted using an acceleration energy V_{acc}=50 keV with a dosage Φ=5.0×10¹⁶ ions/cm², for example. The source/drain region 7 is then formed through thermal treatment.

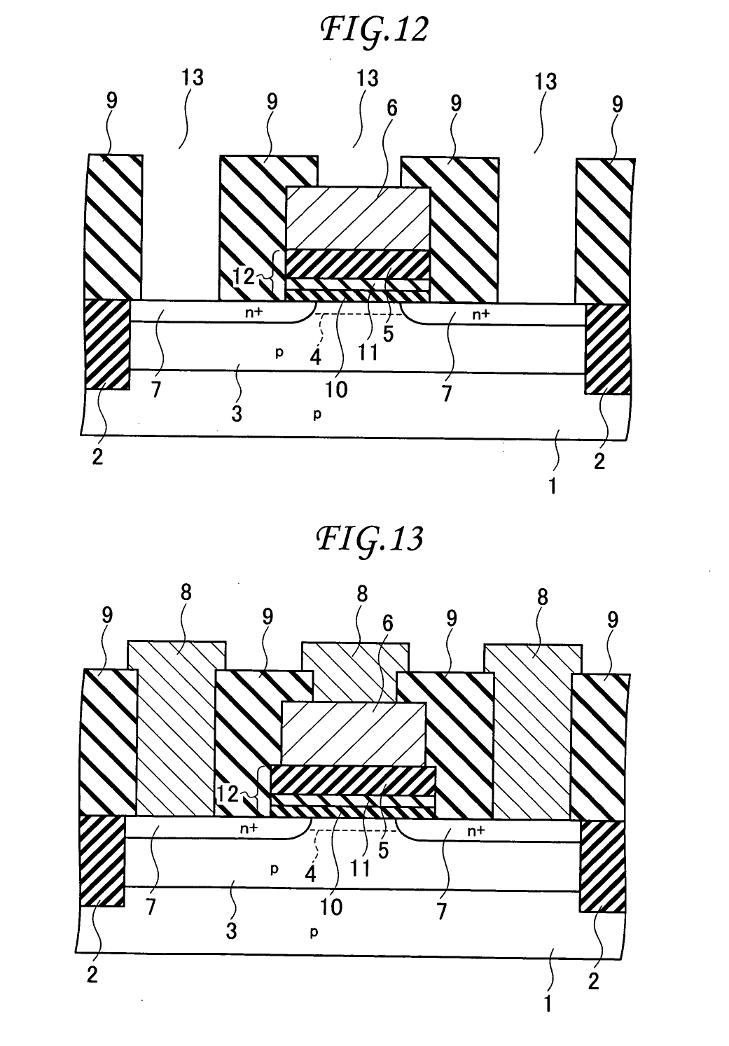

Subsequently, as shown in FIG. 12, a silicon oxide film is deposited as the interlayer insulator films 9 to a depth of 500 nm through CVD (Chemical Vapor Deposition) or the like, and interconnect openings 13 are then formed on the source/drain regions 7 and the gate electrode 6 through RIE or the like.

A 300 nm-thick Al film, for example, containing 1% Si is then formed across the entire surface of the Si substrate 1 through sputtering or the like. Subjecting this Al film to anisotropic etching allows formation of the interconnects 8, forming the field-effect transistor of the embodiment shown in FIG. 4.

The n channel field-effect transistor has been taken as an example in this embodiment; however, usage of an opposite conductivity type of impurity allows usage of this invention for a p channel field-effect transistor. Moreover, implanting an impurity only in a specified region in the substrate through a method such as photo etching allows usage of the invention for a complementary field-effect transistor. Furthermore, the techniques as described above may be used for a semiconductor apparatus including the n channel field-effect transistor, the p channel field-effect transistor and the complementary field-effect transistors as a part thereof.

Additionally, the techniques can be used to form field-effect transistors as a part of a semiconductor including elements other than the field-effect transistor, a different active device such as a bipolar transistor or a single-electron transistor, a passive device such as a resistive element, a diode, an inductor or a capacitor, or an element configured of a ferroelectric or an element made of a magnetic material. Similarly, even in the case of forming field-effect transistors as a part of an opto-electronic integrated circuit (OEIC) or a micro-electromechanical system (MEMS), the same techniques can be used. Furthermore, the same holds for a device with a silicon on insulator (SOI) structure and a FIN-type or columnar structured device.

In the present embodiment, As is used as an impurity for forming the n-type semiconductor layer, and B is used as an impurity for forming the p-type semiconductor layer. Alternatively, a different group V impurity may be used for forming the n-type semiconductor layer, and a different group III impurity may be used for forming the p-type semiconductor layer. Moreover, introduction of group III or group V impurities may be performed using a compound containing both such impurities.

With the present embodiment, introduction of an impurity is performed through ion implantation; however, a method other than ion implantation such as solid phase diffusion or vapor phase diffusion may be used. Moreover, a deposition and a growth method for a semiconductor containing impurities may also be used.

In the present this embodiment, a device with a single drain structure is described; however, a device with a structure other than a single drain structure such as an extension structure, a lightly doped drain (LDD) structure or a graded doped drain (GDD) structure may be constructed. Moreover, a device with a halo structure, a pocket structure or an elevated structure may be used.

In the present embodiment, formation of the source/drain regions is performed after the gate electrode and the gate insulator film are processed; however, the order thereof is not essential, and may be performed in the reverse order. There are cases where thermal treatment is not preferable depending on the material of the gate electrode and the gate insulator film. In such case, introduction of an impurity into a source/drain region to be performed prior to processing of the gate electrode and the gate insulator film is preferred.

In the present embodiment, formation of metallic layers for interconnects is performed through sputtering; however, the metallic layers may be formed using a different method other than sputtering, such as deposition. Furthermore, a method such as selective growth of a metal or damascene may be used. Moreover, the metallic material for interconnects does not need to be aluminum (Al) containing Si, and a different metal such as copper (Cu) may be used instead. Cu is appropriate especially since it has low resistivity.

Furthermore, in the embodiment, the gate electrode is made of a refractory metal; however, the gate electrode may be made of a semiconductor such as a polycrystalline silicon, monocrystalline silicon or amorphous silicon, a metal other than a refractory type, a compound containing a metal, or stacked layers thereof. Gate resistance is controlled by forming a gate electrode with a metal or a compound containing a metal so that a device can operate at a high speed, which is favorable.

In the embodiment, a silicide process is not mentioned; however, a silicide layer may be formed on the source and the drain region. Moreover, a method of depositing or growing a layer containing a metal on the source and the drain region may also be used. In this way, the resistance of the source and the drain region may be favorably reduced. Furthermore, in the case of forming the gate electrode with a polycrystalline silicon, the gate electrode or a part thereof may be processed to have a silicide layer. When a silicide layer is formed, the gate resistance is favorably reduced.

In the embodiment, the upper portion of the gate electrode has a structure exposing the electrode; however, an insulating material such as silicon oxide, silicon nitride or oxidized and nitrided silicon may be provided on that upper portion. This is particularly true in the case where the gate electrode is made of a material containing a metal and a silicide layer is formed on the source and the drain region. This is also true in the case where protecting the gate electrode during the fabrication process is necessary, in which a protective material such as silicon oxide, silicon nitride or oxidized and nitrided silicon needs to be provided on the upper portion of the gate electrode.

In the embodiment, gate sidewalls are not mentioned; however, sidewalls may be provided to the gate electrode. Providing gate sidewalls made of a high dielectric material is particularly favorable since the electric field within the gate insulator film in the vicinity of the gate electrode lower edge is weakened, providing an advantage of improvement in the reliability of the gate insulator film.

In the embodiment, formation of the gate electrode is performed through a method of depositing a gate electrode material and then subjecting the gate electrode material to anisotropic etching. However, the gate electrode may be formed through a method of embedding or the like such as the damascene process. In the case of forming the source and the drain region prior to formation of the gate electrode, employing the damascene process is preferred since the source and the drain region and the gate electrode are formed in a self-aligning manner.

In the embodiment, the lengths of the upper and lower portion of the gate electrode along the main component of current flowing through the device are equal; however, this is not essential. For example, the gate electrode may have a T-shape where the length along the upper portion of the gate electrode is longer than the lower portion. Another advantage of reduction in the gate resistance may also be obtained in this case.

In the embodiment, a silicon oxide film, which is formed by being exposed to a heated oxygen gas, is used as the closest insulator film to the semiconductor among the insulator films forming the gate insulator film. However, the insulator film may be made of silicon nitride or oxidized and nitrided silicon, for example. However, since few charges or few impurity energy levels existing in the insulator film or at the interface between the insulator film and the semiconductor substrate are favorable, usage of silicon oxide in light of this situation is preferred. On the other hand, from the viewpoint of preventing diffusion of an impurity in the channel region when using a semiconductor as the gate electrode, usage of silicon nitride or oxidized and nitrided silicon is preferred since they are known to allow control of impurity diffusion due to existence of nitrogen. Furthermore, the fabrication method is not limited to heated oxygen gas exposure, and deposition, for example, may be used, and exposure to an excited oxide gas without an increase in temperature may be performed. Formation by a method of exposing to an excited oxygen gas without an increase in temperature allows control of changes in impurity concentration distribution within the channel regions due to diffusion, and is thus appropriate. Furthermore, in the case of using oxidized and nitrided silicon, first, the silicon oxide film is formed, and subsequently nitrogen may be introduced in the insulator film by exposing that formed film to a gas containing nitrogen with an increased temperature or excited nitrogen.

In the embodiment, a TiO₂ film, which is formed through sputtering as the second insulator film counting from the semiconductor substrate among the insulator films forming the gate insulator film, is used; however, a different high dielectric film may be used such as an insulator film containing an oxide of a valence of Ti, BaO, BaTiO₃, BaWO₄, BaZnGeO₄, Bi₁₂GeO₂₀, Bi₁₂SiO₂₀, Bi₁₂TiO₂₀, CaMoO₄, CaYAlO₄, Dy₂Ti₂O₇, EuAlO₃, Eu₃NbO₇, EuO, Gd₃NbO₇, Ho₂Ti₂O₇, LaAlO₃, La₂Be₂O₅, La₂CuO₄, LaTi₂O₇, LiNbO₃, LiTaO₃, MnO, Nb₂O₅, NdAlO₃, Nd₂Ti₂O₇, PbF₂, Pb₅GeV₂O₁₂, PbMoO₄, PbO, PbWO₄, PrAlO₃, SrMoO₄, SrTiO₃, SrWO₄, Ta₂O₅, TeO₂, UO₂, Yb₂Ti₂O₇, an oxide of a valence of a metal, or any one of these added with nitrogen. As is described with reference to FIG. 2, a sufficiently high dielectric constant, particularly a higher dielectric constant than the square root of the product of the dielectric constants of the closest insulator film to the semiconductor substrate and the third insulator film counting from the semiconductor substrate is essential for the second insulator film, counting from the semiconductor substrate. Therefore, this embodiment does not prove fully effective when using a closest insulating film to the substance with a low dielectric constant such as silicon nitride or oxidized and nitrided silicon as the second insulator film. Furthermore, the fabrication method for the insulator film is not limited to sputtering, and a different method may be employed such as vapor deposition, chemical-vapor deposition (CVD), or epitaxial growth. Moreover, in a case such as using an oxide of a certain substance as the insulator film, a method such as forming a film made of that substance and then oxidizing the film may be employed.

In the embodiment, a hafnium oxide film (HfO₂ film) formed through sputtering is used as the third insulator film, counting from the semiconductor substrate, from among the insulator films forming the gate insulator film. However, a different high dielectric film may be used as the gate insulator film such as an insulator film containing an oxide of a valence of hafnium (Hf), an oxide of a different metal such as zirconium (Zr), titanium (Ti), scandium (Sc), yttrium (Y), tantalum (Ta), Al, lanthanum (La), cerium (Ce), praseodymium (Pr) or an element from the lanthanoid group, a silicate material containing various elements including these and other elements, or any one of these added with nitrogen, or a different insulator film made of stacked layers thereof. When nitrogen exists in the insulator film, only a certain element being crystallized and then precipitated may be controlled. It should be noted that this embodiment is established for reducing scattering of carriers due to the charges existing in the third insulator film, counting from the semiconductor substrate, or at the interface between the third and the second insulator film, counting from the semiconductor substrate. Therefore, the effects of this embodiment are significant when there are abundant charges such as in the case of using a metal oxide as the third insulator film. Furthermore, the fabrication method for the insulator film is not limited to sputtering, and a different method may be employed such as vapor deposition, CVD, or epitaxial growth. Moreover, in a case such as using an oxide of a certain substance as the insulator film, a method such as forming a film made of that substance and then oxidizing the film may be employed.

Furthermore, the thickness of each insulator film forming the gate insulator film is not limited to the value of the thickness of each insulator film in this embodiment.

As is described for the above Expression 6, the potential within the semiconductor substrate brought about by the point charges in the stacked insulator film as shown in FIGS. 1 through 3 is represented by the power series exp(−kTⱼ) (Tⱼ denotes the thickness of the j-th layer from the semiconductor substrate.) and k denotes the wavenumber for the potential subjected to the Fourier transform along the in-plane of the insulator film. Considering actual scattering of carriers, contribution of the Fermi wavenumber when assuming the carriers in an inversion layer are two-dimensional gas is large. To exactly approximate the value of the potential in the semiconductor substrate based on the primary term of the power series such as Expression (6), the value of each exp(−kTⱼ) must be appropriately small.

Accordingly, it is preferable that the thickness of an insulator film layer should be comparable to the Fermi wavelength/2π (=1/Fermi wavenumber) or greater when the carriers in the inversion layer are considered as a two-dimensional gas. Assuming the carriers in the inversion layer as two-dimensional ideal Fermi gas, and given that Nᵢₙᵥ denotes the carrier area density within the inversion layer, the Fermi wavelength/2π is given by (πNᵢₙᵥ)^{-1/2}. In addition, given that T denotes the thickness of the gate insulator film when the film is made of an oxide film (SiO₂film thickness allowing formation of an electrical capacitance equal to that of a parallel flat plate capacitor with the same insulator film as the gate insulator film using a parallel flat plate capacitor), and V₀ denotes a difference between the power supply voltage and the threshold voltage, Nᵢₙᵥ when a typical device is in an on-state is given by εₛᵢV₀/T. Therefore, assuming T=1 nm and V₀=1V, which are expected in the generation of several 10 nm long gates, the area density of the carriers in the inversion layer while the typical device is in an on-state is Nᵢₙᵥ=2×10³ cm⁻² and the Fermi wavelength/2π is 1.2 nm. It should be noted that geometrically speaking ‘insulator film thickness’ in this case is a film thickness. Thus, the film thickness being 1.2 nm or greater is consistent with the film thickness in an oxide film thickness equivalent to approximately 1 nm.

Accordingly, the thickness of each insulator film layer is preferably approximately 1.2 nm or greater. Furthermore, when the thickness of each insulator film layer is equal to or greater than the product of the Fermi wavelength and the natural logarithm of 10, each value of exp(−kTⱼ) is equal to 1/10 or less, namely a smaller order of magnitude than the terms not including this exponential function, is more favorable to provide a minute semiconductor device capable of high-speed operations by reducing the scattering of carriers as well as enhancing the controllability of the gate electrode with respect to the potential of the channel region. Accordingly, it is even more favorable when the thickness of each insulator film layer is approximately 2.8 nm or greater. However, in the case of using a substance with a low dielectric constant such as silicon oxide, silicon nitride or oxidized and nitrided silicon as the closest insulator film to the semiconductor substrate, since the electrical capacitance between the channel region and the gate electrode is reduced when that thickness is too thick compared to the value 2.8 nm, controllability of the gate electrode with respect to the potential of the channel region is reduced, which is not favorable to provide a minute semiconductor device capable of high-speed operations by reducing the scattering of carriers as well as enhancing the controllability of the gate electrode with respect to the potential of the channel region. Accordingly, especially with the stacked structure as shown in FIG. 2, it is preferable that thickness of the second or the third insulator film, counting from the semiconductor substrate, is 1.2 nm or greater, even further preferable if it is 2.8 nm or greater.

The present embodiment was devised for reducing scattering of carriers in the semiconductor substrate due to the charges existing in the third insulator film counting from the semiconductor substrate, in a device, using a high dielectric material such as a metal oxide for the gate insulator film, wherein a new insulator film layer is provided to the gate insulator film. Reduction in scattering of the carriers due to the charges in the gate insulator film and the like is important. However, considering an increase in the short channel effect and reduction in current driving capability, reduction in the controllability of the gate electrode with respect to the potential of the channel region is not favorable to provide a minute semiconductor device capable of high-speed operations by reducing the scattering of carriers as well as enhancing the controllability of the gate electrode with respect to the potential of the channel region. Accordingly, with the structure of the embodiment shown in FIG. 4, it is preferable that the thickness of the second insulator film, counting from the semiconductor substrate, which is the essential difference from the comparative example shown in FIG. 125, is not very thick. However, the essential value is not the insulator film thickness geometrically speaking when considering the controllability of the gate electrode with respect to the potential of the channel region, but is a value derived by dividing the insulator film thickness by its dielectric constant. Accordingly, it is preferable that the value derived by dividing the thickness of the second insulator film, counting from the semiconductor substrate, by its dielectric constant is smaller than the value derived by dividing the thickness of the third insulator film, counting from the semiconductor substrate, by its dielectric constant.

In the embodiment, the gate insulator film has a three-layer stacked structure; however, if the relationship between dielectric constant and thickness as described above is satisfied, a gate insulator film with a stacked structure of four or more layers may be formed.

In the embodiment, device isolation is performed through shallow trench isolation; however, a different method such as local oxidation or mesa device isolation may be used.

In the embodiment, post-oxidation after the gate electrode has been formed is not mentioned; however, a post oxidation process may be performed if possible in light of the gate electrode and gate insulator film materials. Moreover, not limited to post-oxidation, rounding the gate electrode lower edge may be performed through a method such as chemical processing or exposure to a reactive gas. When these processes are possible, the electric field at the gate electrode lower edge is relaxed therethrough.

In the embodiment, a silicon oxide film is used as the interlayer insulator film. However, a substance other than silicon oxide such as a low dielectric material may be used for the interlayer insulator film. Lowering the dielectric constant of the interlayer insulator film allows reduction in device parasitic capacitance, thereby providing an advantage of achieving high-speed operations of the device.

Furthermore, with regard to contact holes, self-aligned contacts may be formed. The device area may be reduced using self-aligned contacts, thereby improving the scale of integration.

In the embodiment, the case of a semiconductor device with only a single layer of interconnect is described; however, devices and/or interconnects may be made of two or more layers. The degree of device integration increases in that case.

In the embodiment, the gate insulator film is removed from the source and the drain region; however, it may be retained. For example, since dose losses are prevented when forming the source and the drain region through ion implantation after the gate electrode has been formed, removing the gate insulator film on the source and the drain region is preferred. Furthermore, removal is necessary when forming a silicide layer in the source and the drain region. Moreover, the removal method is not limited to RIE, and a method such as CDE or wet processing may be employed.

### MODIFIED EXAMPLE OF THE FIRST EMBODIMENT

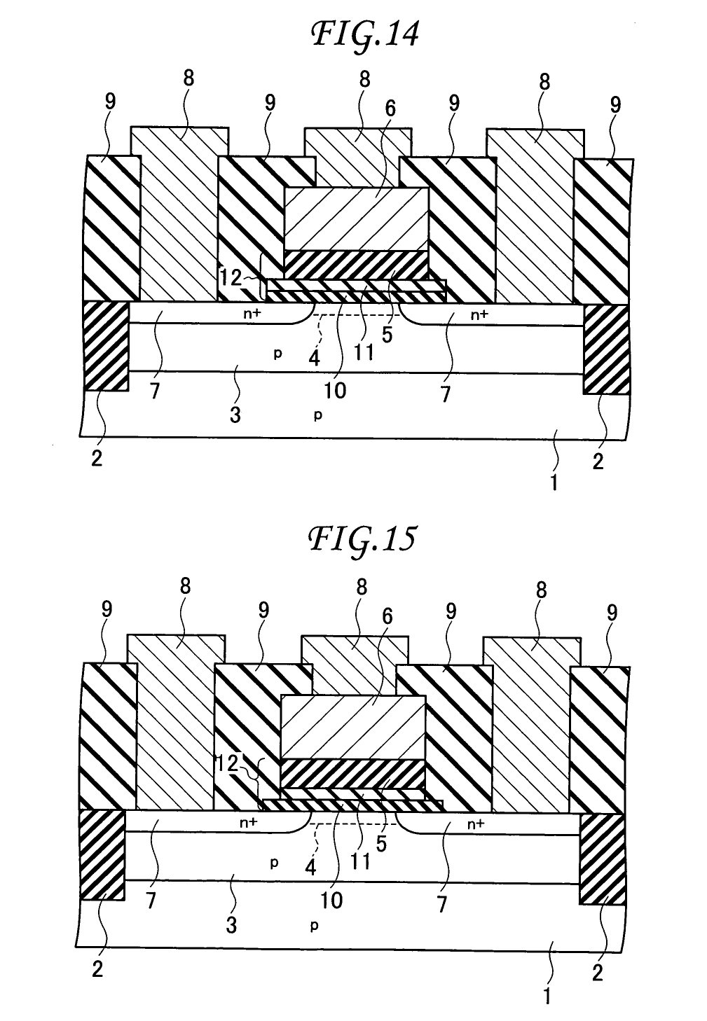

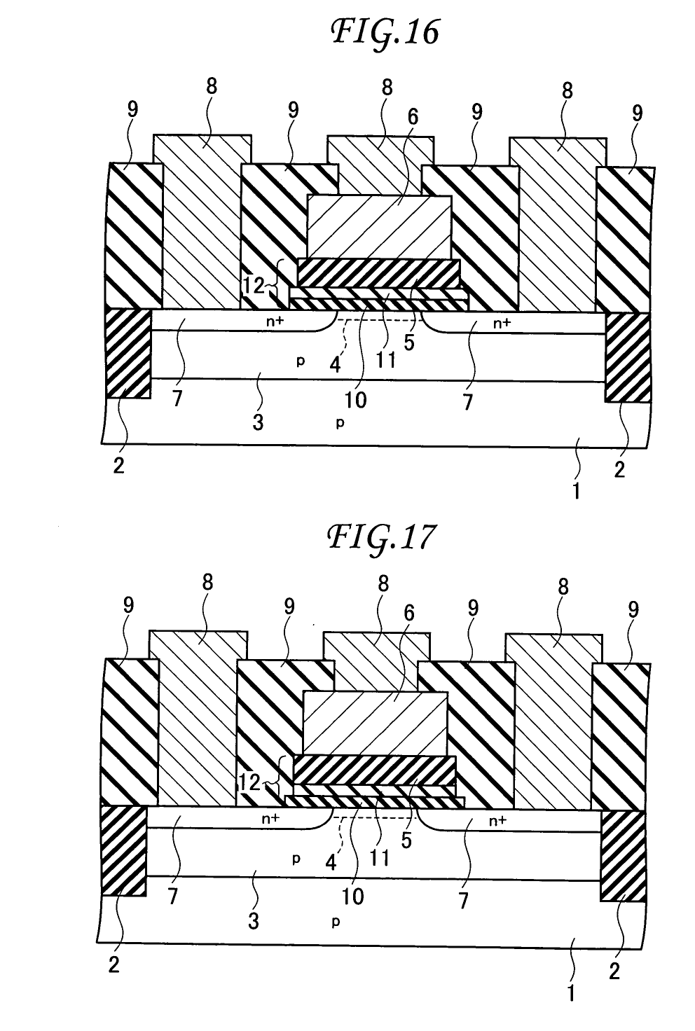

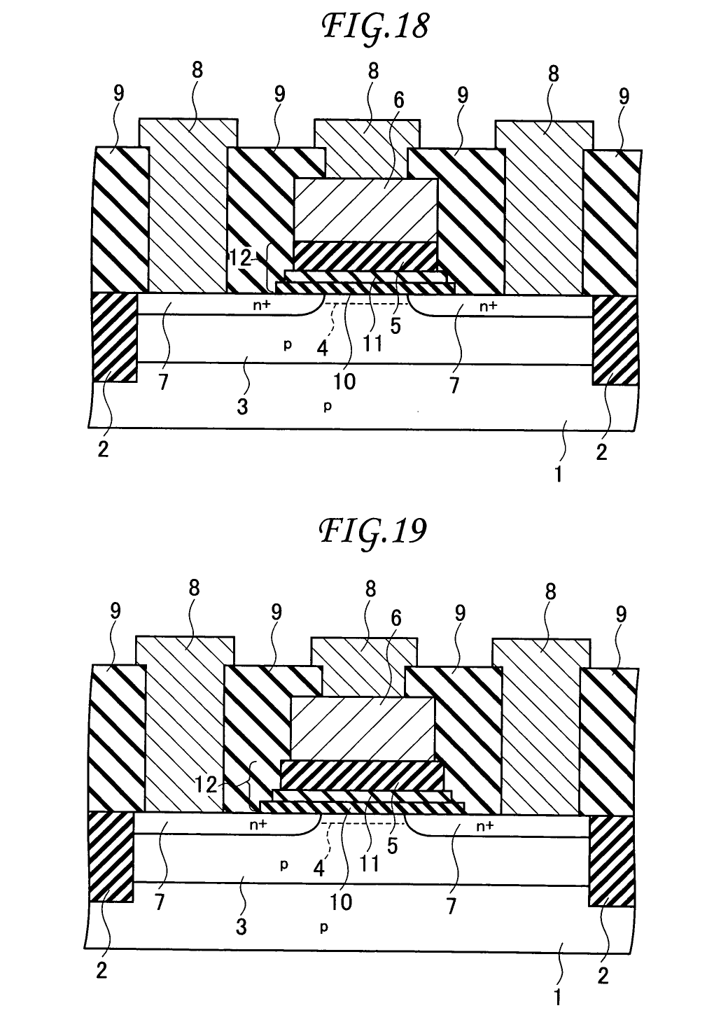

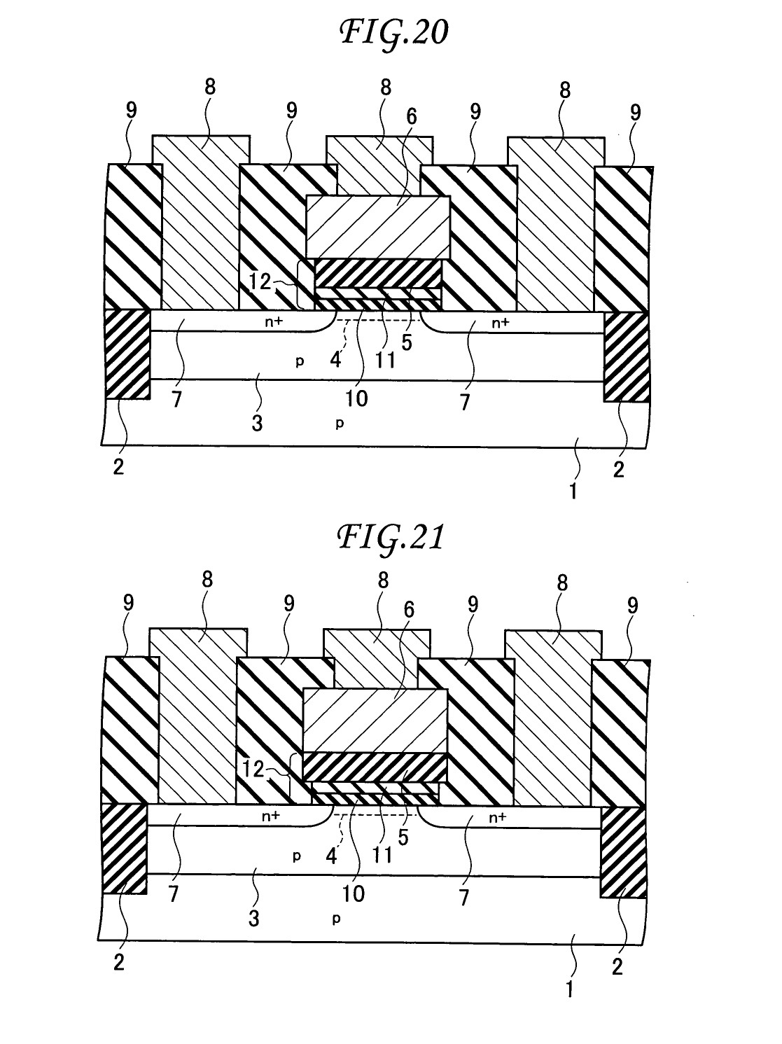

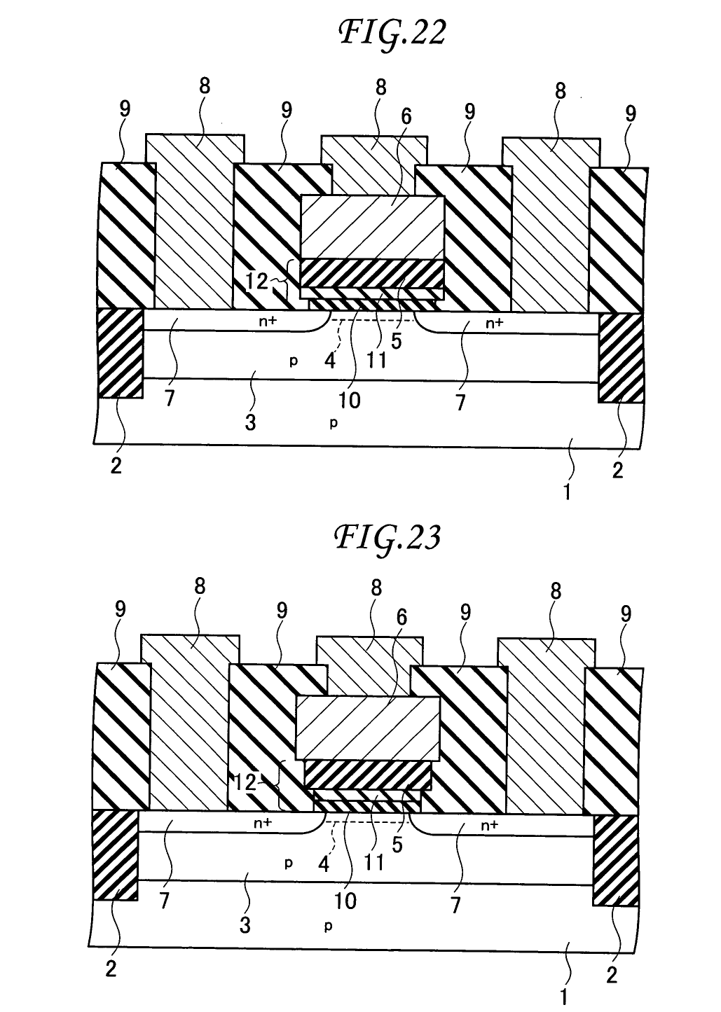

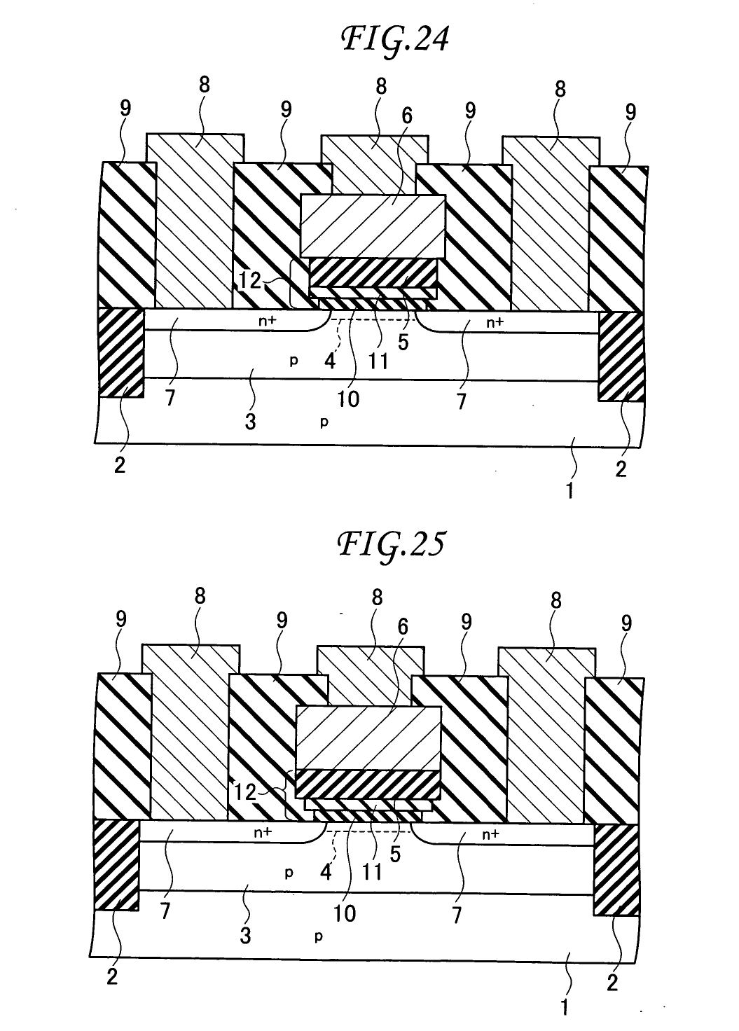

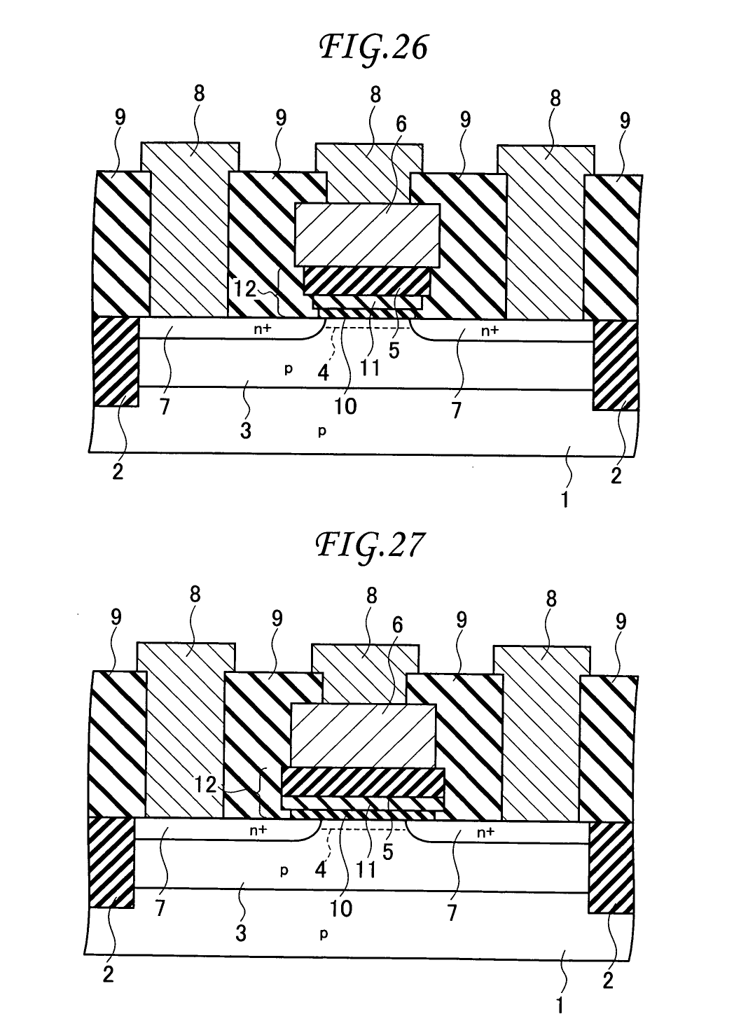

In the embodiment, sidewalls of the gate insulting film 12 with a stacked structure as shown in FIG. 4 are processed, so as to match the gate electrode 6. However, the gate insulator film 12 with a stacked structure as shown in FIGS. 13 through 19, for example, may be processed, so as to overhang from the gate electrode 6. By doing so, the capacitive coupling between the source/drain regions 7 and the gate electrode 6 is strengthened. Therefore, advantages of reducing the resistance of the source/drain regions 7, controlling the parasitic capacitance as well as allowing high-speed operations are obtained. Furthermore, the gate insulator film 12 with a stacked structure as shown in FIGS. 20 through 26 may be processed, so as to be further inward than the gate electrode 6. By doing so, the electrical capacitance to be formed between the gate electrode 6 and the source/drain regions 7 decreases. Therefore, advantages of reducing the parasitic capacitance as well as allowing high-speed operations are obtained. Moreover, by processing the stacked gate insulator film 12 so as to be further inward than the gate electrode 6, an advantage of a relaxed electric field in the stacked gate insulator film 12 near the gate electrode 6 lower edge is obtained.

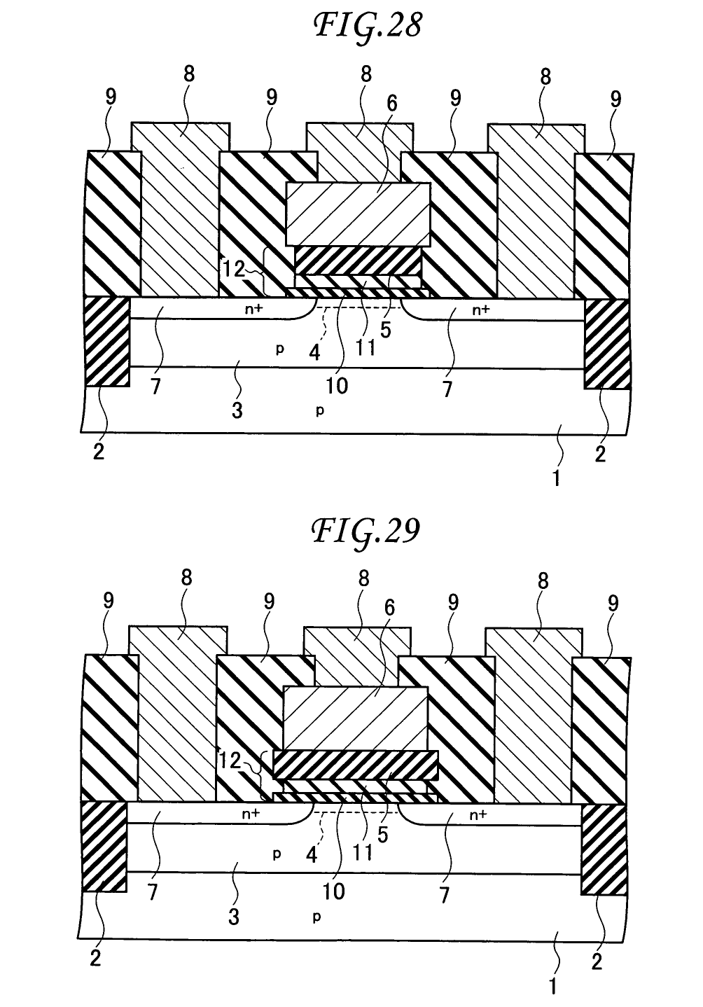

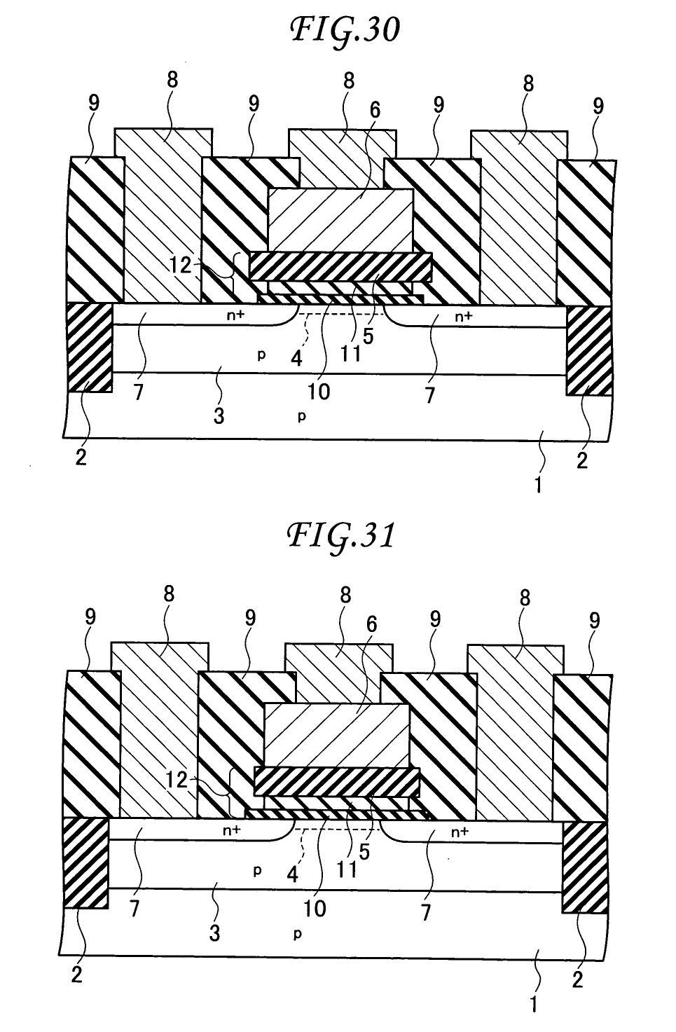

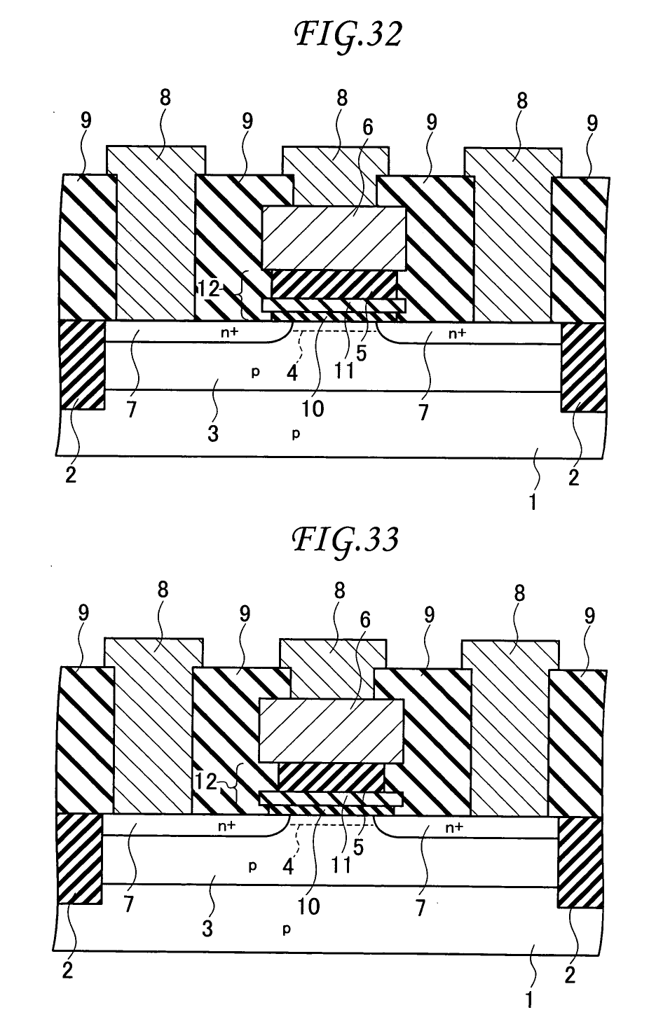

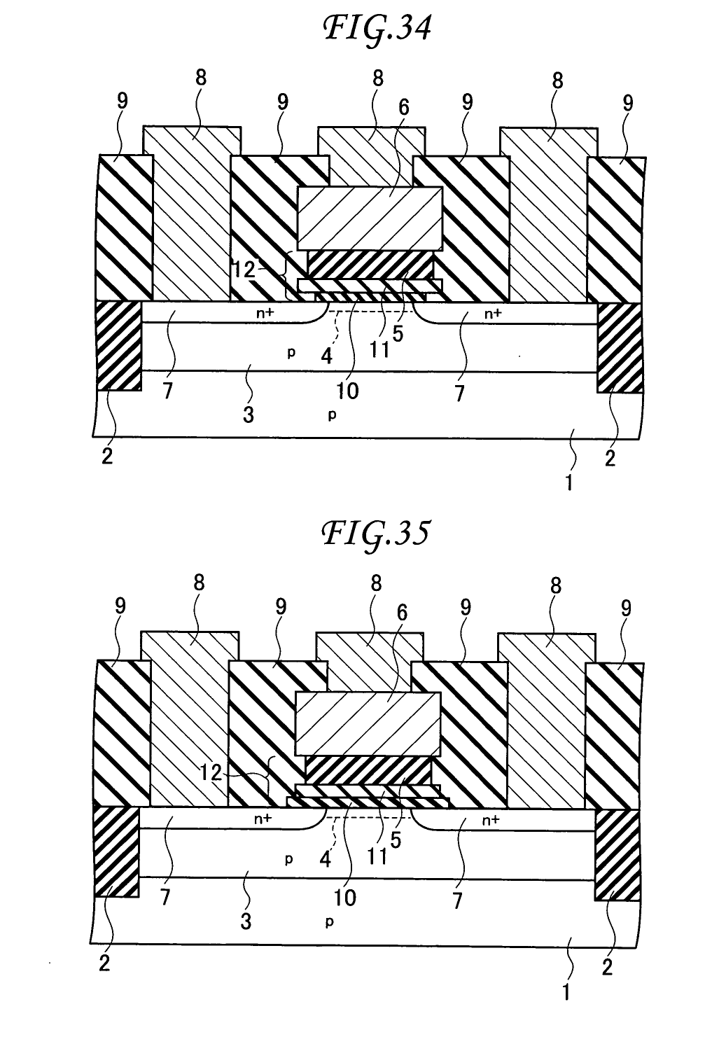

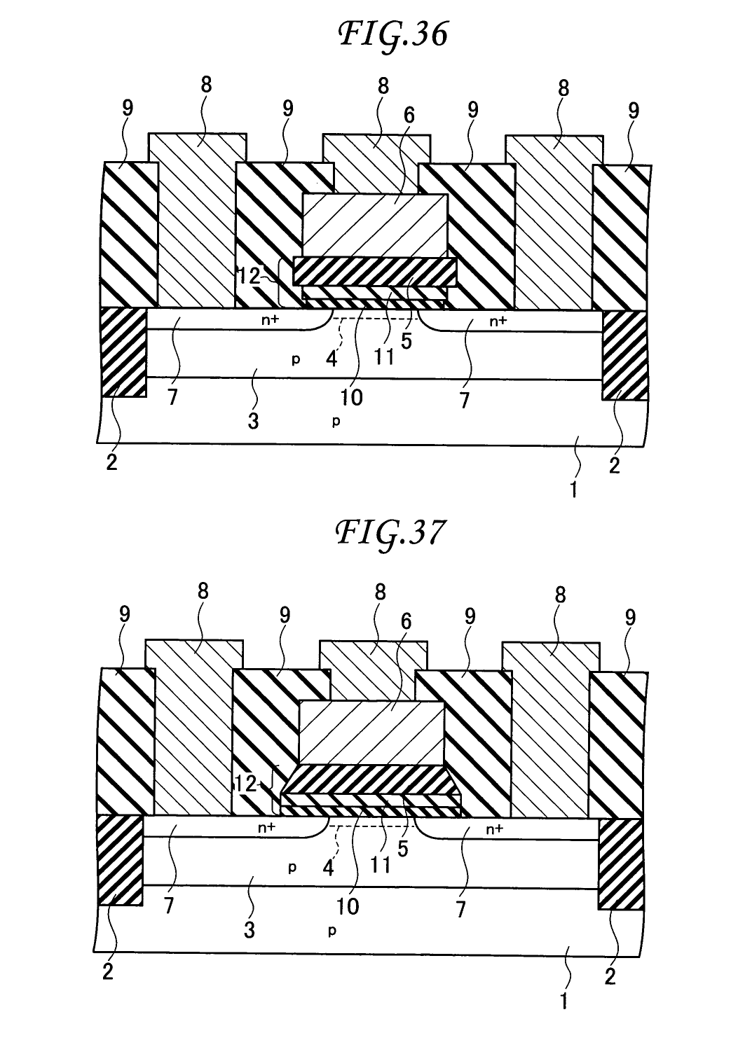

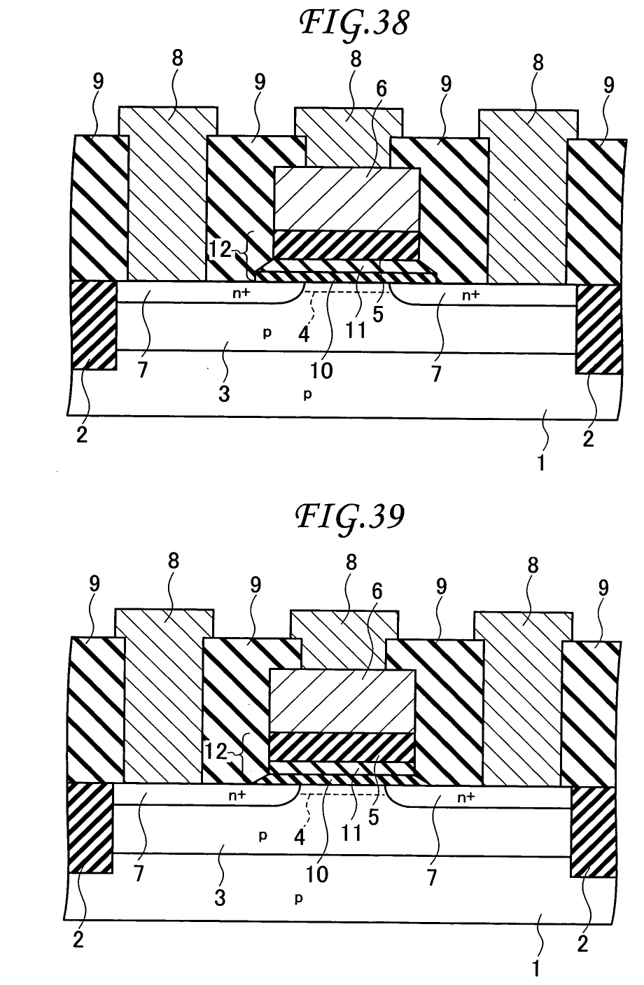

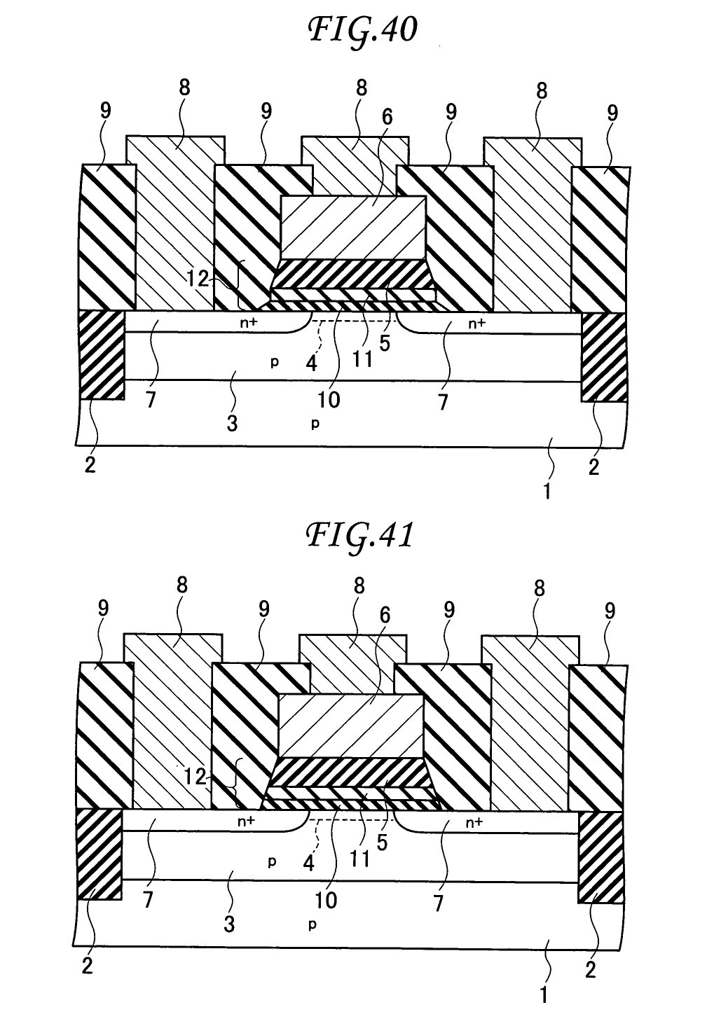

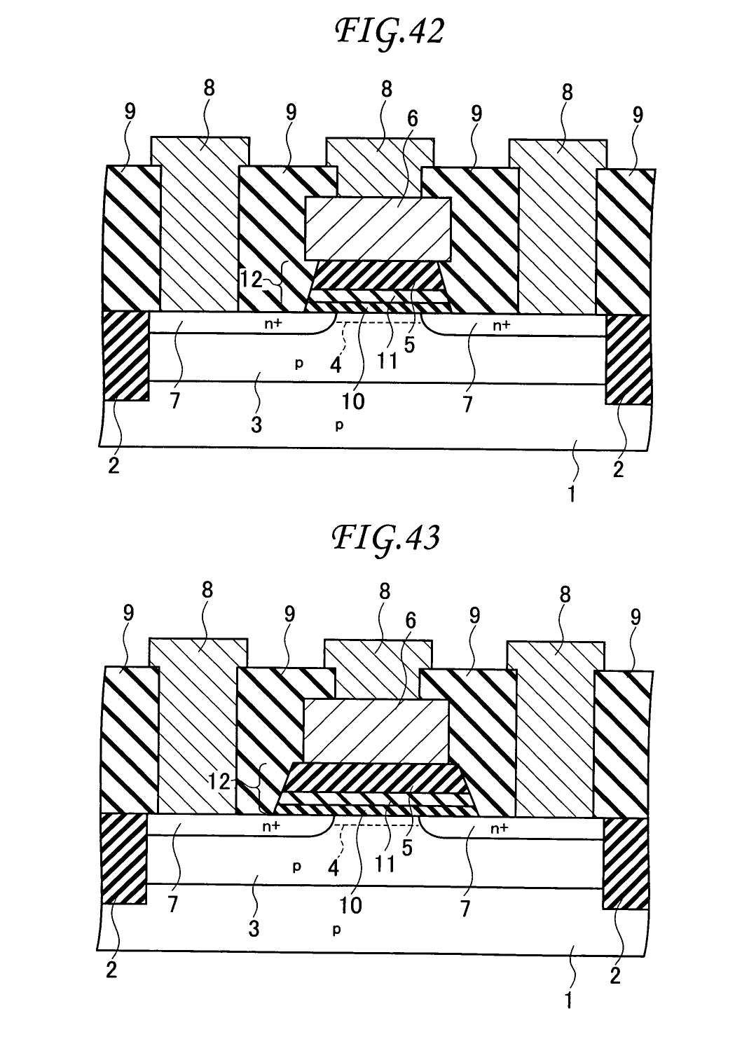

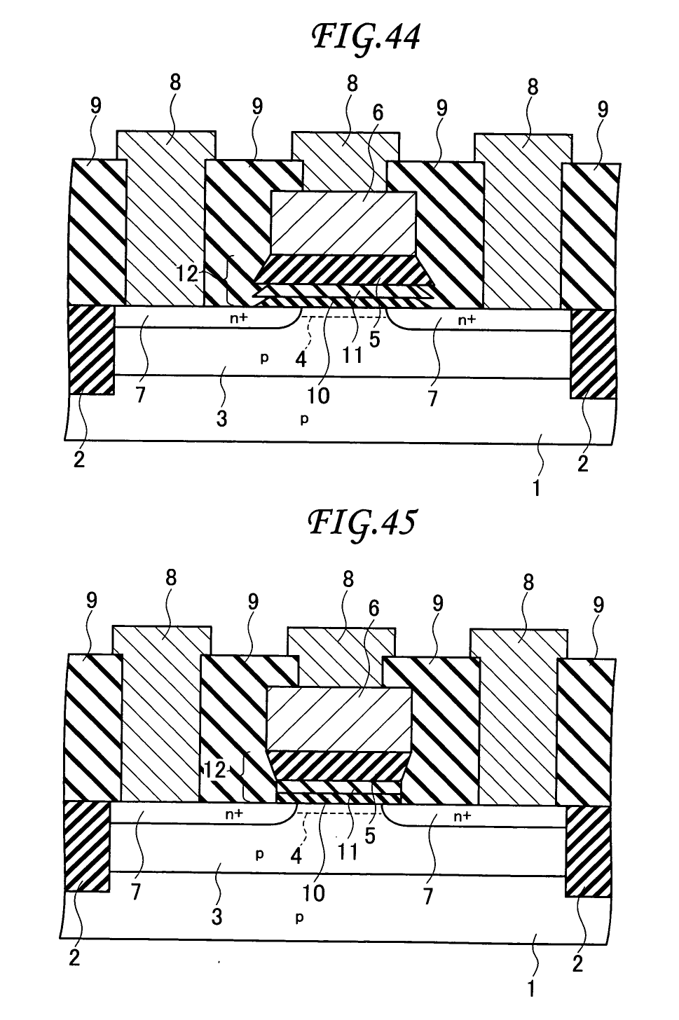

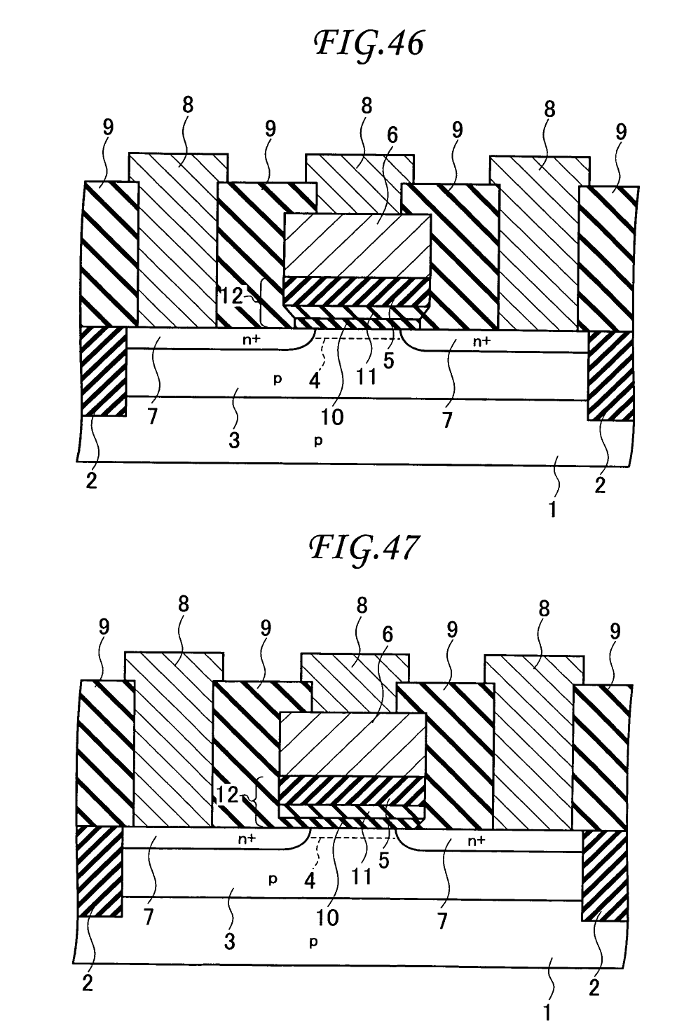

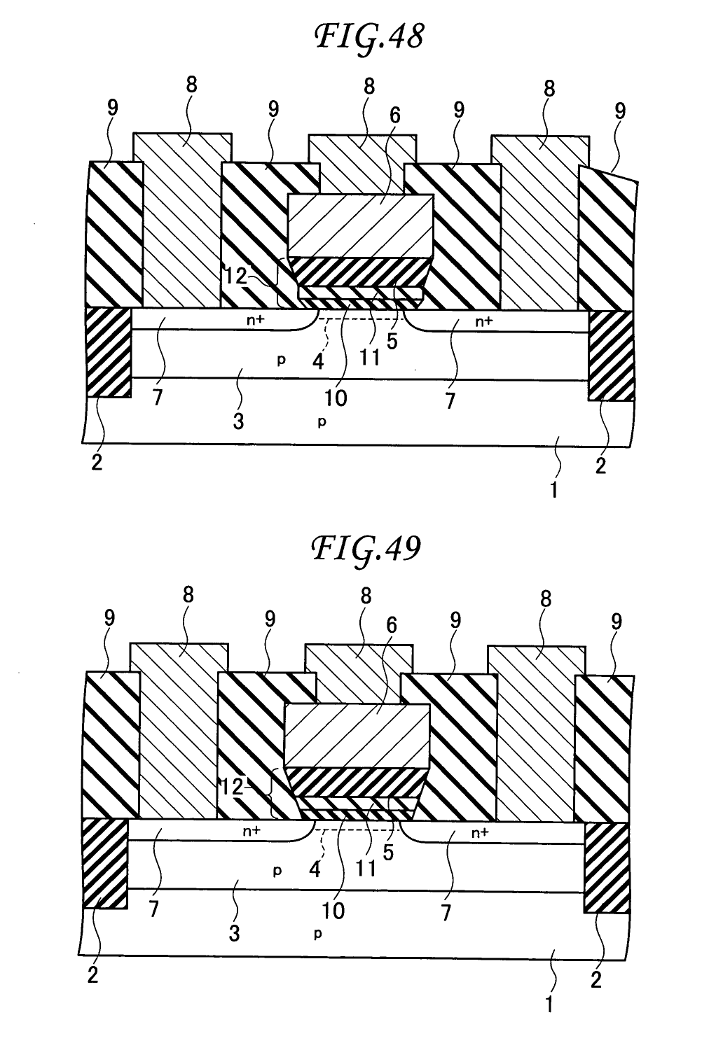

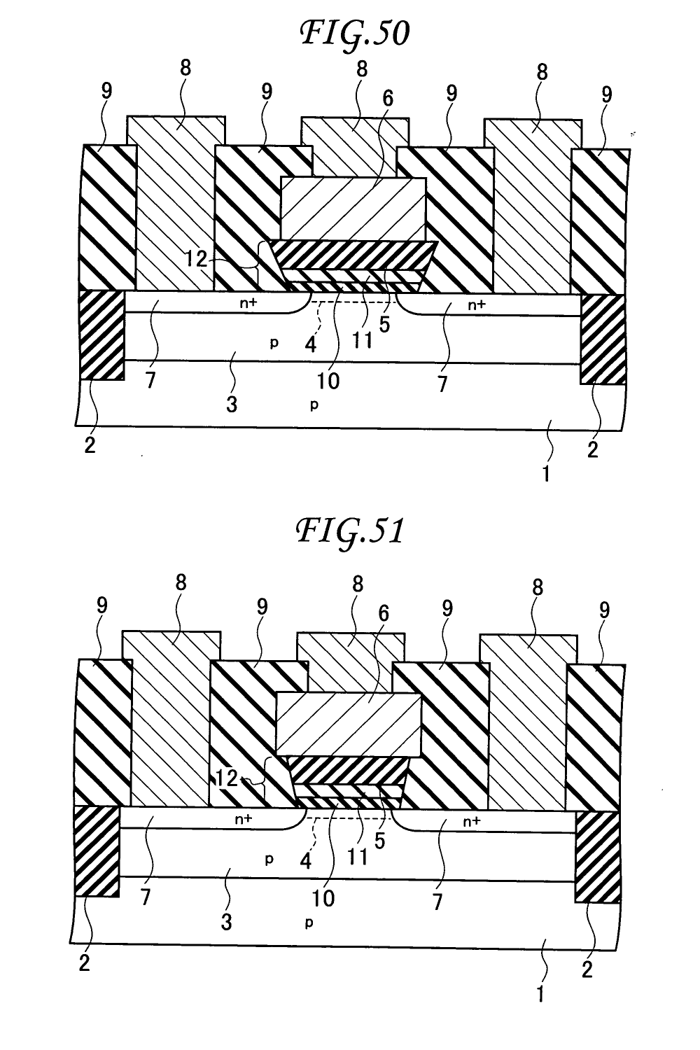

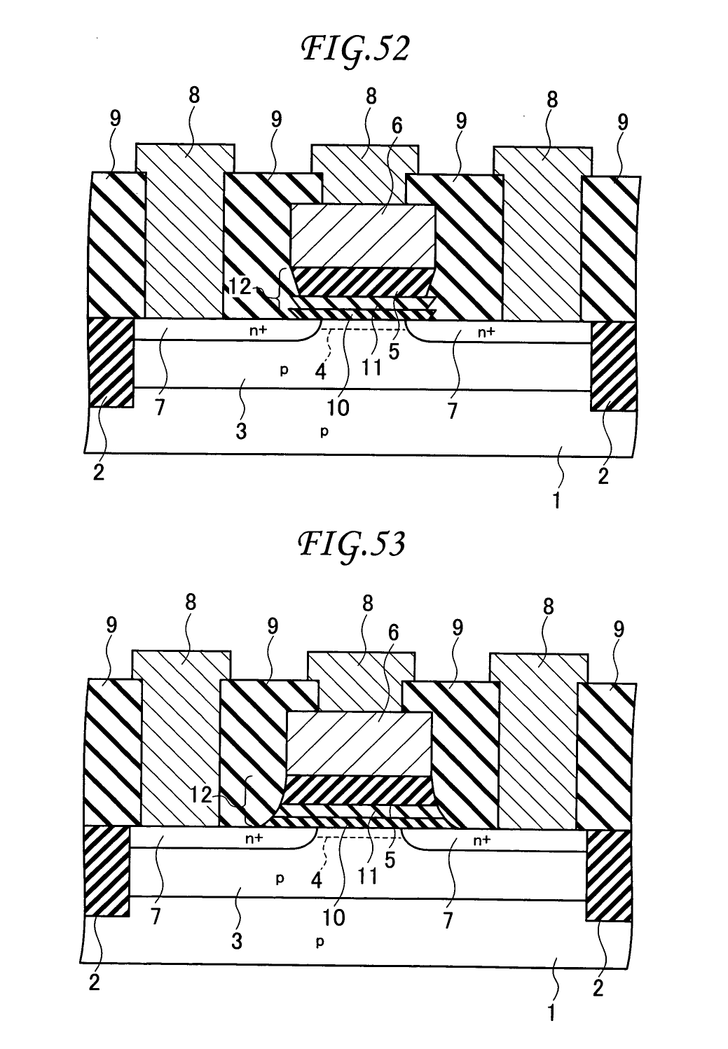

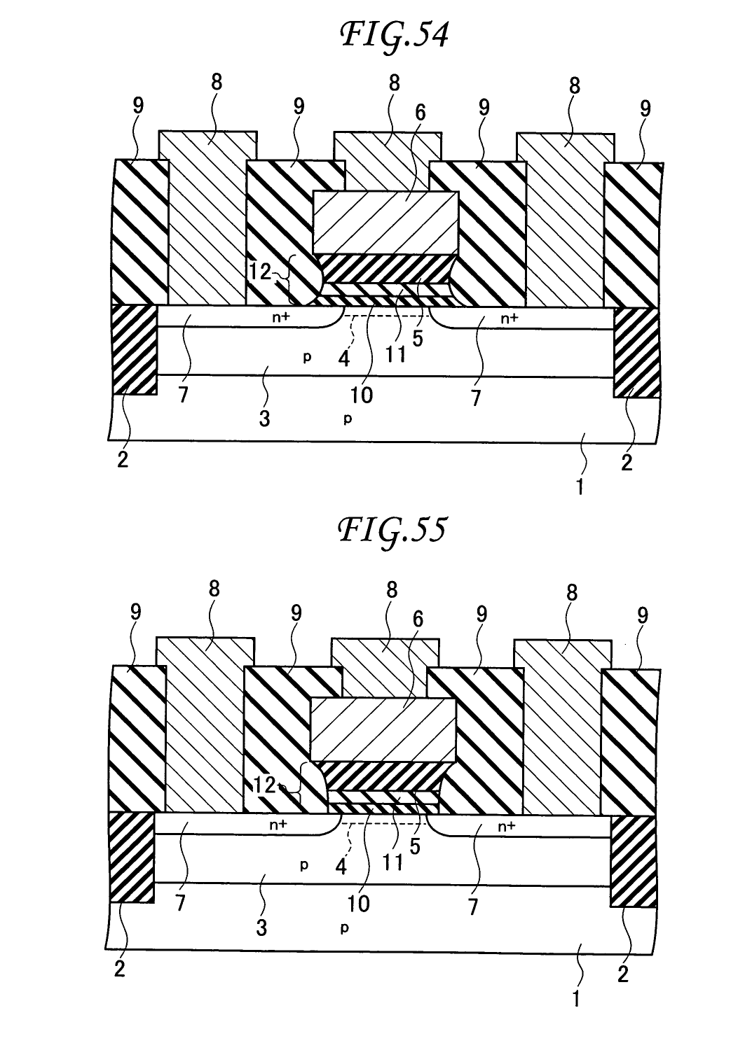

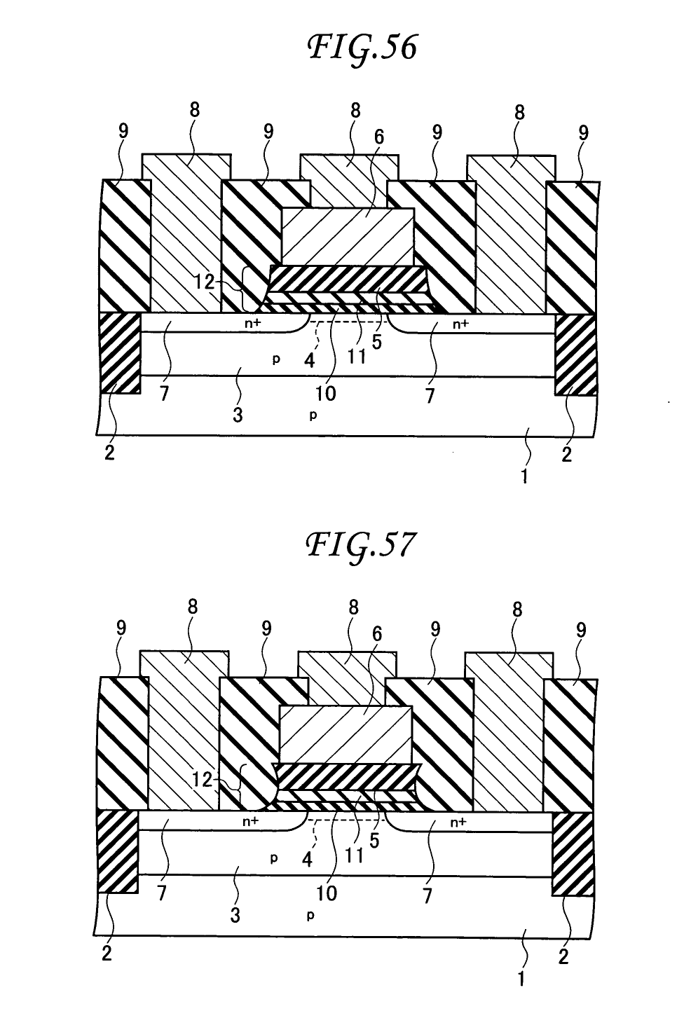

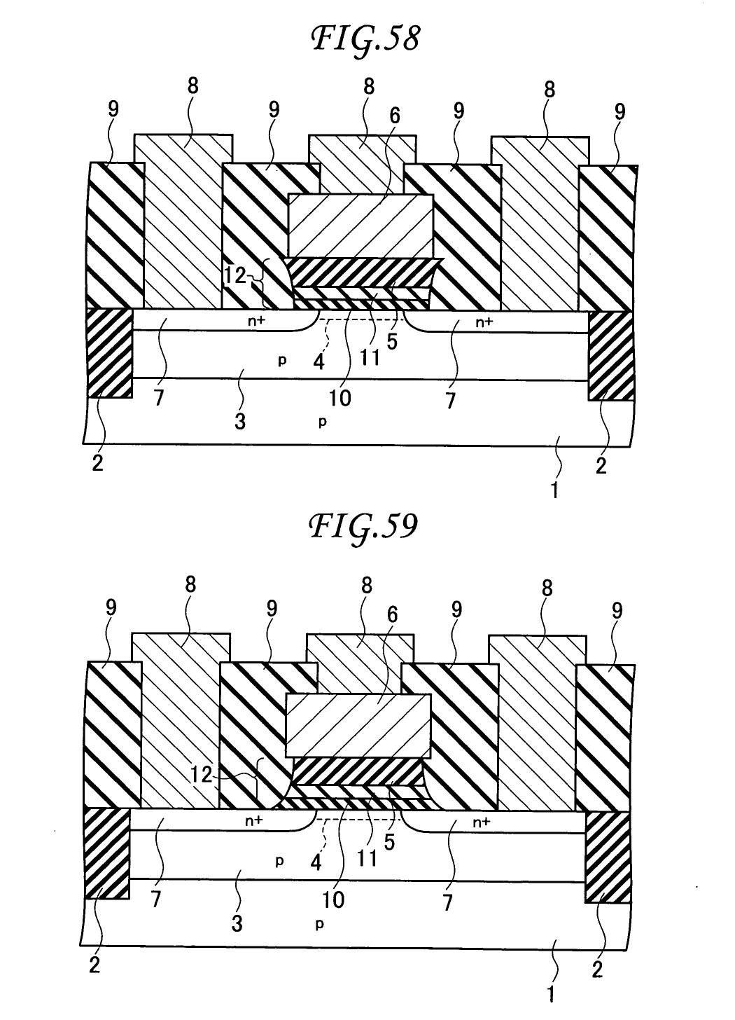

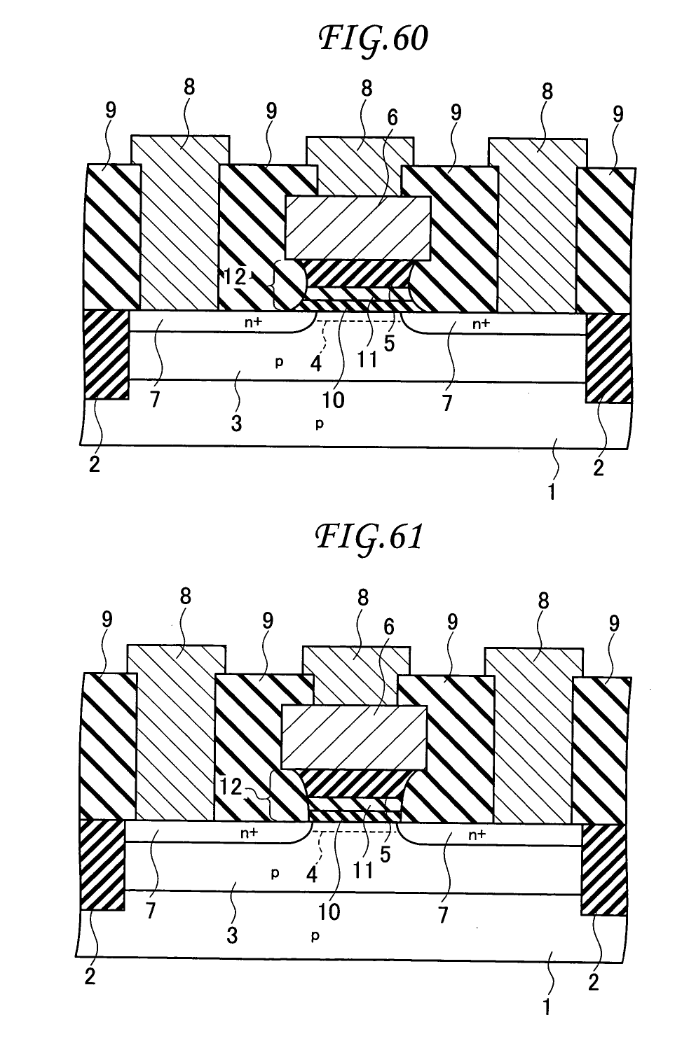

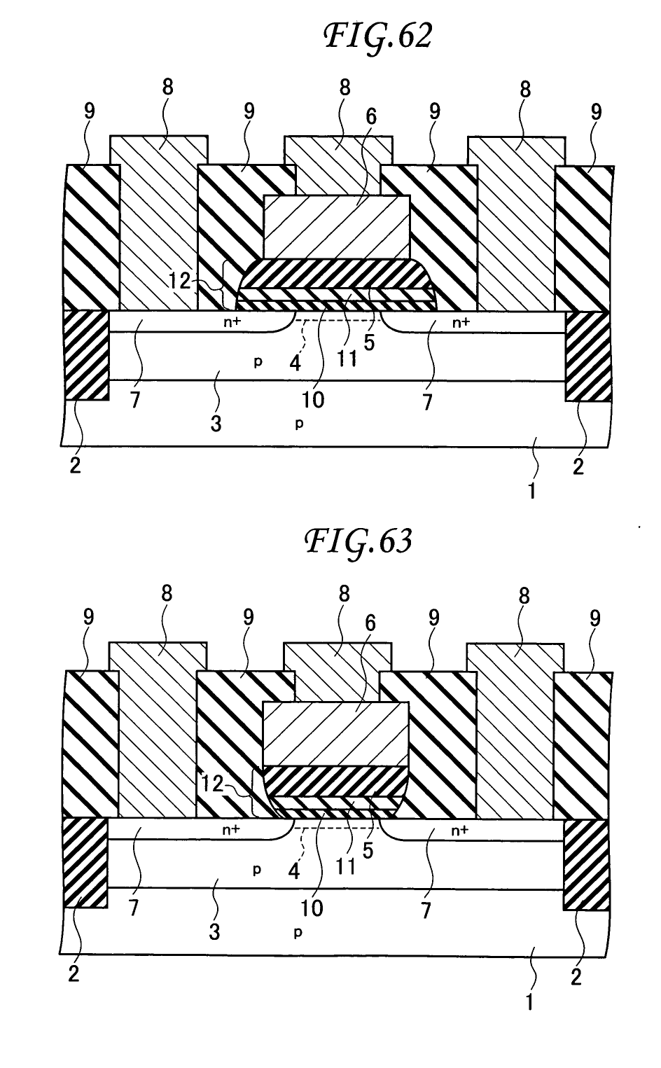

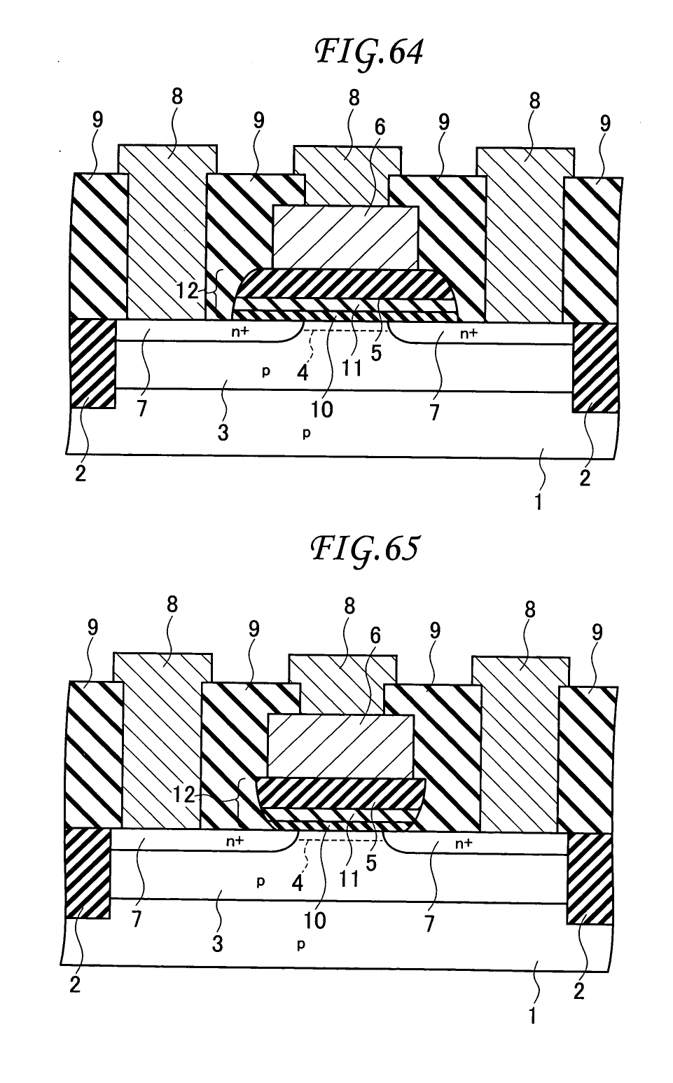

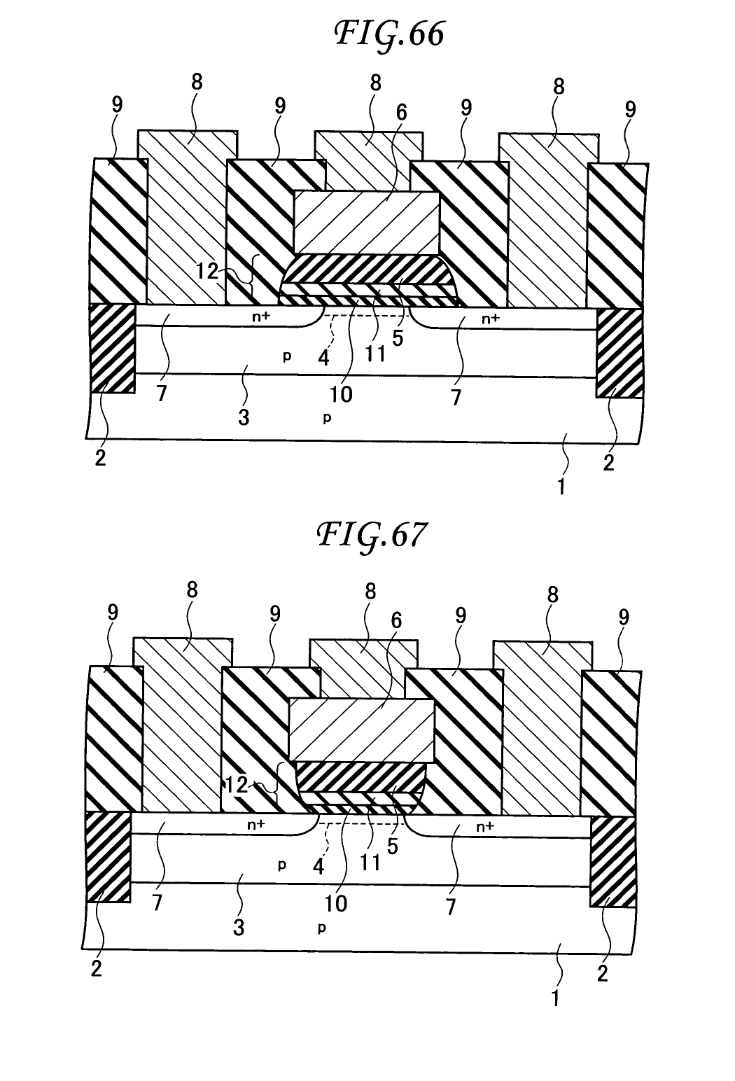

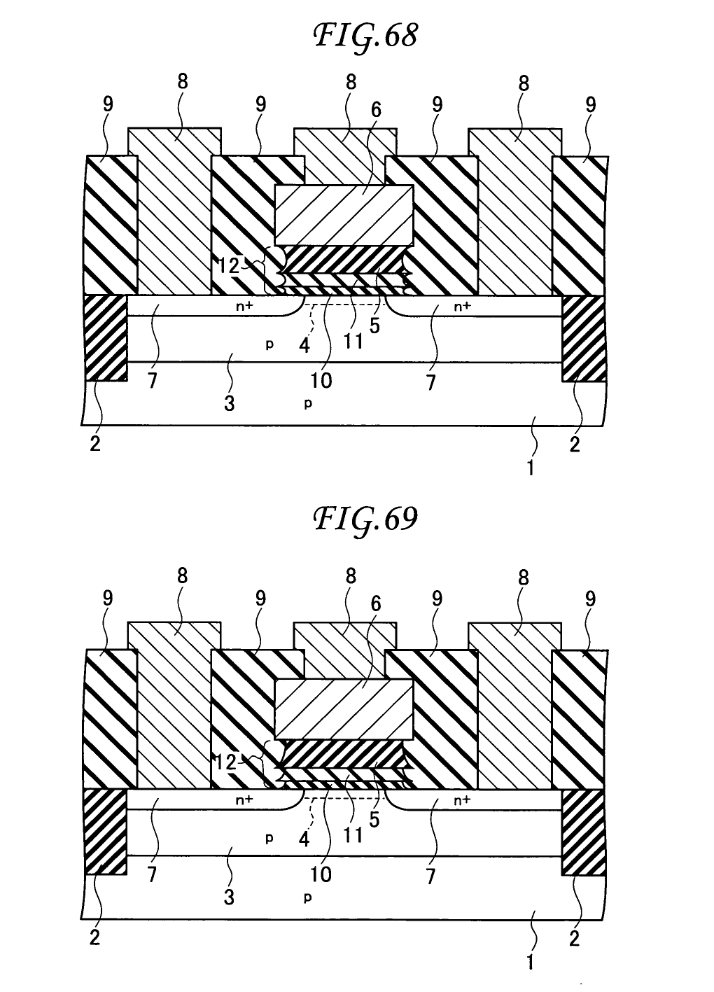

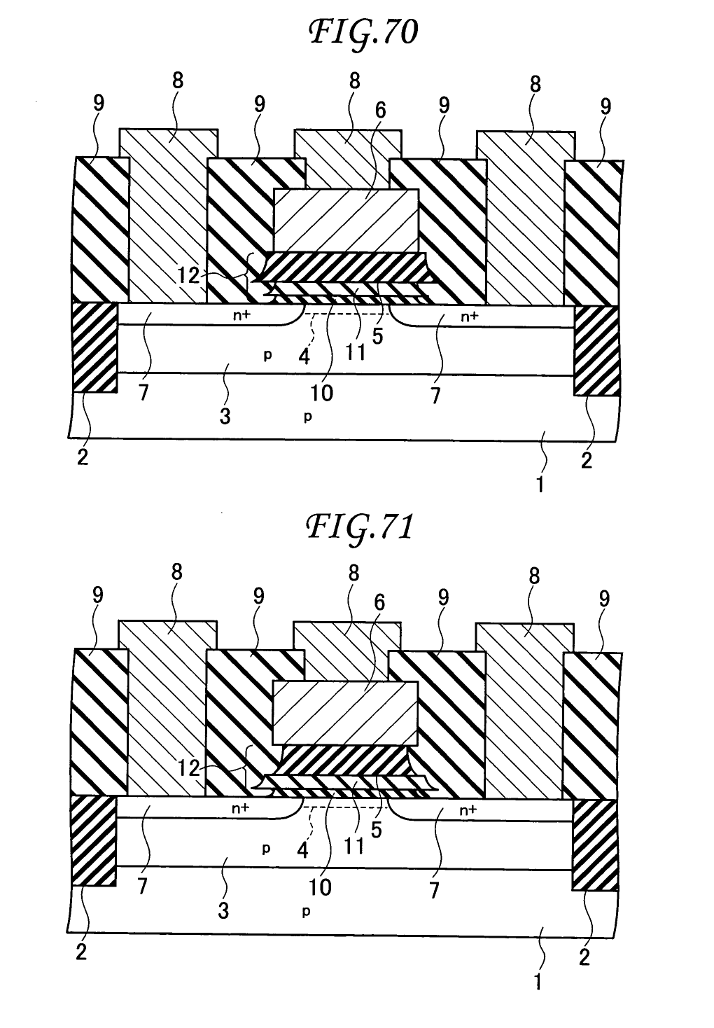

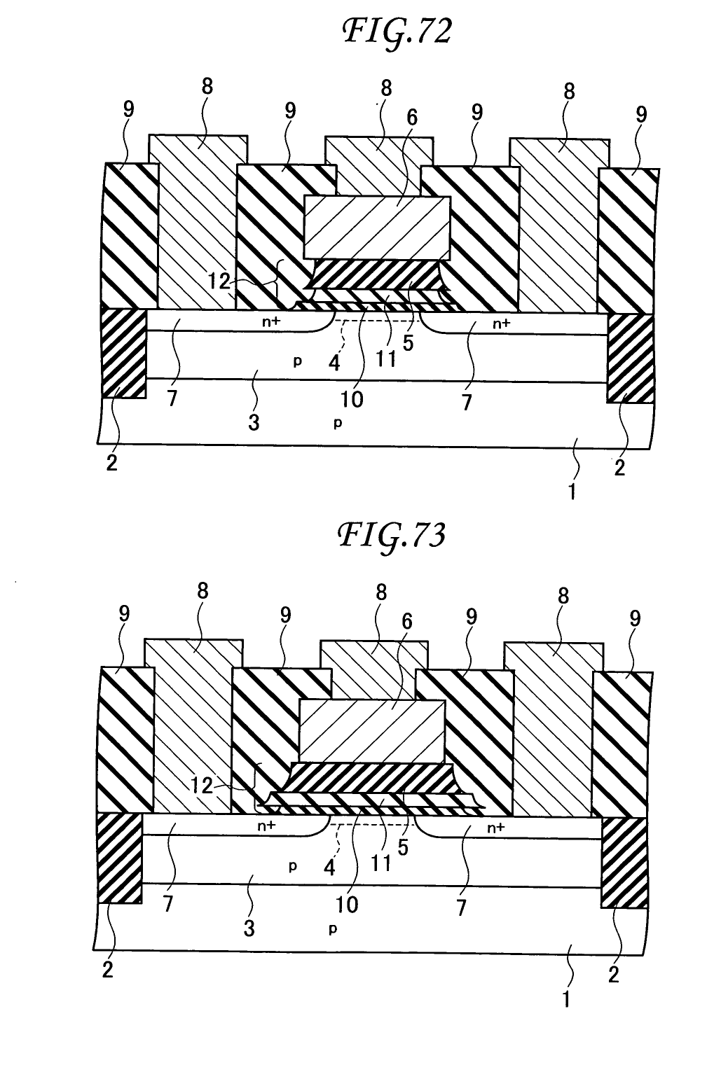

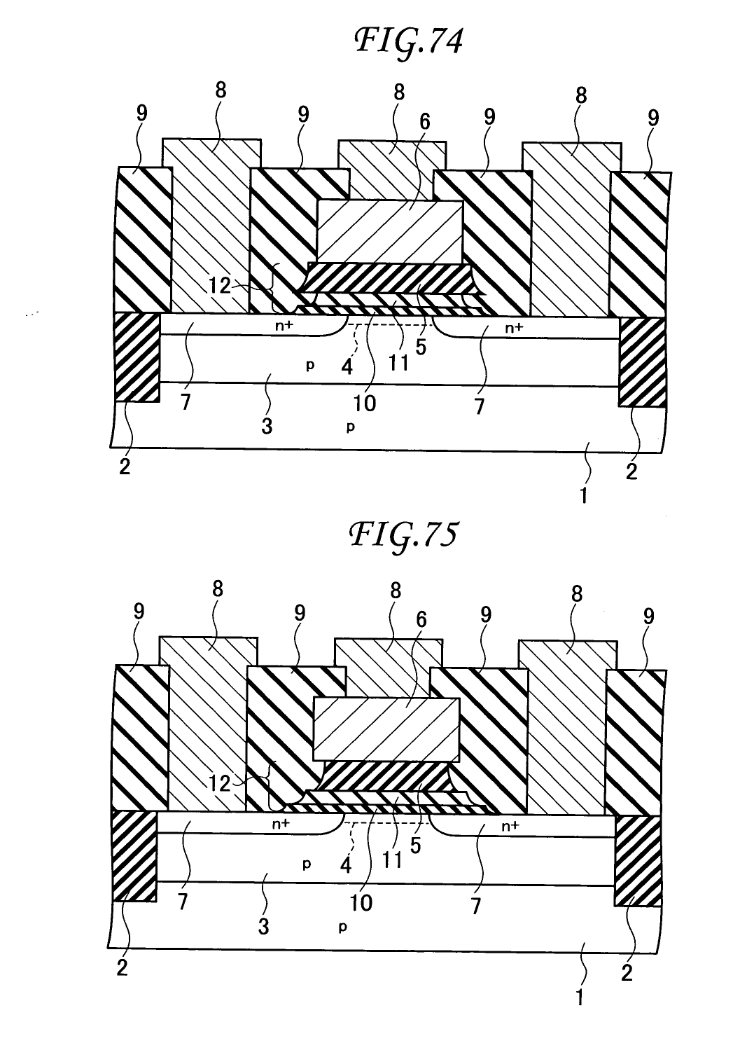

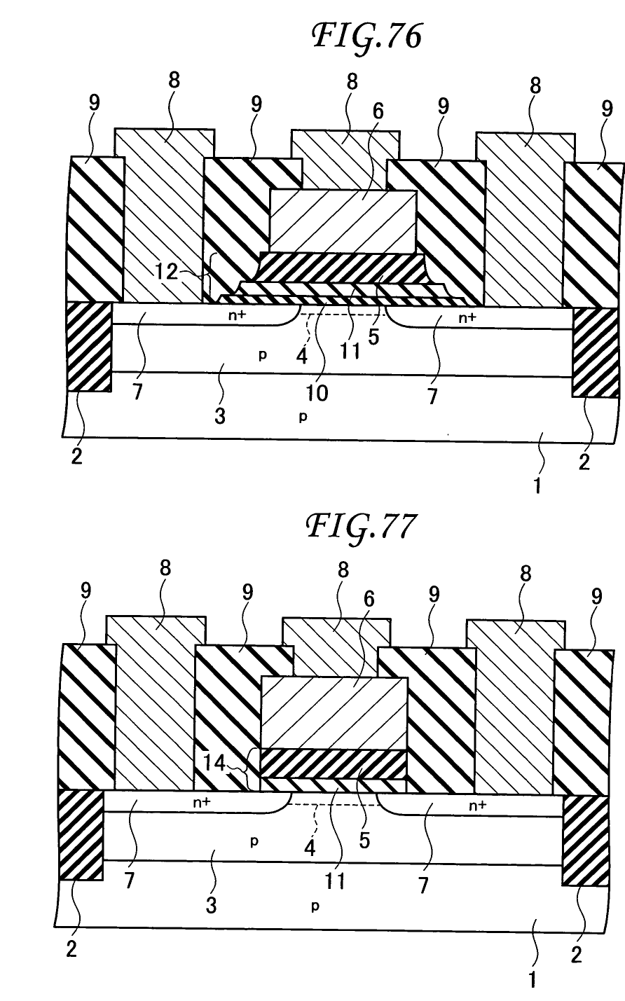

Furthermore, the length of the insulator film along the main component of current flowing through the element does not need to vary in accordance with the order from the semiconductor substrate 1, but may have a form as shown in FIGS. 27 through 36, for example. Moreover, the sidewalls of the stacked gate insulator film 12 need not be perpendicular to the semiconductor device surface, but may be slanted as shown in FIGS. 37 through 52. In addition, the sidewalls of the stacked gate insulator film 12 may be curved as shown in FIGS. 53 through 76, for example. Changing the form of the stacked gate insulator film 12 near the gate electrode 6 lower edge changes the electrical capacitance between the gate electrode 6 and the source/drain regions 7. The electrical capacitance between the gate electrode 6 and the source/drain regions 7 is preferably large from the standpoint of controlling the parasitic resistance, which is caused by the resistance of the source/drain regions 7, and is preferably small from the standpoint of reducing the device parasitic capacitance. If the form of the stacked gate insulator film 12 near the gate electrode 6 lower edge is changed as in this modified example, the electrical capacitance between the gate electrode 6 and the source/drain regions 7 may be adjusted, and thus there is an advantage of optimization.

Furthermore, in the embodiment and modified example thereof, the form of the gate insulator film is made symmetrical with a source and a drain side; however, the source and the drain side may be asymmetrical.

Moreover, with the embodiment and modified example thereof, the thickness of each insulator film forming the stacked gate insulator film 12 is even across the entire channel region. However, any of the insulator films 10, 11 and 5, which form the stacked gate insulator film 12 near the gate electrode 6, may be formed thicker without necessarily being even. In this case, since the electrical capacitance to be formed between the gate electrode 6 and the source/drain regions 7 decreases, there is an advantage of controlling the parasitic capacitance so that the devices operate at a higher speed. Furthermore, any of the insulator films 10, 11 and 5, which form the stacked gate insulator film 12 near the gate electrode 6, may be formed thinner. In this case, since the resistance of the source/drain regions 7 is reduced and the parasitic capacitance is controlled due to the strengthened capacitive coupling between the source/drain regions 7 and the gate electrode 6, there is the advantage of achieving higher-speed operations.

It should be noted that a structure with only a single transistor is described in the embodiment and modified example thereof; however, this embodiment is not limited to the case of a single transistor.

With the semiconductor device according to the embodiment of the present invention, scattering of the carriers moving in the semiconductor substrate due to the charges existing in the gate insulator film or at the interface between the gate insulator film and the semiconductor substrate may be controlled. Mobility of the carriers in the channel is improved as a result. Furthermore, high controllability of the gate electrode with respect to the potential of the channel region may be achieved. A highly efficient, minute device capable of high-speed operation may be implemented as a result.

(Second Embodiment)

Next, a field-effect transistor of a second embodiment is described while referencing FIGS. 77 through 79. FIG. 77 is a cross section of the field-effect transistor of this embodiment. The field-effect transistor has a two layer stacked gate insulator film, and each insulator film is made of a metal oxide. The dielectric constant of the closest layer to the semiconductor substrate is higher than that of the second layer, counting from the semiconductor substrate. The field-effect transistor has a structure with a gate insulator film made of two layers as in the field-effect transistor of the comparative example shown in FIG. 125, wherein one gate insulator film made of silicon oxide, silicon nitride, or oxidized and nitrided silicon is formed of an insulator film using a high dielectric material, such as a metal oxide. Such configured gate insulator film has the same structure as the stacked films in FIG. 1, and according to the reasons described with reference to FIG. 3, carrier mobility increases by controlling scattering of the carriers due to the charges in the gate insulator film or at the interface between the gate insulator film and the semiconductor substrate. Therefore, a higher current driving capability than with the semiconductor device with the structure of the comparative example shown in FIGS. 124 and 125 may be obtained. Furthermore, as opposed to the closest insulator film to the semiconductor substrate in the semiconductor device of the comparative example shown in FIG. 125 being made of silicon oxide, silicon nitride, or oxidized and nitrided silicon, the closest insulator film to the semiconductor substrate in the semiconductor device shown in FIG. 77 is made of a high dielectric material, such as a metal oxide. Accordingly, satisfactory controllability of the gate electrode with respect to the potential of the channel region is achieved. As a result, using a high dielectric material such as a metal oxide for the gate insulator film, controllability of the gate electrode with respect to the potential in the channel region may be improved, high mobility may be attained, and a highly efficient, minute semiconductor device capable of high-speed operation may be implemented.

This field-effect transistor further includes device isolation regions 2 formed on the p-type Si substrate 1 through trench device isolation. The p-well region 3 is formed in the p-type Si substrate 1, and the n-channel region 4 is formed in the p-well region 3. A gate insulator film 14, which has a stacked structure of the gate insulator film 5 made of a metal oxide or the like and the gate insulator film 11 made of a metal oxide with a higher dielectric constant than the gate insulator film 5, is formed on the n-channel region 4; and the gate electrode 6 is formed on the stacked gate insulator film 14. Reference numeral 7 denotes source/drain regions, 8 denotes interconnects, and 9 denotes inter-layer insulator films.

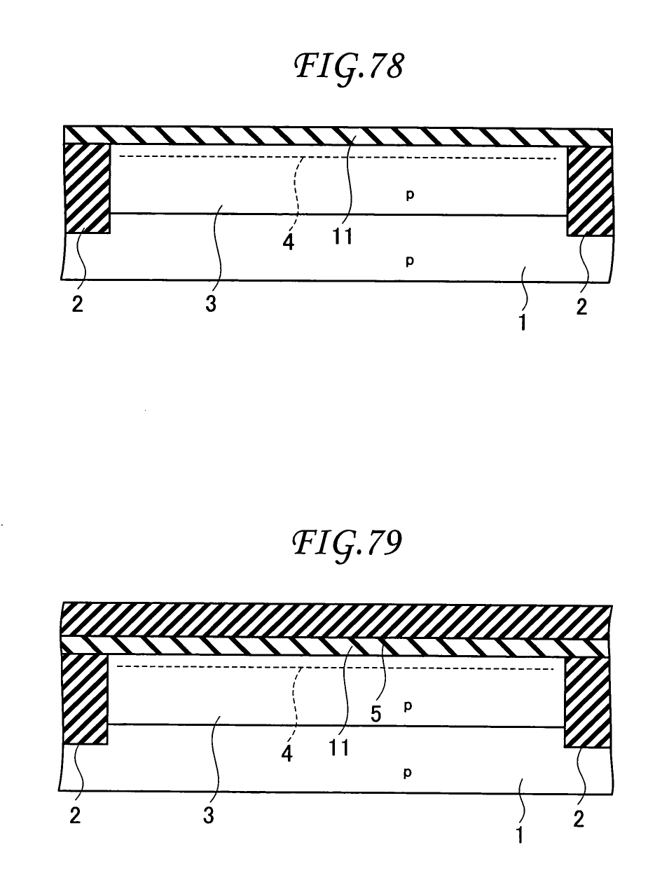

This field-effect transistor may be formed in the following manner. In the formation process, after the process shown in FIG. 6 of the first embodiment, as shown in FIG. 78, the gate insulator film 11, which is made of a 3 nm-thick TiO₂ film, for example, is formed through a method such as sputtering.

Next, as shown in FIG. 79, the gate insulator film 5, which is made of a 5 nm-thick HfO₂ film, for example, is formed through a method such as sputtering. Subsequent steps are the same as in the process shown after FIG. 10 of the first embodiment.

Various modifications as described in the first embodiment are also possible with this embodiment, and the same effects may be obtained. Further with this embodiment, a TiO₂ film, which is formed through sputtering as the closest insulator film to the semiconductor substrate 1 among the insulator films forming the gate insulator film, is used. However, a different high dielectric film may be used such as an insulator film containing an oxide of a valence of Ti, BaO, BaTiO₃, BaWO₄₁ BaZnGeO₄, Bi₁₂GeO₂₀, Bi₁₂SiO₂₀, Bi₁₂TiO₂₀, CaMoO₄, CaYAlO₄, Dy₂Ti₂O₇, EuAlO₃, Eu₃NbO₇, EuO, Gd₃NbO₇, Ho₂Ti₂O₇, LaAlO₃, La₂Be₂O₁, La₂CuO₄, LaTi₂O₇, LiNbO₃, LiTaO₃, MnO, Nb₂O₅, NdAlO₃, Nd₂Ti₂O₇, PbF₂, Pb₅GeV₂O₁₂, PbMoO₄, PbO, PbWO₄, PrAlO₃, SrMoO₄, SrTiO₃, SrWO₄, Ta₂O₅, TeO₂, UO₂, Yb₂Ti₂₀₇, an oxide with a valence of a metal, or any one of these added with nitrogen. As is described referencing FIG. 3, a sufficiently high dielectric constant, particularly a higher dielectric constant than the square root of the product of the dielectric constants of the Si substrate 1 and the second insulator film counting from the Si substrate 1 is essential for the first insulator film counting from the Si substrate 1. Therefore, this embodiment does not prove fully effective when using a substance with a low dielectric constant such as silicon oxide, silicon nitride or oxidized and nitrided silicon as the closest insulator film to the Si substrate 1. Furthermore, the fabrication method for the insulator film is not limited to sputtering, and a different method may be employed such as vapor deposition, CVD, or epitaxial growth. Moreover, in a case such as using an oxide of a certain substance as the insulator film, a method such as forming a film made of that substance and then oxidizing the film may be employed.

In this embodiment, an HfO₂ film formed through sputtering is used as the second insulator film counting from the Si substrate 1 from among the insulator films forming the gate insulator film. However, a different high dielectric film may be used as the gate insulator film such as an insulator film containing an oxide of a valence of Hf, an oxide of a different metal such as Zr, Ti, Sc, Y, Ta, Al, La, Ce, Pr or an element from the lanthanoid group, a silicate material containing various elements including these and other elements, or any one of these elements with nitrogen added, or a different insulator film made of stacked layers. When nitrogen exists in the insulator film, only a certain element being crystallized and then precipitated may be controlled. It should be noted that this embodiment was devised for reducing scattering of carriers due to the charges existing in the gate insulator film, or at the interface between the gate insulator film and the Si substrate. Accordingly, the effects of this embodiment are significant when there are abundant charges such as in the case of using a metal oxide as the gate insulator film. Furthermore, the fabrication method for the insulator film is not limited to sputtering, and a different method may be used such as vapor deposition, CVD, or epitaxial growth. Moreover, in a case such as using an oxide of a certain substance as the insulator film, a method such as forming a film made of that substance and then oxidizing it may be employed.

Furthermore, the thickness of each insulator film forming the gate insulator film is not limited in this embodiment. As is described for the above Expression 6, the potential within the Si substrate due to the point charges in the stacked insulator film as shown in FIGS. 1 through 3 is represented by the power series exp(−kTⱼ) (Tⱼdenotes the thickness of the j-th layer from the Si substrate.) and k denotes the wavenumber for the potential subjected to the Fourier transform along the in-plane of the insulator film. Considering actual scattering of carriers, contribution of the Fermi wavenumber when assuming the carriers in an inversion layer as two-dimensional gas is large. To approximate the value of the potential in the Si substrate using the primary term of the power series such as in Expression (6), the value of each exp(−kTⱼ) must be appropriately small. Accordingly, it is preferable that the thickness of an insulator film layer should be comparable to the Fermi wavelength or larger when assuming the carriers in the inversion layer as two-dimensional gas. Assuming that the area density of the carriers in the inversion layer is 2×10¹³ cm², which is approximately the same as the area density of the carriers in the inversion layer in a typical device that is in an on-state, and that the carriers in the inversion layer are a two-dimensional ideal Fermi gas, the Fermi wavelength is approximately 1.2 nm. Accordingly, the thickness of each insulator film layer is preferably approximately 1.2 nm or greater. Furthermore, when the thickness of each insulator film layer is equal to or greater than the product of the Fermi wavelength and the natural logarithm of 10, the value of each exp(−kTⱼ) is equal to 1/10 or less, namely a smaller order of magnitude than the terms not including this exponential function. Accordingly, when the thickness of each insulator film layer is approximately 2.8 nm or greater, it is even more favorable to provide a minute semiconductor device capable of high-speed operations by reducing the scattering of carriers as well as enhancing the controllability of the gate electrode with respect to the potential of the channel region.

This embodiment was devised for reducing scattering of carriers in the semiconductor substrate due to the charges existing in the second insulator film counting from the semiconductor substrate in a device using a high dielectric material such as a metal oxide for the gate insulator film. An additional insulator film layer is provided to the gate insulator film with the structure of the comparative example shown in FIG. 124. Reduction in scattering of the carriers due to the charges in the gate insulator film and the like is important; however, considering an increase in the short channel effect and reduction in current driving capability, reduction in the controllability of the gate electrode with respect to the potential of the channel region is not favorable to provide a minute semiconductor device capable of high-speed operations by reducing the scattering of carriers as well as enhancing the controllability of the gate electrode with respect to the potential of the channel region. Therefore, with the structure of this embodiment shown in FIG. 77, it is preferable that the thickness of the closest insulator film to the semiconductor substrate, which is the essential difference from the comparative example shown in FIG. 124, is not very thick. However, the essential value is not the insulator film thickness, geometrically speaking, when considering the controllability of the gate electrode with respect to the potential of the channel region, but is a value derived by dividing the insulator film thickness by its dielectric constant. Accordingly, it is preferable that the value derived by dividing the thickness of the closest insulator film to the semiconductor substrate by its dielectric constant is smaller than the value derived by dividing the thickness of the second insulator film counting from the semiconductor substrate by its dielectric constant.

In this embodiment, the gate insulator film has a two-layer stacked structure; however, if the relationship between dielectric constant and thickness as described above is satisfied, a gate insulator film with a stacked structure of three or more layers may be formed.

### MODIFIED EXAMPLE OF THE SECOND EMBODIMENT

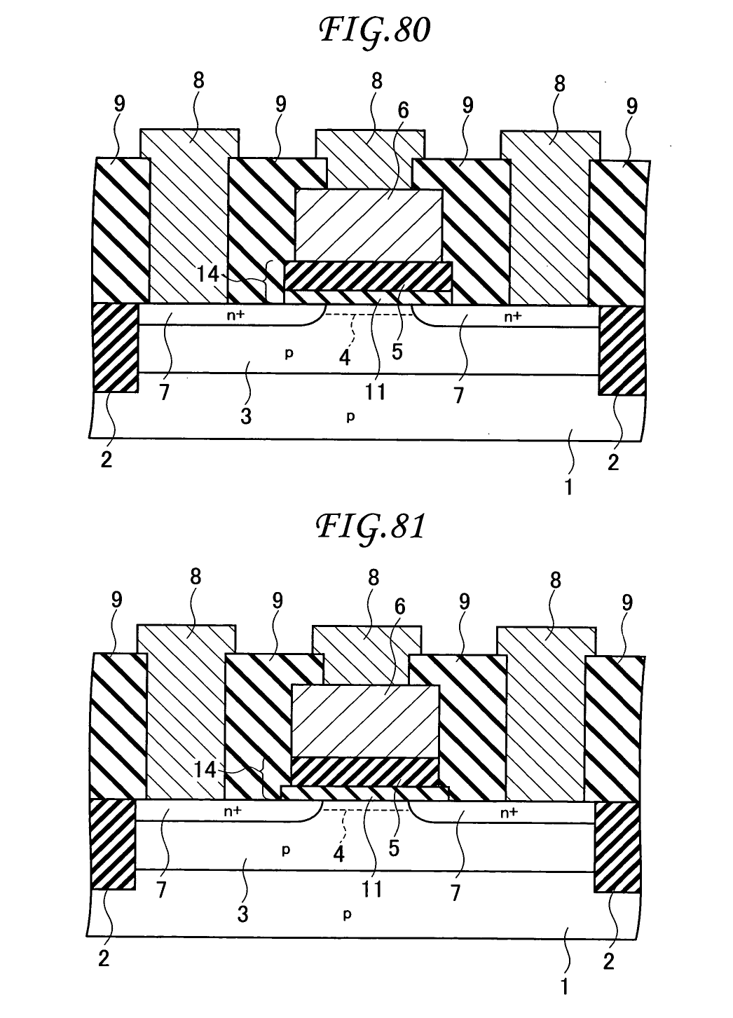

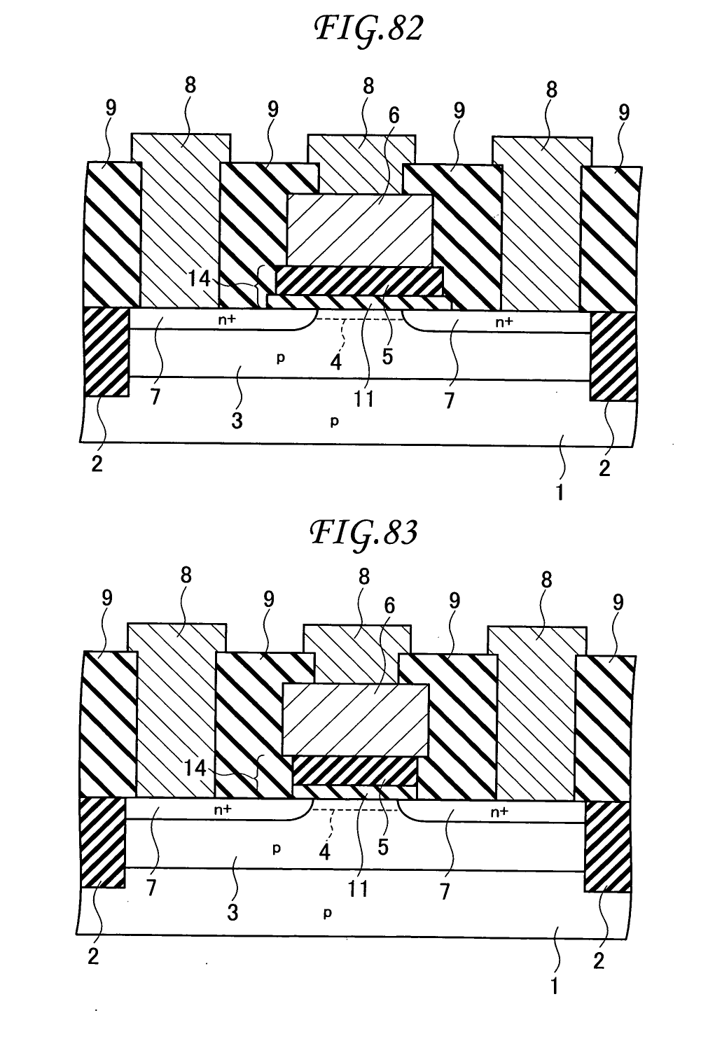

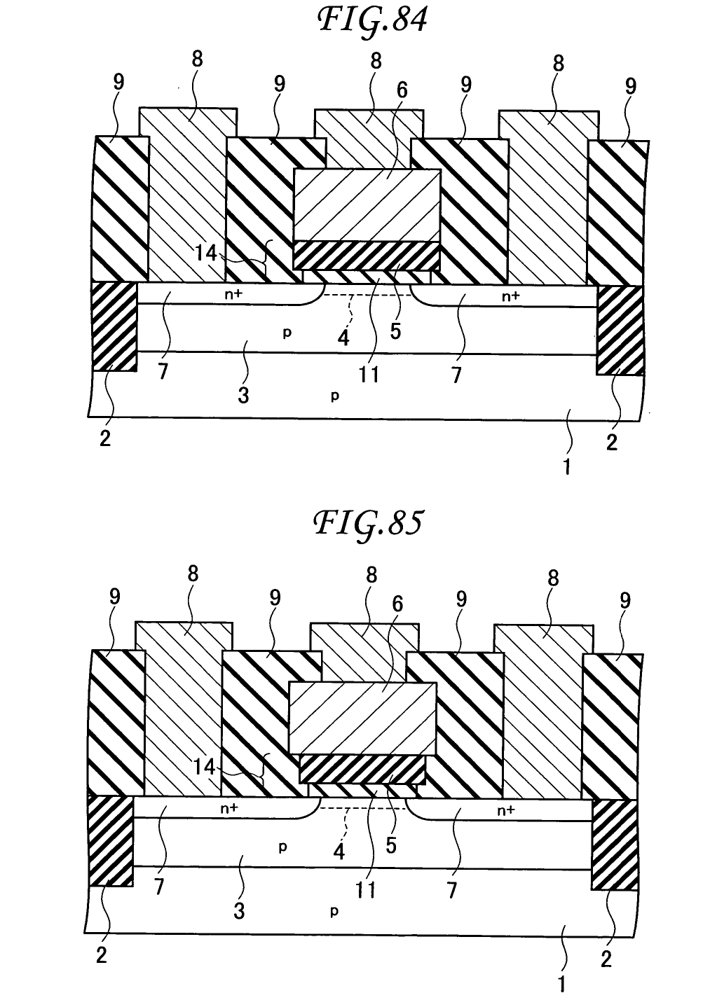

With this embodiment, the sidewalls of the gate insulting film 14 with the stacked structure as shown in FIG. 77 are processed so as to match the gate electrode 6; however, the gate insulator film 14 with the structure as shown in FIGS. 80 through 82, for example, may be processed so as to overhang from the gate electrode 6. By doing so, the capacitive coupling between the source/drain regions 7 and the gate electrode 6 is strengthened, therefore advantages of reducing the resistance of the source/drain regions 7, controlling the parasitic capacitance as well as allowing high-speed operations are obtained. Furthermore, the gate insulator film 14 with the stacked structure as shown in FIGS. 83 through 85 may be processed so as to be further inward than the gate electrode 6. By doing so, the electrical capacitance to be formed between the gate electrode 6 and the source/drain regions 7 decreases, therefore advantages of reducing the parasitic capacitance as well as allowing high-speed operations are obtained. Moreover, by processing the stacked gate insulator film 14 so as to be further inward than the gate electrode 6, an advantage of a relaxed electric field in the stacked gate insulator film 14 near the gate electrode 6 lower edge is obtained.

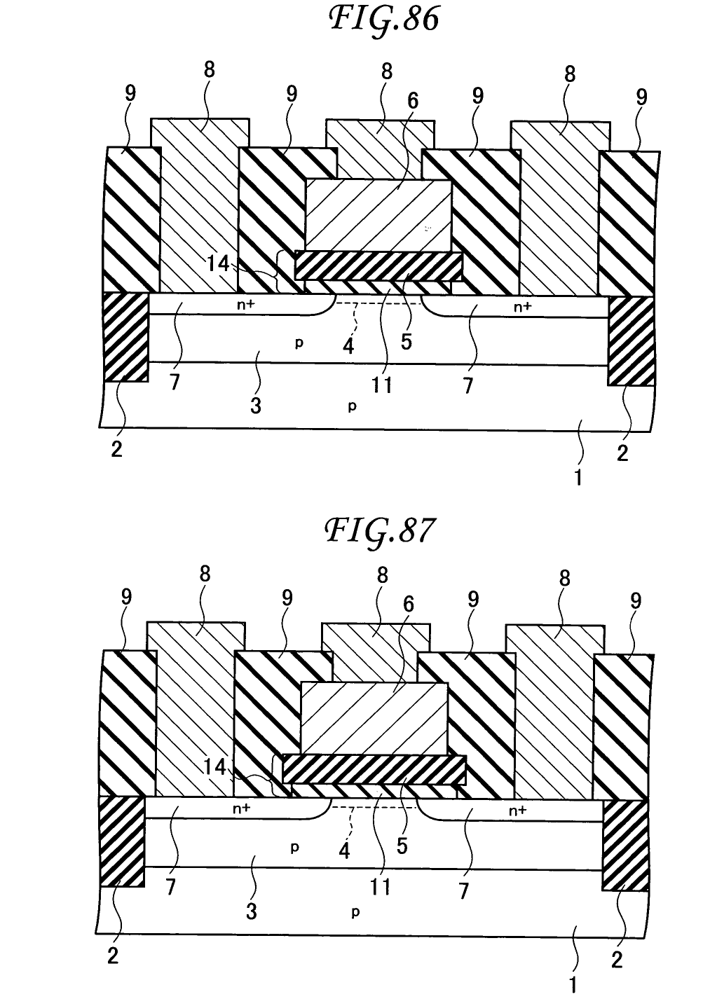

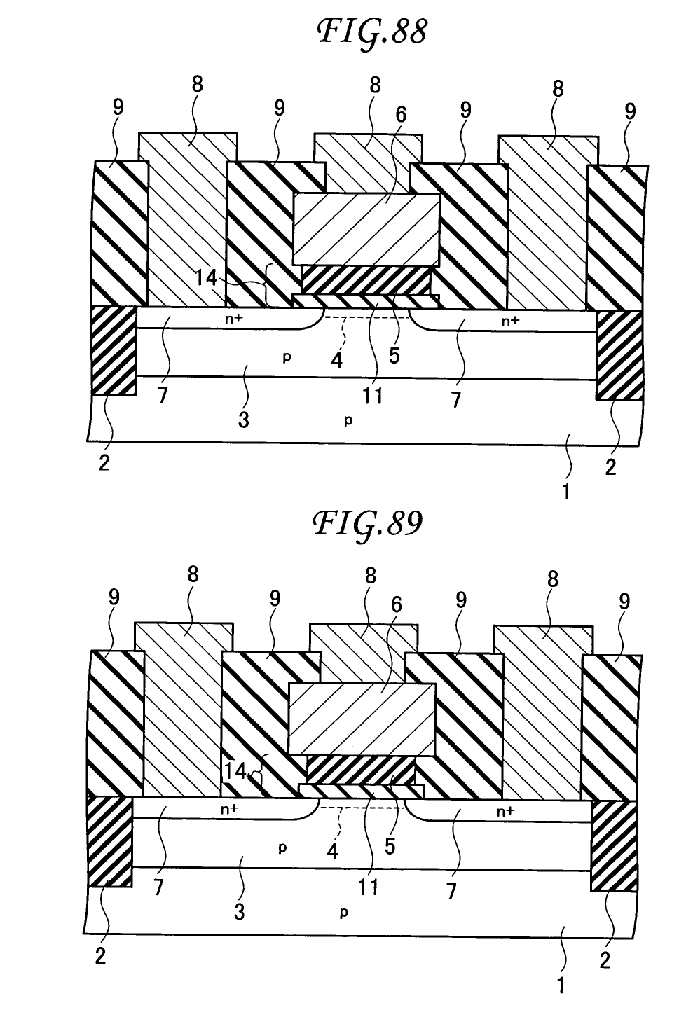

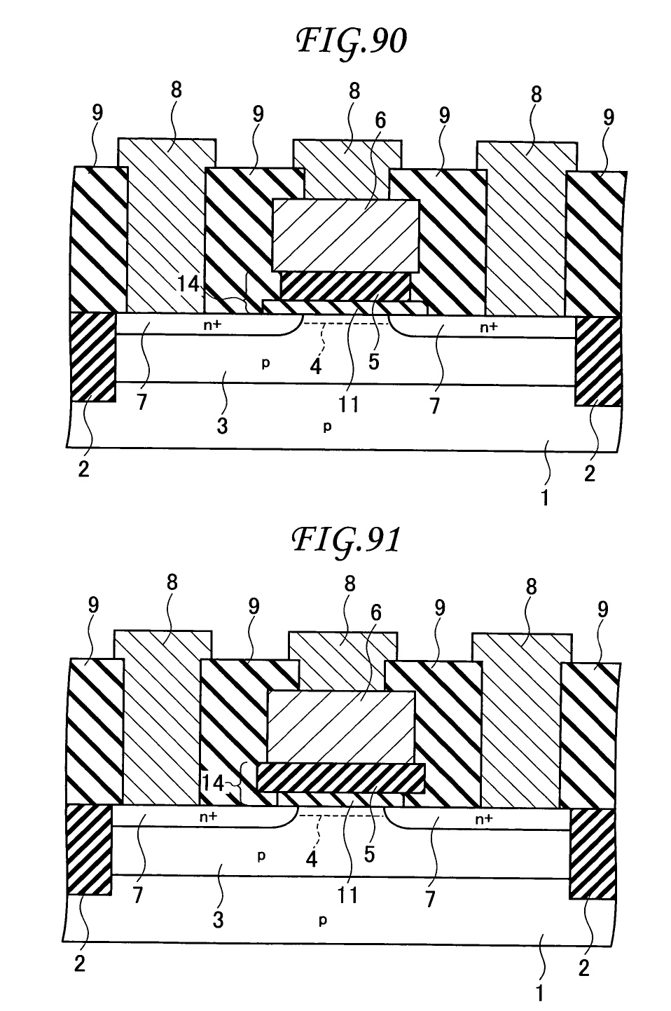

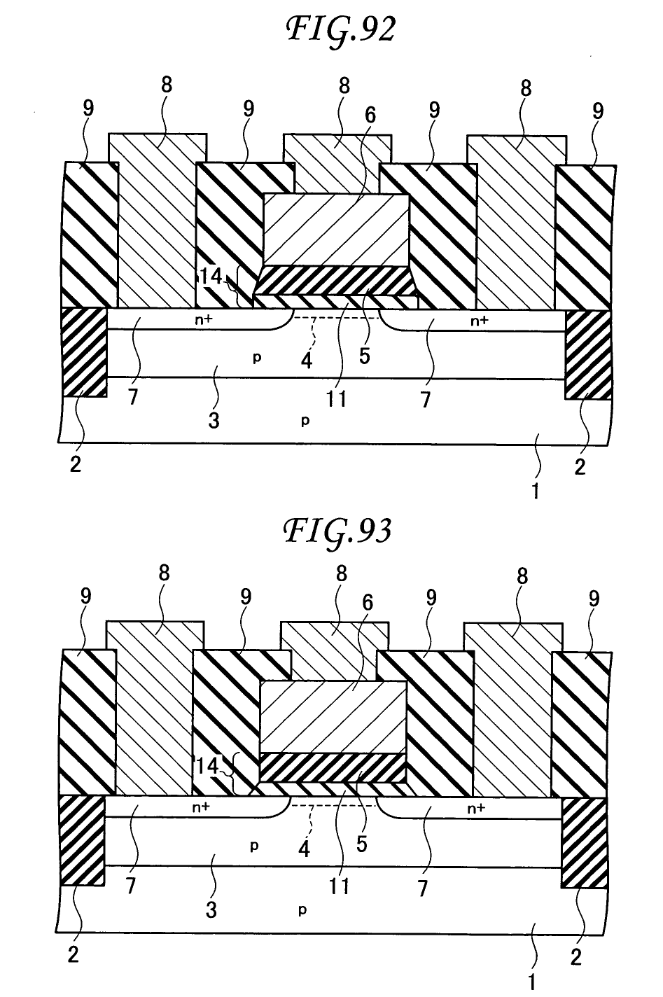

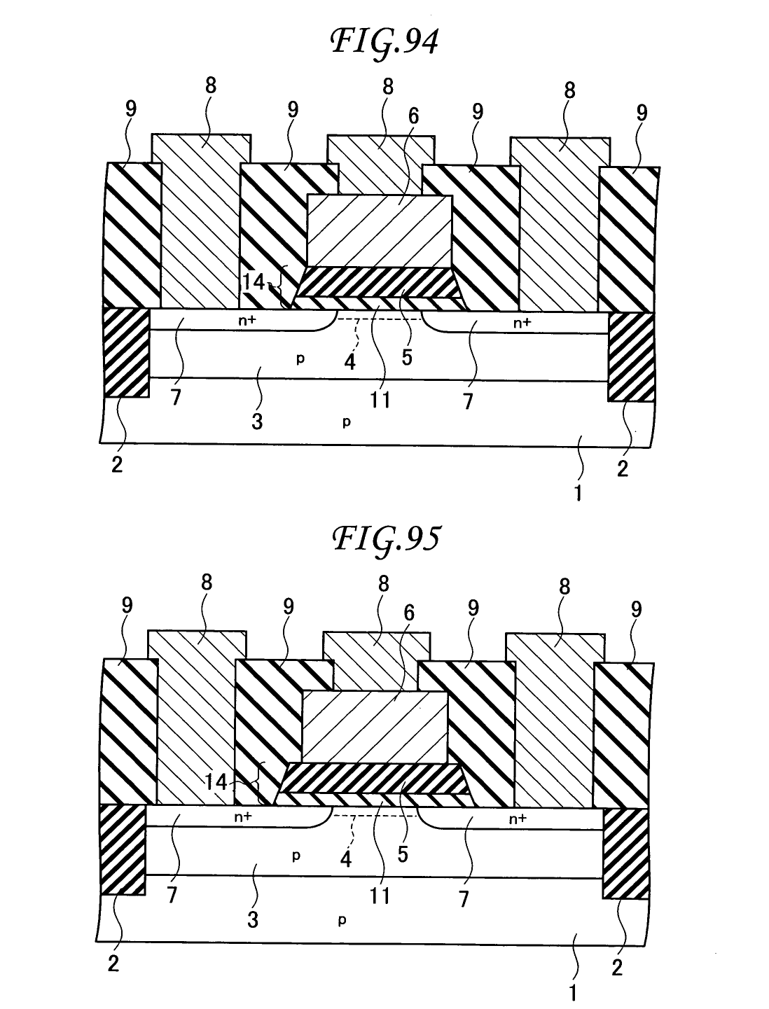

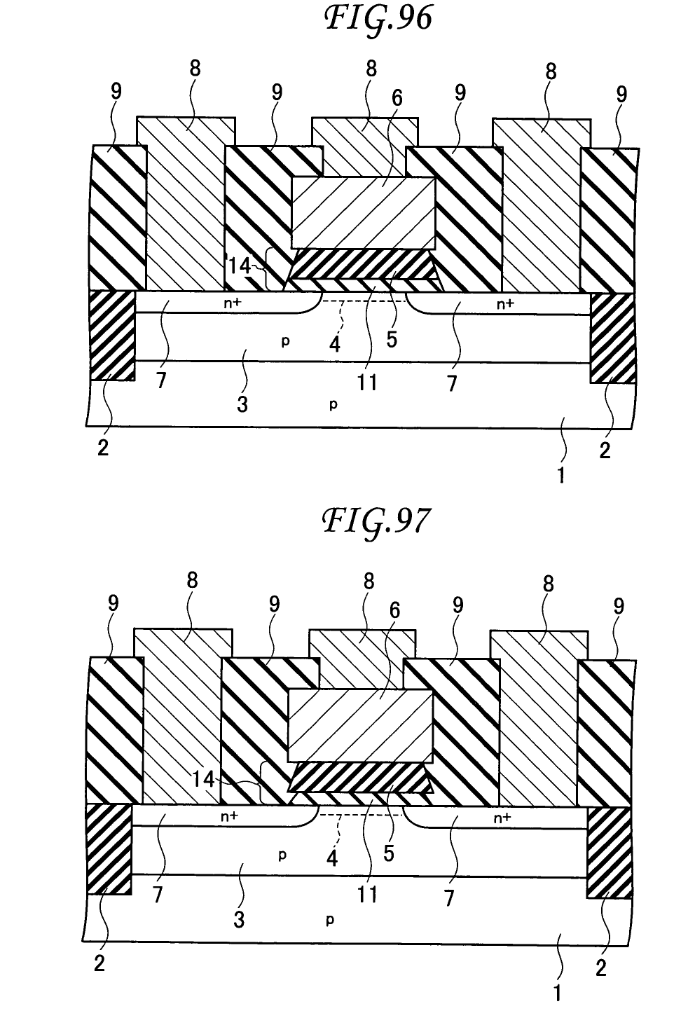

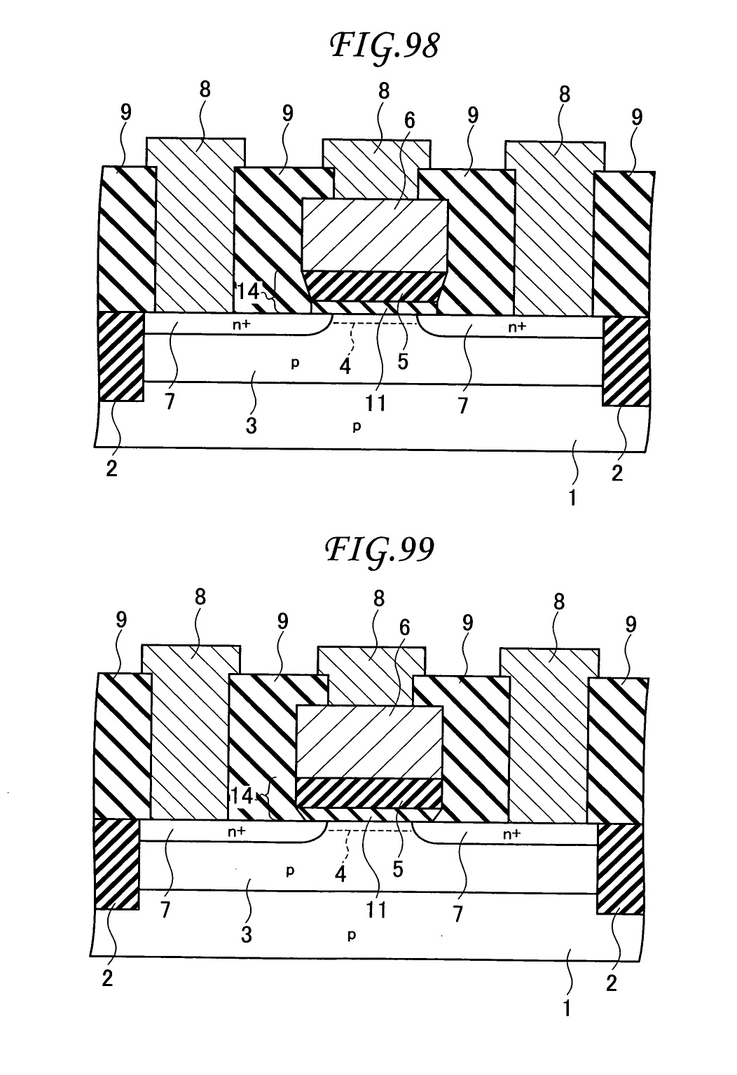

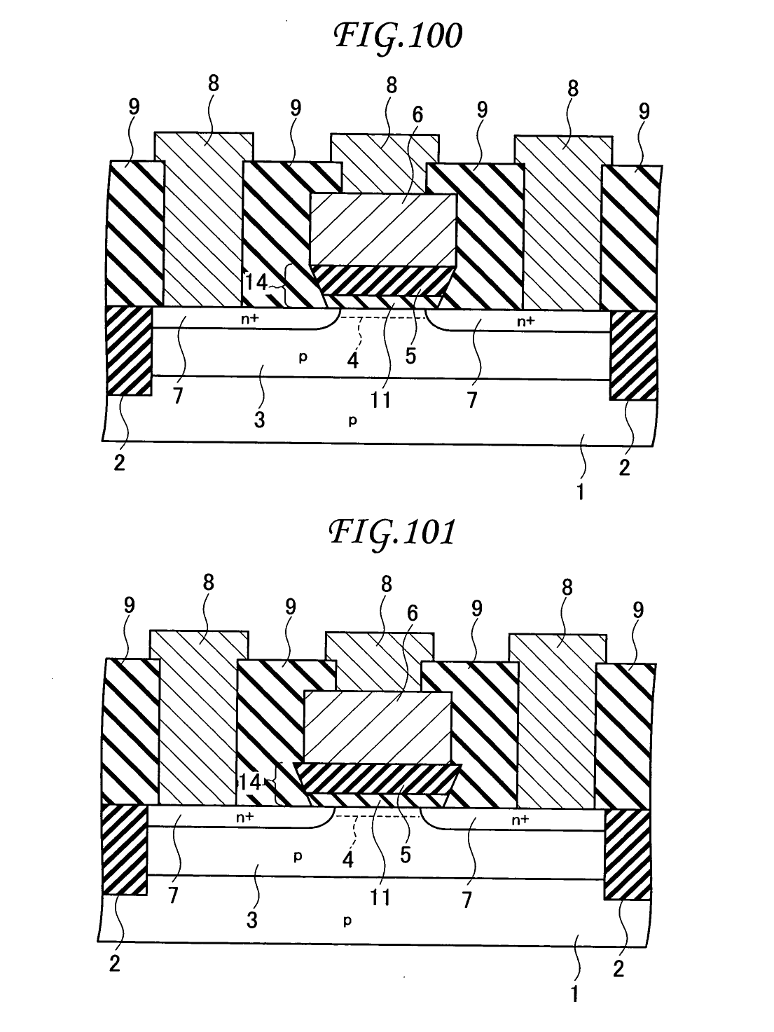

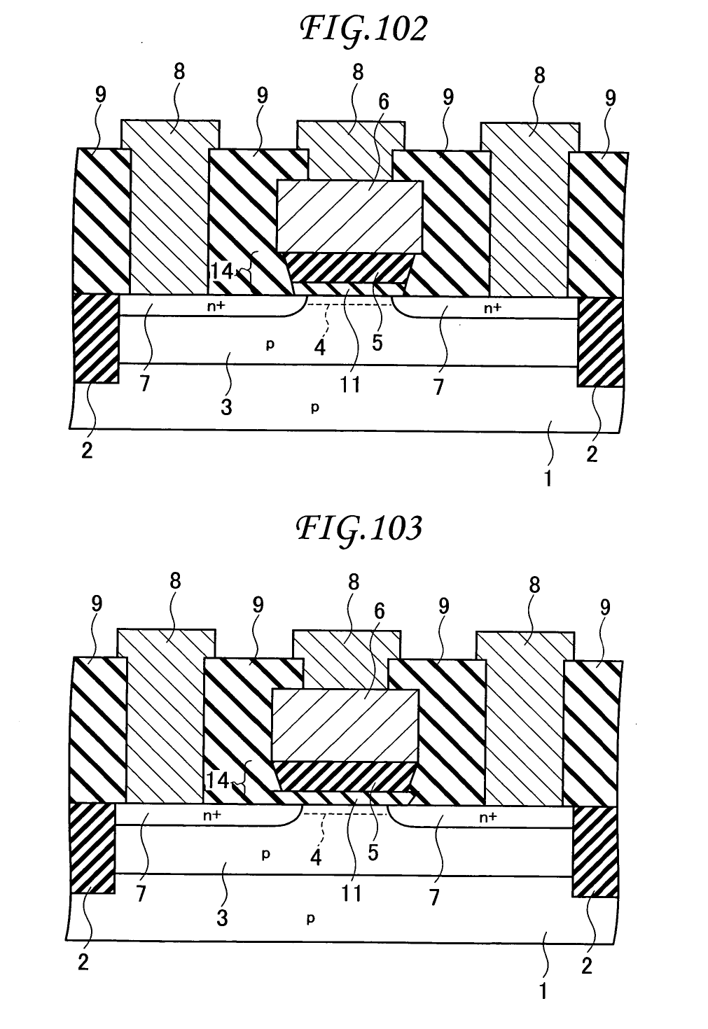

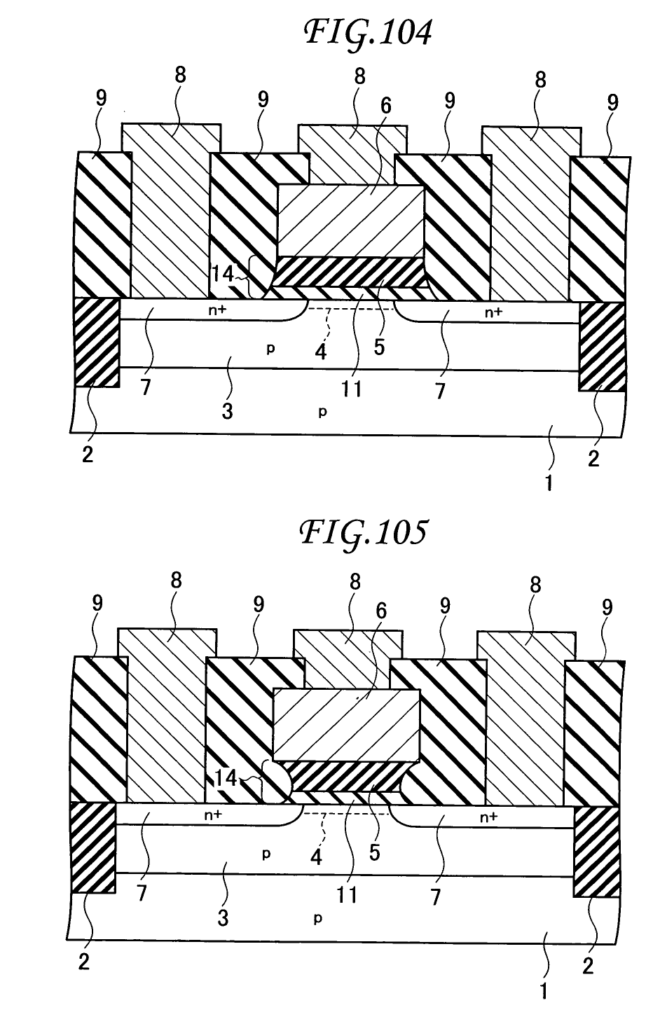

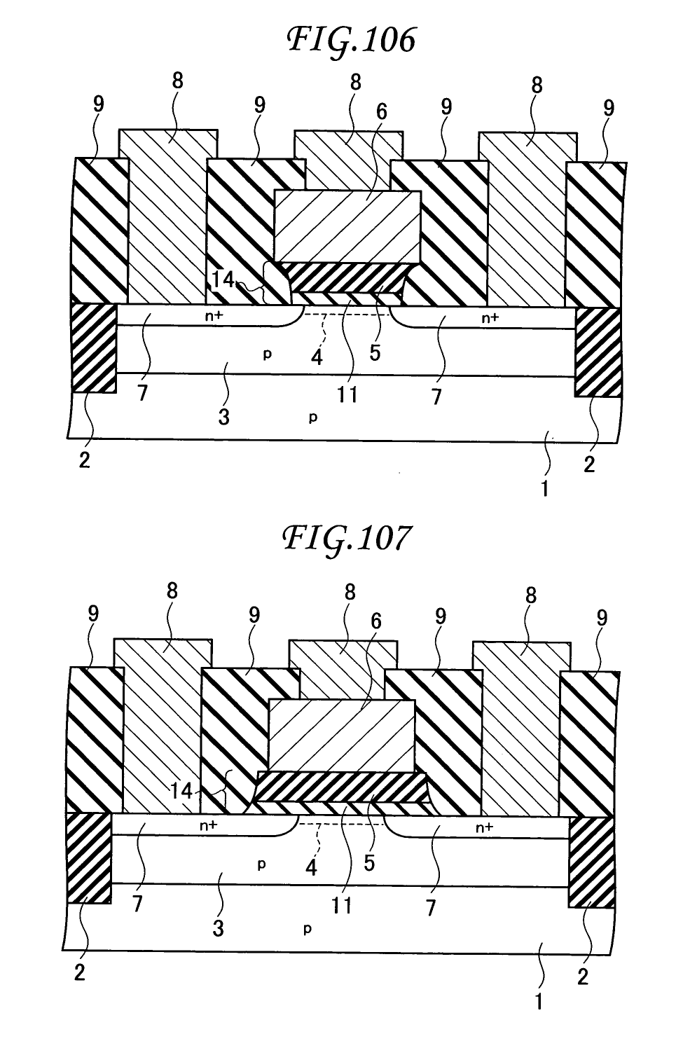

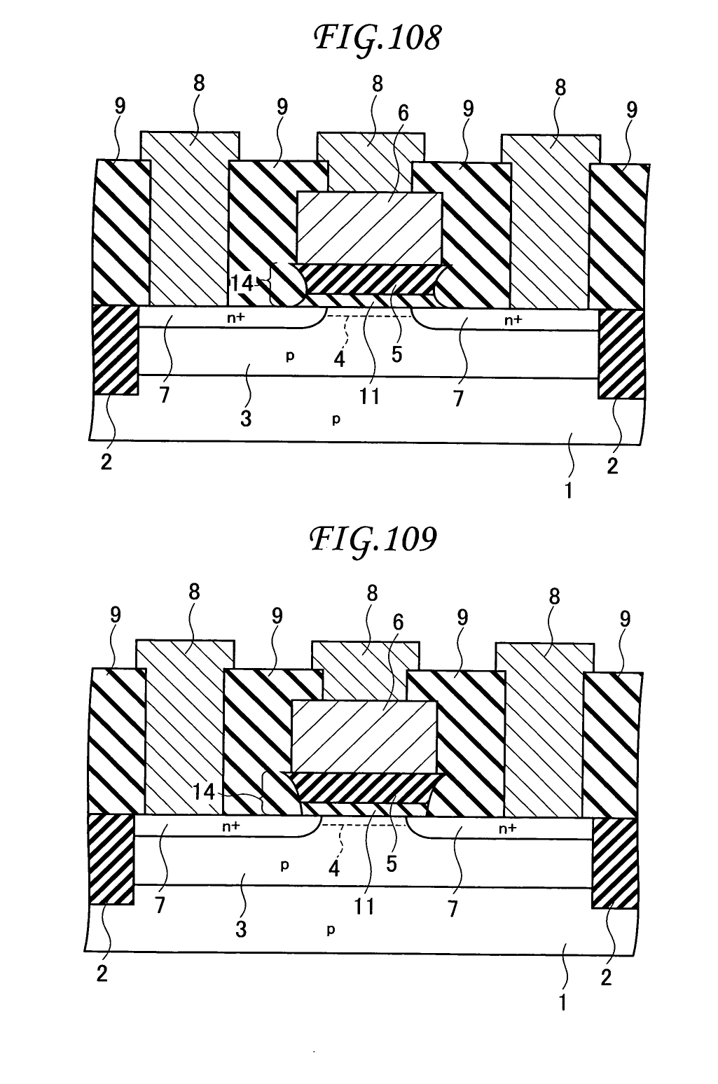

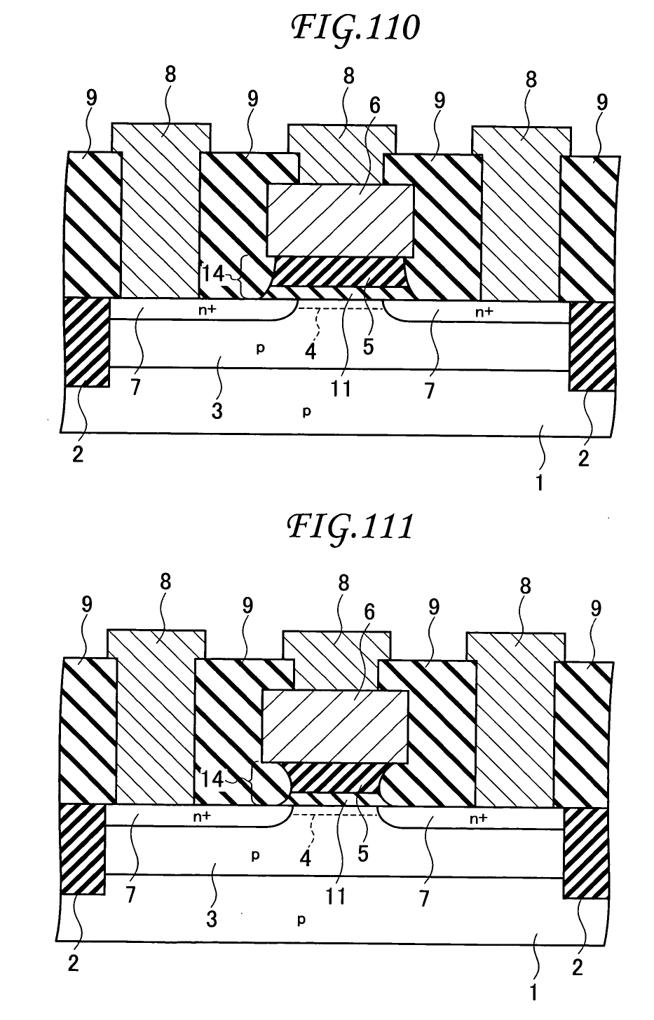

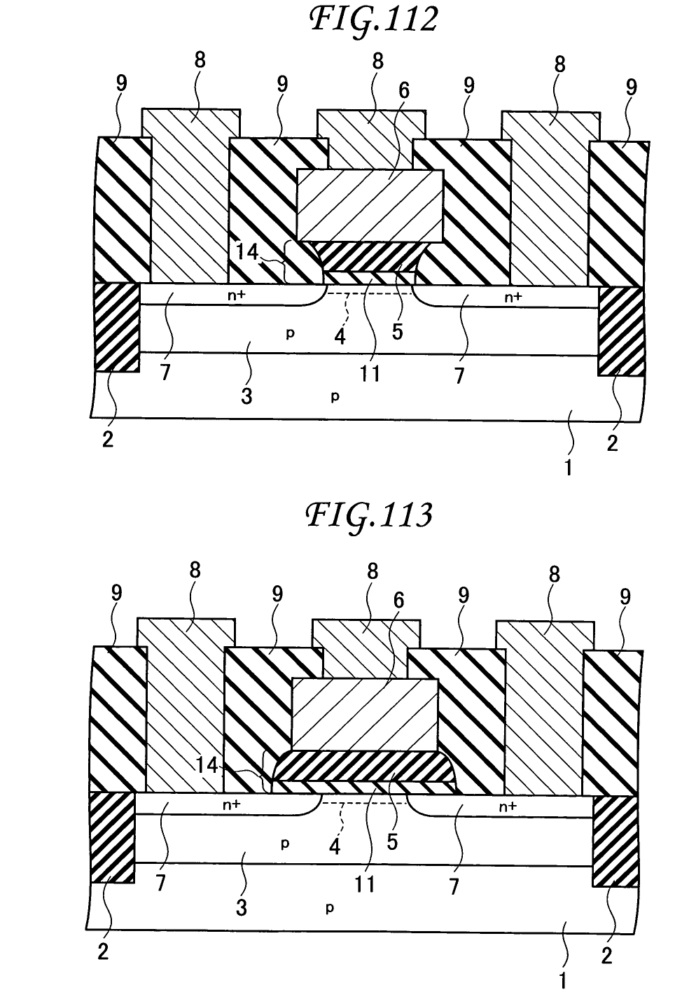

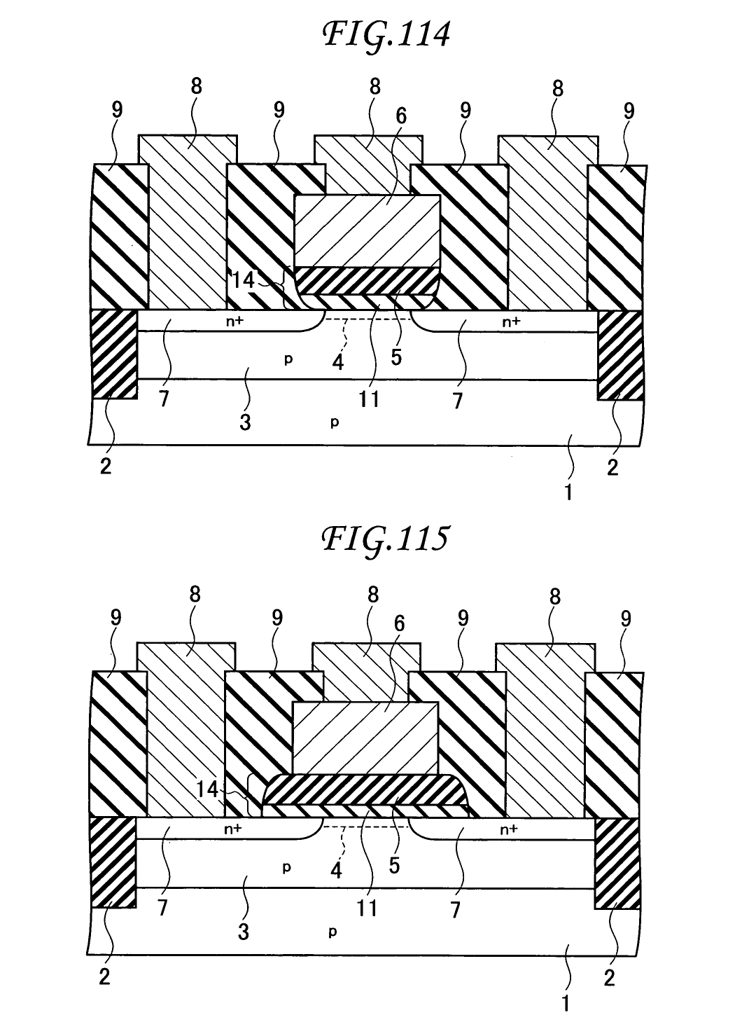

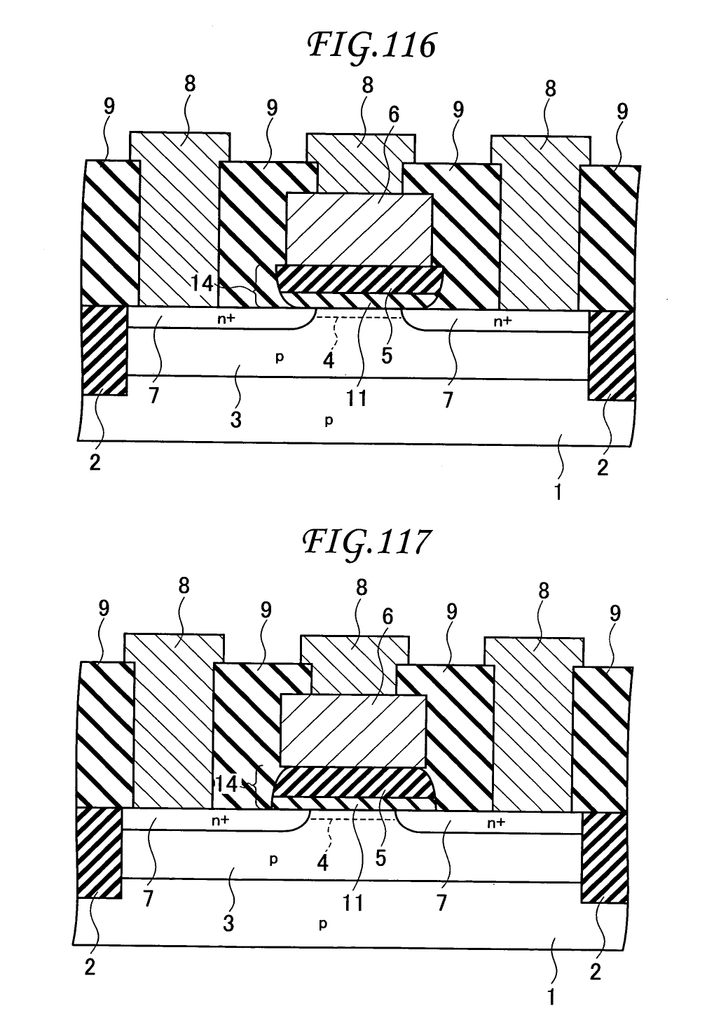

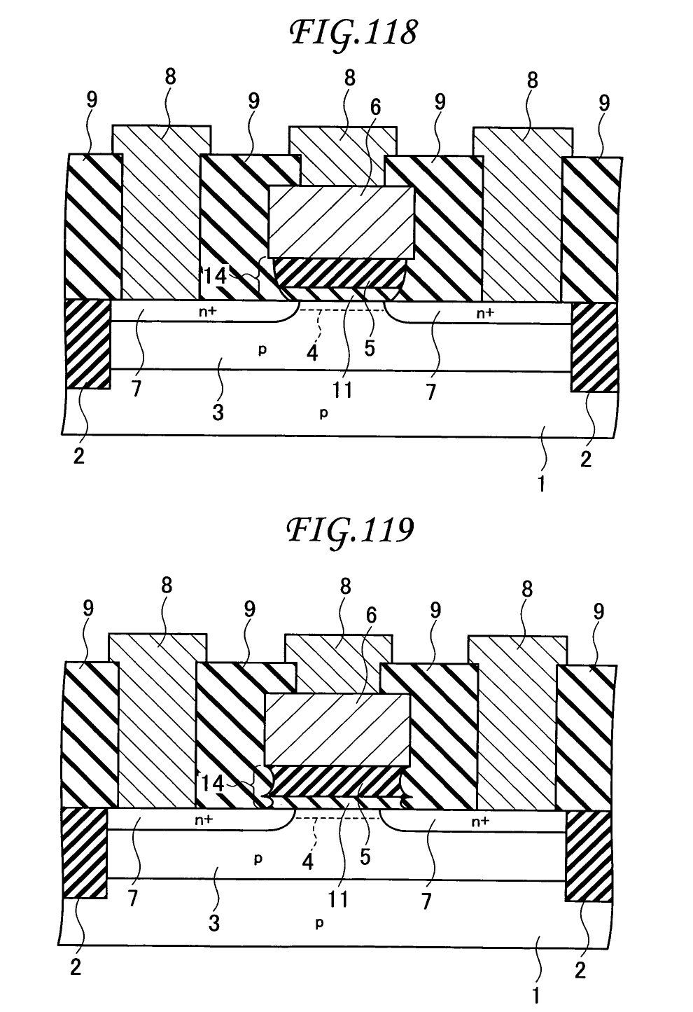

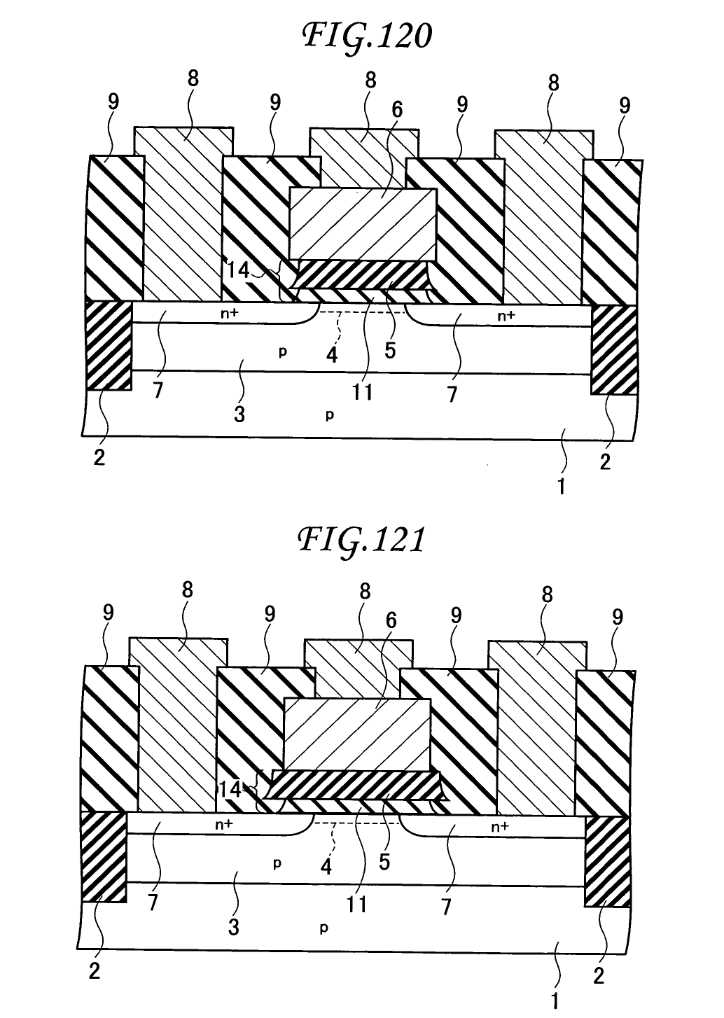

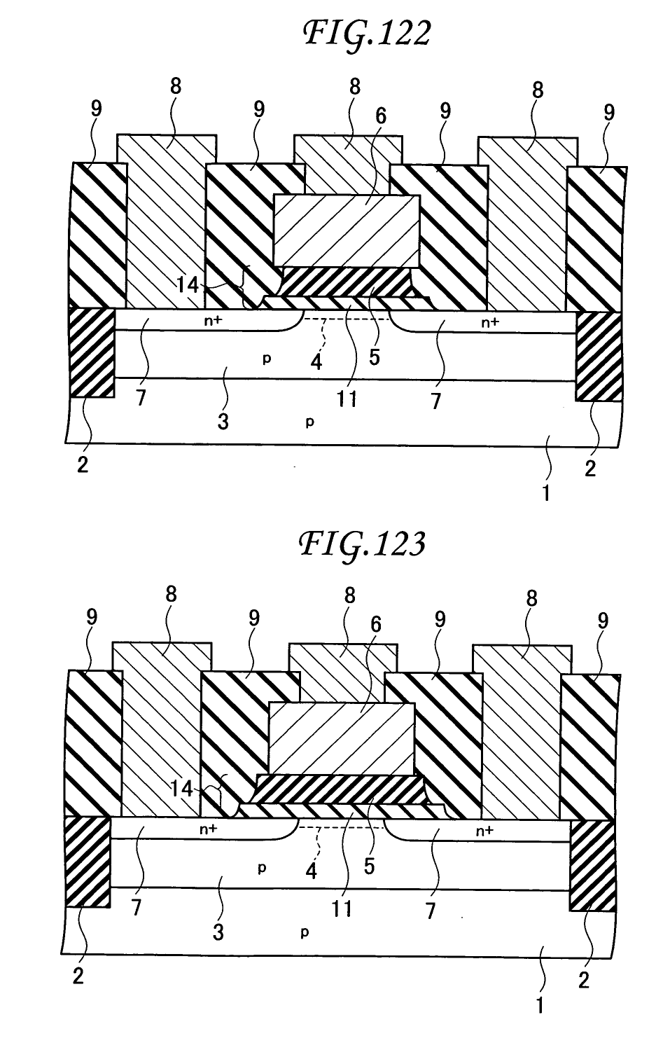

Furthermore, the length of the insulator film along the main component of current flowing through the element does not need to vary in accordance with the order from the semiconductor substrate 1, but may have a form as shown in FIGS. 86 through 91, for example. Moreover, the sidewalls of the gate insulator film need not be perpendicular to the semiconductor device surface, but may be slanted as shown in FIGS. 92 through 103. In addition, the sidewalls of the gate insulator film may curve as shown in FIGS. 104 through 123, for example. Changing the form of the gate insulator film near the gate electrode 6 lower edge changes the electrical capacitance between the gate electrode 6 and the source/drain regions 7. The electrical capacitance between the gate electrode 6 and the source/drain regions 7 is preferably large from the standpoint of controlling the parasitic resistance, which is caused by the resistance of the source/drain regions 7, and is preferably small from the standpoint of reducing the device parasitic capacitance. If the form of the gate insulator film near the gate electrode 6 lower edge is changed as in this modified example, the electrical capacitance between the gate electrode 6 and the source/drain regions 7 may be adjusted, and thus there is an advantage of possible optimization to provide a minute semiconductor device capable of high-speed operations by reducing the scattering of carriers as well as enhancing the controllability of the gate electrode with respect to the potential of the channel region.

With the semiconductor device according to this embodiment of the present invention, scattering of the carriers moving in the semiconductor substrate due to the charges existing in the gate insulator film or at the interface between the gate insulator film and the semiconductor substrate may be controlled. Mobility of the carriers in the channel is improved as a result. Furthermore, high controllability of the gate electrode with respect to the potential of the channel region may be achieved. A highly efficient, minute device capable of high-speed operation may be implemented as a result.

(Other Embodiments)

While the present invention is described in accordance with the aforementioned embodiments, it should not be understood that the description and drawings that configure part of this disclosure are to limit the present invention. This disclosure makes clear a variety of alternative embodiments, working examples, and operational techniques for those skilled in the art. Accordingly, the technical scope of the present invention is defined by only the claims that appear appropriate from the above explanation.

Various modifications will become possible for those skilled in the art after receiving the teachings of the present disclosure without departing from the scope thereof.

1. A semiconductor device, comprising:
a semiconductor substrate;
a source and a drain region arranged at the surface of the semiconductor substrate;
a gate insulator film arranged on a channel defined between the source and drain regions at the surface of the semiconductor substrate and implemented by a stacked structure including a first insulator film, a second insulator film containing a metal on the first insulator film, and a third insulator film containing a metal on the second insulator film; and
a gate electrode arranged on the third insulator film, wherein the dielectric constant of the second insulator film is higher than the square root of the product of the dielectric constants of the first and third insulator films.

2. The semiconductor device of claim 1, wherein the dielectric constant of the second insulator film is higher than that of the third insulator film.

3. The semiconductor device of claim 1, wherein thicknesses of the second insulator film and the third insulator film are respectively greater than 1.2 nm.

4. The semiconductor device of claim 1, wherein thicknesses of the second insulator film and the third insulator film are respectively approximately 2.8 nm or greater than 2.8 nm.

5. The semiconductor device of claim 1, wherein a value derived by dividing the thickness of the second insulator film by its dielectric constant is smaller than a value derived by dividing the thickness of the third insulator film by its dielectric constant.

6. The semiconductor device of claim 1, wherein the first insulator film is made of any one of silicon oxide, silicon nitride, or oxidized and nitrided silicon.

7. The semiconductor device of claim 1, wherein the second insulator film is made of any one of TiO₂, BaO, BaTiO₃, BaWO₄, BaZnGeO₄, Bi₁₂GeO₂₀, Bi₁₂SiO₂₀, Bi₁₂TiO₂₀, CaMoO₄, CaYAlO₄, Dy₂Ti₂O₇, EuAlO₃, Eu₃NbO₇, EuO, Gd₃NbO₇, Ho₂Ti₂O₇, LaAlO₃, La₂Be₂O₅, La₂CuO₄, LaTi₂O₇, LiNbO₃, LiTaO₃, MnO, Nb₂O₆, NdAlO₃, Nd₂Ti₂O₇, PbF₂, Pb₅GeV₂O₁₂, PbMoO₄, PbO, PbWO₄, PrAlO₃, SrMoO₄, SrTiO₃, SrWO₄, Ta₂O₅, TeO₂, UO₂, Yb₂Ti₂O₇.

8. The semiconductor device of claim 1, wherein the second insulator film is made of any one of oxide of a valence of Hf, an oxide of Zr, Ti, Sc, Y, Ta, Al, La, Ce, Pr or an element from the lanthanoid group, and a silicate material.

9. The semiconductor device of claim 2, wherein thicknesses of the second insulator film and the third insulator film are respectively greater than 1.2 nm.

10. The semiconductor device of claim 2, wherein thicknesses of the second insulator film and the third insulator film are respectively approximately 2.8 nm or greater than 2.8 nm.

11. The semiconductor device of claim 2, wherein a value derived by dividing the thickness of the second insulator film by its dielectric constant is smaller than a value derived by dividing the thickness of the third insulator film by its dielectric constant.

12. The semiconductor device of claim 2, wherein the first insulator film is made of any one of silicon oxide, silicon nitride, or oxidized and nitrided silicon.

13. A semiconductor device, comprising:
a semiconductor substrate;
a source and a drain region arranged at the surface of the semiconductor substrate;
a gate insulator film arranged on a channel defined between the source and drain regions at the surface of the semiconductor substrate and implemented by a stacked structure including a first insulator film containing a metal and a second insulator film containing a metal on the first insulator film; and
a gate electrode arranged on the second insulator film, wherein the dielectric constant of the first insulator film is higher than the square root of the product of the dielectric constants of the semiconductor substrate and the second insulator film.

14. The semiconductor device of claim 13, wherein the dielectric constant of the first insulator film is higher than that of the second insulator film.

15. The semiconductor device of claim 13, wherein thicknesses of the first insulator film and the second insulator film are respectively greater than 1.2 nm.

16. The semiconductor device of claim 13, wherein thicknesses of the second insulator film and the third insulator film are respectively approximately 2.8 nm or greater than 2.8 nm.

17. The semiconductor device of claim 13, wherein a value derived by dividing the thickness of the first insulator film by its dielectric constant is smaller than a value derived by dividing the thickness of the second insulator film by its dielectric constant.

18. The semiconductor device of claim 13, wherein the first insulator film is made of any one of silicon oxide, silicon nitride, or oxidized and nitrided silicon.

19. The semiconductor device of claim 13, wherein the second insulator film is made of any one of TiO₂, BaO, BaTiO₃, BaWO₄, BaZnGeO₄, Bi₁₂GeO₂₀, Bi₁₂SiO₂₀, Bi₁₂TiO₂₀, CaMoO₄, CaYAlO₄, Dy₂Ti₂O₇, EuAlO₃, Eu₃NbO₇, EuO, Gd₃NbO₇Ho₂Ti₂O₇, LaAlO₃, La₂Be₂O₆, La₂CuO₄, LaTi₂O₇, LiNbO₃, LiTaO₃, MnO, Nb₂O₅, NdAlO₃, Nd₂Ti₂O₇, PbF₂, Pb₅GeV₂O₁₂, PbMoO₄, PbO, PbWO₄, PrAlO₃, SrMoO₄, SrTiO₃, SrWO₄, Ta₂O₅, TeO₂, UO₂, Yb₂Ti₂O₇.

20. The semiconductor device of claim 13, wherein the second insulator film is made of any one of oxide of a valence of Hf, an oxide of Zr, Ti, Sc, Y, Ta, Al, La, Ce, Pr or an element from the lanthanoid group, and a silicate material.
